(19) United States
(12) Patent Application Publication
(10) Pub. No.: US 2012/0187382 A1
(43) Pub. Date: Jul. 26, 2012

(54) ELECTRONIC DEVICES HAVING LONG LIFETIME

(75) Inventors: Vsevolod Rostovtsev, Swarthmore, PA (US); Weiying Gao, Landenberg, PA (US); Gary A. Johansson, Hockessin, DE (US); Yulong Shen, Wilmington, DE (US); Adam Fennimore, Wilmington, DE (US); Kalindi Dogra, Wilmington, DE (US); Hong Meng, Wilmington, DE (US); Weishi Wu, Landenberg, PA (US); Michael Henry Howard, JR., Montchanin, DE (US); Ralph Birchard Lloyd, Fayetteville, NC (US); Nora Sabina Radu, Landenberg, PA (US); Norman Herron, Newark, DE (US); Daniel David Lecloux, West Chester, PA (US); Eric Maurice Smith, Hockessin, DE (US); Che-Hsiung Hsu, Wilmington, DE (US); Kyung-Ho Park, Wilmington, DE (US); Jeffrey A. Merlo, Wilmington, DE (US); Christina M. Older, Wilmington, DE (US); Jerald Feldman, Wilmington, DE (US); Ying Wang, Wilmington, DE (US)

(73) Assignee: E.I. DUPONT DE NEMOURS AND COMPANY, Wilmington, DE (US)

(21) Appl. No.: 13/141,352

(22) PCT Filed: Dec. 22, 2009
(86) PCT No.: PCT/US09/69255

§ 371 Date: Sep. 13, 2011

Related U.S. Application Data
(60) Provisional application No. 61/139,834, filed on Dec. 22, 2008.
(60) Provisional application No. 61/156,181, filed on Feb. 27, 2009.
(60) Provisional application No. 61/166,400, filed on Apr. 3, 2009.
(60) Provisional application No. 61/176,141, filed on May 7, 2009.
(60) Provisional application No. 61/179,407, filed on May 19, 2009.
(60) Provisional application No. 61/228,689, filed on Jul. 27, 2009.
(60) Provisional application No. 61/233,592, filed on Aug. 13, 2009.
(60) Provisional application No. 61/239,574, filed on Sep. 3, 2009.

(51) Int. Cl. H01L 51/54

(52) U.S. Cl. 257/40; 257/E51.026

(57) ABSTRACT

An organic light-emitting diode is provided having an anode, a cathode, and an organic active layer therebetween. The organic active layer includes a deuterated compound and the device has a calculated half-life at 1000 nits of at least 5000 hours.

### RELATED APPLICATION DATA

This application claims priority under 35 U.S.C. §119(e) from U.S. application Ser. No. 12/643,459 filed Dec. 21, 2009, U.S. Provisional Application No. 61/139,834 filed on Dec. 22, 2008, U.S. Provisional Application No. 61/156,181, filed on Feb. 27, 2009, U.S. Provisional Application No. 61/166,400 filed on Apr. 3, 2009, U.S. Provisional Application No. 61/176,141 filed on May 7, 2009, U.S. Provisional Application No. 61/179,407 filed on May 19, 2009, U.S. Provisional Application No. 61/228,689 filed on Jul. 27, 2009,

U.S. Provisional Application No. 61/233,592 filed on Aug. 13, 2009, U.S. Provisional Application No. 61/239,574 filed on Sep. 3, 2009, U.S. Provisional Application No. 61/246,563 filed on Sep. 29, 2009, U.S. Provisional Application No. 61/256,012 filed on Oct. 29, 2009, and U.S. Provisional Application No. 61/267,928 filed on Dec. 3, 2009, each of which is incorporated by reference herein in its entirety.

### BACKGROUND

1. Field of the Disclosure

This invention relates to electronic devices having at least one layer with a deuterated compound and having long active lifetimes.

2. Description of the Related Art

Organic electronic devices that emit light, such as light-emitting diodes that make up displays, are present in many different kinds of electronic equipment. In all such devices, an organic active layer is sandwiched between two electrical contact layers. At least one of the electrical contact layers is light-transmitting so that light can pass through the electrical contact layer. The organic active layer emits light through the light-transmitting electrical contact layer upon application of electricity across the electrical contact layers.

It is well known to use organic electroluminescent compounds as the active component in light-emitting diodes. Simple organic molecules such as anthracene, thiadiazole derivatives, and coumarin derivatives are known to show electroluminescence. Semiconductive conjugated polymers have also been used as electroluminescent components, as has been disclosed in, for example, U.S. Pat. No. 5,247,190, U.S. Pat. No. 5,408,109, and Published European Patent Application 443 861. In many cases the electroluminescent compound is present as a dopant in a host material. In many devices organic charge-injection layers and/or charge-transport layers are present between the light-emitting layer and the anode and/or the cathode.

There is a continuing need for electronic devices having greater lifetime.

### SUMMARY

There is provided an organic light-emitting diode comprising an anode, a cathode, and an organic active layer therebetween, wherein the organic active layer comprises a deuterated compound and the device has a calculated half-life at 1000 nits of at least 5000 hours.

There is also provided the above organic light-emitting diode, wherein the organic active layer comprises deuterated conductive polymer and a fluorinated acid polymer.

There is also provided the above organic light-emitting diode, wherein the organic active layer comprises a deuterated hole transport compound having at least two diarylamino moieties.

There is also provided the above organic light-emitting diode, wherein the organic active layer comprises an electroluminescent compound selected from the group consisting of deuterated aminoanthracenes, deuterated aminochrysenes, deuterated metal quinolate complexes, and deuterated iridium complexes.

There is also provided the above organic light-emitting diode, wherein the organic active layer comprises (a) a host material selected from the group consisting of deuterated arylanthracenes, deuterated arylpyrenes, deuterated arylchrysenes, deuterated phenanthrolines, deuterated indolocarbazoles, and combinations thereof and (b) an electroactive dopant capable of electroluminescence having an emission maximum between 380 and 750 nm.

There is also provided the above organic light-emitting diode, wherein the organic active layer comprises an electron transport material selected from the group consisting of deuterated phenanthrolines, deuterated indolocarbazoles, and deuterated metal quinolates.

### BRIEF DESCRIPTION OF THE DRAWINGS

Embodiments are illustrated in the accompanying figures to improve understanding of concepts as presented herein.

FIG. 1 includes an illustration of one example of an organic electronic device.

FIG. 2 includes another illustration of an organic electronic device.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments are disclosed herein and are exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Organic Light-Emitting Device, the Hole Injection Layer, the Hole Transport Layer, the Electroactive Layer, the Electron Transport Layer, the Containment Layer, Other Device Layers, Synthesis of Deuterated Materials, and finally, Examples.

### 1. Definitions and Clarification of Terms

Before addressing details of embodiments described below, some terms are defined or clarified.

The term “aliphatic ring” is intended to mean a cyclic group that does not have delocalized pi electrons. In some embodiments, the aliphatic ring has no unsaturation. In some embodiments, the ring has one double or triple bond.

The term “alkoxy” refers to the group RO—, where R is an alkyl.

The term “alkyl” is intended to mean a group derived from an aliphatic hydrocarbon having one point of attachment, and includes a linear, a branched, or a cyclic group. The term is intended to include heteroalkyls. The term “hydrocarbon alkyl” refers to an alkyl group having no heteroatoms. The term “deuterated alkyl” is a hydrocarbon alkyl having at least one available H replaced by D. In some embodiments, an alkyl group has from 1-20 carbon atoms. The term “branched alkyl” refers to an alkyl group having at least one secondary or tertiary carbon. The term “secondary alkyl” refers to a branched alkyl group having a secondary carbon atom. The term “tertiary alkyl” refers to a branched alkyl group having a tertiary carbon atom. In some embodiments, the branched alkyl group is attached via a secondary or tertiary carbon.

The term “aryl” is intended to mean a group derived from an aromatic hydrocarbon having one point of attachment. The term “aromatic compound” is intended to mean an organic compound comprising at least one unsaturated cyclic group having delocalized pi electrons. The term is intended include heteroaryls. The term “hydrocarbon aryl” is intended to mean aromatic compounds having no heteroatoms in the ring. The term aryl includes groups which have a single ring and those which have multiple rings which can be joined by a single bond or fused together. The term “deuterated aryl” refers to an aryl group having at least one available H bonded directly to the aryl replaced by D. The term “arylene” is intended to mean a group derived from an aromatic hydrocarbon having two points of attachment. In some embodiments, an aryl group has from 3-60 carbon atoms.

The term “aryloxy” refers to the group RO—, where R is an aryl.

The term “compound” is intended to mean an electrically uncharged substance made up of molecules that further consist of atoms, wherein the atoms cannot be separated by physical means. The phrase “adjacent to,” when used to refer to layers in a device, does not necessarily mean that one layer is immediately next to another layer. On the other hand, the phrase “adjacent R groups,” is used to refer to R groups that are next to each other in a chemical formula (i.e., R groups that are on atoms joined by a bond).

The term “conductive” or “electrically conductive” as it refers to a material, is intended to mean a material which is inherently or intrinsically capable of electrical conductivity without the addition of carbon black or conductive metal particles.

The term “deuterated” is intended to mean that at least one H has been replaced by D. The deuterium is present in at least 100 times the natural abundance level. A “deuterated derivative” of compound X has the same structure as compound X, but with at least one D replacing an H. The terms “% deuterated” and “% deuteration” refer to the ratio of deuterons to the sum of protons and deuterons, expressed as a percentage. Thus, for the compound C₆H₄D₂ the % deuteration is:

2/(4+2)×100=33% deuteration.

The term “dopant” is intended to mean a material, within a layer including a host material, that changes the electronic characteristic(s) or the targeted wavelength(s) of radiation emission, reception, or filtering of the layer compared to the electronic characteristic(s) or the wavelength(s) of radiation emission, reception, or filtering of the layer in the absence of such material.

The prefix “fluoro” and the term “fluorinated” refer to a material in which at least one available H has been replaced by F.

The term “electroactive” when referring to a layer or material, is intended to mean a layer or material that exhibits electronic or electro-radiative properties. In an electronic device, an electroactive material electronically facilitates the operation of the device. Examples of electroactive materials include, but are not limited to, materials which conduct, inject, transport, or block a charge, where the charge can be either an electron or a hole, and materials which emit radiation or exhibit a change in concentration of electron-hole pairs when receiving radiation. Examples of inactive materials include, but are not limited to, planarization materials, insulating materials, and environmental barrier materials. An organic electroactive layer comprises an organic compound as the electroactive material. As used herein, the term “organic” includes organometallic materials.

The term “half-life” is intended to mean the time required for the device luminance to reach half the initial value. The “observed half-life” is the half-life of the device measured at a constant current of 7 mA. The “calculated half-life” is the half-life derived from the observed half-life and calculated for 1000 nits initial luminance. The half-life is measured in hours.

The prefix “hetero” indicates that one or more carbon atoms have been replaced with a different atom. In some embodiments, the different atom is N, O, or S.

The term “host material” is intended to mean a material to which a dopant is added. The host material may or may not have electronic characteristic(s) or the ability to emit, receive, or filter radiation. In some embodiments, the host material is present in higher concentration.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing.

The term “organic electronic device” or sometimes just “electronic device” is intended to mean a device including one or more organic semiconductor layers or materials.

All groups can be substituted or unsubstituted unless otherwise indicated. In some embodiments, the substituents are selected from the group consisting of D, halide, alkyl, alkoxy, aryl, aryloxy, cyano, and NR₂, where R is alkyl or aryl.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

The IUPAC numbering system is used throughout, where the groups from the Periodic Table are numbered from left to right as 1-18 (CRC Handbook of Chemistry and Physics, 81^{st} Edition, 2000).

### 2. Organic Light-Emitting Diode

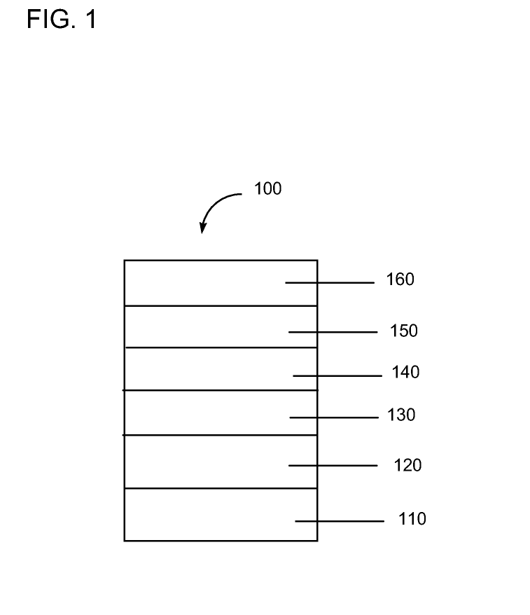

One illustration of an organic light-emitting diode (“OLED”) device structure is shown in FIG. 1. The device 100 has a first electrical contact layer, an anode layer 110 and a second electrical contact layer, a cathode layer 160, and an electroluminescent layer 140 between them. Adjacent to the anode may be a hole injection layer 120, comprising hole injection material. Adjacent to the hole injection layer may be a hole transport layer 130, comprising hole transport material. Adjacent to the cathode may be an electron transport layer 150, comprising an electron transport material. Devices may use one or more additional hole injection or hole transport layers (not shown) next to the anode 110 and/or one or more additional electron injection or electron transport layers (not shown) next to the cathode 160.

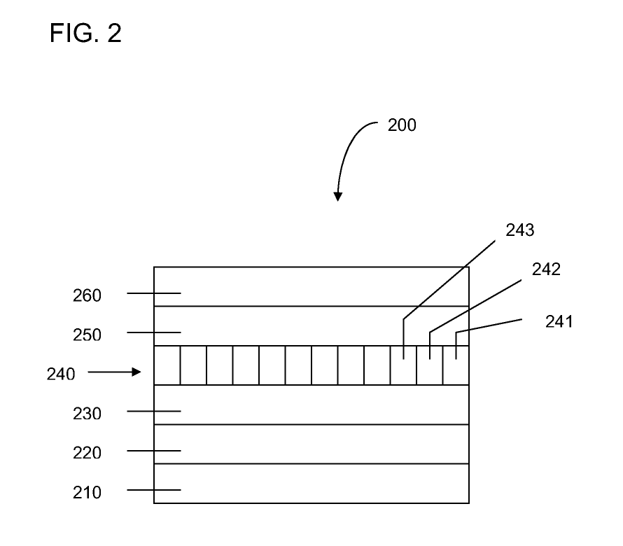

In some embodiments, in order to achieve full color, the light-emitting layer is pixellated, with subpixel units for each of the different colors. An illustration of a pixellated device is shown in FIG. 2. The device 200 has anode 210, hole injection layer 220, hole transport layer 230, electroluminescent layer 240, electron transport layer 250, and cathode 260. The electroluminescent layer is divided into subpixels 241, 242, 243, which are repeated across the layer. In some embodiments, the subpixels represent red, blue and green color emission. Although three different subpixel units are depicted in FIG. 2, two or more than three subpixel units may be used.

The different layers will be discussed further herein with reference to FIG. 1. However, the discussion applies to FIG. 2 and other configurations as well.

Layers 120 through 150 are individually and collectively referred to as the electroactive layers. At least one of the electroactive layers is an organic electroactive layer comprising a deuterated material. The deuterated materials may be used alone or in combination with other deuterated materials or non-deuterated materials. In some embodiments, the deuterated material is at least 10% deuterated. By this is meant that at least 10% of the H are replaced by D. In some embodiments, the deuterated material is at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated. In some embodiments, the deuterated material is 100% deuterated.

In some embodiments, the deuterated material is a hole injection material in layer 120. In some embodiments, at least one additional layer includes a deuterated material. In some embodiments, the additional layer is the hole transport layer 130. In some embodiments, the additional layer is the electroactive layer 140. In some embodiments, the additional layer is the electron transport layer 150.

In some embodiments, the deuterated material is a hole transport material in layer 130. In some embodiments, at least one additional layer includes a deuterated material. In some embodiments, the additional layer is the hole injection layer 120. In some embodiments, the additional layer is the electroactive layer 140. In some embodiments, the additional layer is the electron transport layer 150.

In some embodiments, the deuterated material is a host material for a dopant materials in electroactive layer 140. In some embodiments, the dopant material is also deuterated. In some embodiments, at least one additional layer includes a deuterated material. In some embodiments, the additional layer is the hole injection layer 120. In some embodiments, the additional layer is the hole transport layer 130. In some embodiments, the additional layer is the electron transport layer 150.

In some embodiments, the deuterated material is an electron transport material in layer 150. In some embodiments, at least one additional layer includes a deuterated material. In some embodiments, the additional layer is the hole injection layer 120. In some embodiments, the additional layer is the hole transport layer 130. In some embodiments, the additional layer is the electroactive layer 140.

In some embodiments, an electronic device has deuterated materials in any combination of layers selected from the group consisting of the hole injection layer, the hole transport layer, the electroactive layer, and the electron transport layer. In some embodiments, all the organic active layers of the device include deuterated materials.

In some embodiments, the devices have additional layers to aid in processing or to improve functionality. Any or all of these layers can include deuterated materials. In some embodiments, all the organic device layers comprise deuterated materials. In some embodiments, all the organic device layers consist essentially of deuterated materials.

In some embodiments, the organic light-emitting diode comprises an anode, a cathode and has organic layers therebetween, wherein the organic layers are a hole injection layer, a hole transport layer, an electroluminescent layer, an electron transport layer, and a cathode, and wherein at least two of the organic layers consist essentially of deuterated material. In some embodiments, all of the organic layers consist essentially of deuterated material.

In one embodiment, the different layers have the following range of thicknesses: anode 110, 500-5000 Å, in one embodiment 1000-2000 Å; hole injection layer 120, 50-2000 Å, in one embodiment 200-1000 Å; hole transport layer 130, 50-2000 Å, in one embodiment 200-1000 Å; electroactive layer 140, 10-2000 Å, in one embodiment 100-1000 Å; layer 150, 50-2000 Å, in one embodiment 100-1000 Å; cathode 160, 200-10000 Å, in one embodiment 300-5000 Å. The location of the electron-hole recombination zone in the device, and thus the emission spectrum of the device, can be affected by the relative thickness of each layer. The desired ratio of layer thicknesses will depend on the exact nature of the materials used.

The observed half-life of the device described herein is at least 200 hours. In some embodiments, the observed half-life is at least 400 hours; in some embodiments, at least 1000 hours.

The calculated half-life of the device described herein is at least 5000 hours. The method for calculating the half-life at a given initial luminance is well known. The method has been described in, for example, Chu et. al., Appl. Phys. Lett. 89, 053503 (2006) and Wellmann et. al., SID Int. Symp. Digest Tech. Papers 2005, 393. In some embodiments, the calculated half-life is at least 10,000 hours; in some embodiments, at least 20,000 hours; in some embodiments, at least 50,000 hours.

### 2. Hole Injection Layer

The hole injection layer 120 comprises hole injection material and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Hole injection materials may be polymers, oligomers, or small molecules. They may be vapor deposited or deposited from liquids which may be in the form of solutions, dispersions, suspensions, emulsions, colloidal mixtures, or other compositions.

In some embodiments, the hole injection layer comprises deuterated material. In some embodiments, the deuterated material comprises a deuterated electrically conductive polymer. By “deuterated electrically conductive polymer” it is meant that the electrically conductive polymer itself, not including the associated polymeric acid, is deuterated. In some embodiments, the deuterated material comprises an electrically conductive polymer doped with a deuterated polymeric acid. In some embodiments, the deuterated material comprises a deuterated electrically conductive polymer doped with a deuterated polymeric acid.

In some embodiments, the deuterated electrically conductive polymer is selected from the group consisting of deuterated polythiophenes, deuterated poly(selenophenes), deuterated poly(tellurophenes), deuterated polypyrroles, deuterated polyanilines, deuterated poly(4-amino-indoles), deuterated poly(7-amino-indoles), and deuterated polycyclic aromatic polymers, respectively. The term “polycyclic aromatic” refers to compounds having more than one aromatic ring. The rings may be joined by one or more bonds, or they may be fused together. The term “aromatic ring” is intended to include heteroaromatic rings. A “polycyclic heteroaromatic” compound has at least one heteroaromatic ring. In some embodiments, the deuterated polycyclic aromatic polymers are deuterated poly(thienothiophenes).

In some embodiments, the deuterated electrically conductive polymer is selected from the group consisting of deuterated poly(3,4-ethylenedioxythiophene), deuterated polyaniline, deuterated polypyrrole, deuterated poly(4-aminoindole), deuterated poly(7-aminoindole), deuterated poly(thieno(2,3-b)thiophene), deuterated poly(thieno(3,2-b)thiophene), and deuterated poly(thieno(3,4-b)thiophene).

In some embodiments, the deuterated conductive polymer is at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated.

In some embodiments, the electrically conductive polymer is selected from the group consisting of poly(D₆-3,4-ethylenedioxythiophene), poly(D₅-pyrrole), poly(D₇-aniline), poly(perdeutero-4-aminoindole), poly(perdeutero-7-aminoindole), poly(perdeutero-thieno(2,3-b)thiophene), poly(perdeutero-thieno(3,2-b)thiophene), and poly(perdeutero-thieno(3,4-b)thiophene).

In some embodiments, the deuterated conductive polymer is doped with a non-fluorinated polymeric acid. Any polymer having acidic groups with ionizable protons or deuterons can be used. Examples of acidic groups include, but are not limited to, carboxylic acid groups, sulfonic acid groups, sulfonimide groups, phosphoric acid groups, phosphonic acid groups, and combinations thereof. The acidic groups can all be the same, or the polymer may have more than one type of acidic group. In some embodiments, the acidic groups are selected from the group consisting of sulfonic acid groups, sulfonimide groups, and combinations thereof. A sulfonimide group has the formula:

—SO₂—NH—SO₂—R

where R is an alkyl group. Examples of suitable acids include, but are not limited to, poly(styrenesulfonic acid) (“PSSA”), poly(perdeutero-styrenesulfonic acid) (“D₈-PSSA”), poly(2-acrylamido-2-methyl-1-propanesulfonic acid) (“PAAMPSA”), poly(perdeutero-2-acrylamido-2-methyl-1-propanesulfonic acid) (“D₁₃-PAAMPSA”), and mixtures thereof.

In some embodiments, the deuterated conductive polymer doped with a non-fluorinated polymeric acid is further combined with a highly-fluorinated acid polymer (“HFAP”).

In some embodiments, the fluorinated acid polymer is a highly fluorinated acid polymer (“HFAP”), where at least 80% of the available hydrogens bonded to carbon have been replaced by fluorine. The highly-fluorinated acid polymer (“HFAP”) can be any polymer which is highly-fluorinated and has acidic groups. The acidic groups supply an ionizable proton, H⁺, or deuteron, D. In some embodiments, the acidic group has a pKa of less than 3. In some embodiments, the acidic group has a pKa of less than 0. In some embodiments, the acidic group has a pKa of less than −5. The acidic group can be attached directly to the polymer backbone, or it can be attached to side chains on the polymer backbone. Examples of acidic groups include, but are not limited to, carboxylic acid groups, sulfonic acid groups, sulfonimide groups, phosphoric acid groups, phosphonic acid groups, and combinations thereof. The acidic groups can all be the same, or the polymer may have more than one type of acidic group. In some embodiments, the acidic groups are selected from the group consisting of sulfonic acid groups, sulfonimide groups, and combinations thereof.

In some embodiments, the HFAP is a deutero-acid with an acidic deuteron.

In some embodiments, the HFAP is at least 90% fluorinated; in some embodiments, at least 95% fluorinated; in some embodiments, fully-fluorinated. In some embodiments where the HFAP is not fully-fluorinated, the HFAP is also deuterated.

In some embodiments, the acidic groups are selected from the group consisting of sulfonic acid groups, sulfonimide groups, and combinations thereof. In some embodiments, the acidic groups are on a fluorinated side chain. In some embodiments, the fluorinated side chains are selected from alkyl groups, alkoxy groups, amido groups, ether groups, and combinations thereof, all of which are fully fluorinated.

In some embodiments, the HFAP has a highly-fluorinated olefin backbone, with pendant highly-fluorinated alkyl sulfonate, highly-fluorinated ether sulfonate, highly-fluorinated ester sulfonate, or highly-fluorinated ether sulfonimide groups. In some embodiments, the HFAP is a perfluoroolefin having perfluoro-ether-sulfonic acid side chains. In some embodiments, the polymer is a copolymer of tetrafluoroethylene and perfluoro-3,6-dioxa-4-methyl-7-octenesulfonic acid (“poly(TFE-PSEPVE)”). The deutero-acid analog is abbreviated as D-poly(TFE-PSEPVE). In some embodiments, the polymer is a copolymer of 1,1-difluoroethylene and 2-(1,1-difluoro-2-(trifluoromethyl)allyloxy)-1,1,2,2-tetrafluoroethanesulfonic acid. In some embodiments, the polymer is a copolymer of ethylene and 2-(2-(1,2,2-trifluorovinyloxy)-1,1,2,3,3,3-hexafluoropropoxy)-1,1,2,2-tetrafluoroethanesulfonic acid. These copolymers can be made as the corresponding sulfonyl fluoride polymer and then can be converted to the sulfonic acid form.

In some embodiments, the deuterated conductive polymer is doped with a HFAP. The non-deuterated analogs of such materials have been described in, for example, published U.S. patent applications US 2004/0102577, US 2004/0127637, US 2005/0205860, and published PCT application WO 2009/018009.

In some embodiments, the hole injection layer comprises a deuterated poly(3,4-ethylenedioxythiophene) (“d-PEDOT”) doped with polystyrenesulfonic acid (“PSSA”). In some embodiments, the hole injection layer comprises poly(3,4-ethylenedioxythiophene) (“PEDOT”) doped with a deuterated polystyrenesulfonic acid (“d-PSSA”). In some embodiments, the hole injection layer comprises deuterated poly(3,4-ethylenedioxythiophene) doped with deuterated polystyrenesulfonic acid. In some embodiments, the d-PEDOT/d-PSSA is at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated. In some embodiments, the hole injection layer consists essentially of a material selected from the group consisting of d-PEDOT/PSSA, PEDOT/d-PSSA, and d-PEDOT/d-PSSA. In some embodiments, the hole injection layer consists essentially of poly(D₆-3,4-ethylenedioxythiophene) doped with D₈-PSSA.

In some embodiments, the hole injection layer comprises a deuterated polyaniline (“d-PANI”) doped with poly(2-acrylamido-2-methyl-1-propanesulfonic acid) (“PAAMPSA”). In some embodiments, the hole injection layer comprises polyaniline (“PANI”) doped with deuterated poly(2-acrylamido-2-methyl-1-propanesulfonic acid) (“d-PAAMPSA”). In some embodiments, the hole injection layer comprises deuterated polyanilijne doped with deuterated poly(2-acrylamido-2-methyl-1-propanesulfonic acid). In some embodiments, the d-PANI/d-PAAMPSA is at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated. In some embodiments, the hole injection layer consists essentially of a material selected from the group consisting of d-PANI/PAAMPSA, PANI/d-PAAMPSA, and d-PANI/d-PAAMPSA. In some embodiments, the hole injection layer consists essentially of poly(D₇-aniline) doped with D₁₃-PAAMPSA.

In some embodiments, the hole injection layer comprises a deuterated polypyrrole (“d-PPy”) doped with polystyrenesulfonic acid (“PSSA”). In some embodiments, the hole injection layer comprises polypyrrole (“PPy”) doped with a deuterated polystyrenesulfonic acid (“d-PSSA”). In some embodiments, the hole injection layer comprises deuterated polypyrrole doped with deuterated polystyrenesulfonic acid. In some embodiments, the d-PPy/d-PSSA is at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated. In some embodiments, the hole injection layer consists essentially of a material selected from the group consisting of d-PPy/PSSA, PPy/d-PSSA, and d-PPy/d-PSSA. In some embodiments, the hole injection layer consists essentially of poly(D₅-pyrrole) doped with D₈-PSSA.

In some embodiments, the hole injection layer comprises a deuterated conductive polymer and a HFAP. In some embodiments, the hole injection layer comprises a deuterated conductive polymer doped with HFAP. In some embodiments, the hole injection layer consists essentially of a deuterated conductive polymer doped with HFAP. In some embodiments, the hole injection layer consists essentially of a deuterated conductive polymer doped with a perfluorinated sulfonic acid polymer. In some embodiments, the hole injection layer consists essentially of a deuterated conductive polymer doped with D-poly(TFE-PSEPVE), where the conductive polymer is selected from the group consisting of poly(D₆-3,4-ethylenedioxythiophene), poly(D₇-aniline) and poly(D₅-pyrrole).

In some embodiments, the hole injection layer comprises charge transfer compounds, and the like, such as copper phthalocyanine, the tetrathiafulvalene-tetracyanoquinodimethane system (TTF-TCNQ) and deuterated analogs thereof.

### 3. Hole Transport Layer

The hole transport layer 130 comprises hole transport material. The term “hole transport” when referring to a layer, material, member, or structure, is intended to mean that such layer, material, member, or structure facilitates migration of positive charges through the thickness of such layer, material, member, or structure with relative efficiency and small loss of charge. Although light-emitting materials may also have some hole transport properties, the terms “hole transport layer, material, member, or structure” are not intended to include a layer, material, member, or structure whose primary function is light emission.

Hole transport materials may be polymers, oligomers, or small molecules. They may be vapor deposited or deposited from liquids, which may be in the form of solutions, dispersions, suspensions, emulsions, colloidal mixtures, or other compositions.

In some embodiments, the hole transport layer comprises deuterated material. In some embodiments, the hole transport material is at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated.

In some embodiments, the hole transport material is a deuterated compound having at least two diarylamino moieties per molecular formula unit. In some embodiments, the hole transport material is a deuterated triarylamine polymer. Non-deuterated analogs of such materials have been described in, for example, published PCT application WO 2009/067419. In some embodiments, the hole transport material is a deuterated fluorene-triarylamine copolymer. Non-deuterated analogs of such materials have been described in, for example, published U.S. patent applications US 2008/0071049 and US 2008/0097076. Examples of non-deuterated analogs of crosslinkable hole transport polymers can be found in, for example, published US patent application 2005/0184287 and published PCT application WO 2005/052027.

In some embodiments, the hole transport material is selected from the group consisting of deuterated triarylamine, deuterated carbazoles, deuterated fluorenes, polymers thereof, copolymers thereof, and combinations thereof. In some embodiments, the hole transport material is selected from the group consisting of deuterated polymeric triarylamines, deuterated polycarbazoles, deuterated polyfluorenes, deuterated polymeric triarylamines having conjugated moieties which are connected in a non-planar configuration, deuterated copolymers of fluorene and triarylamine, and combinations thereof. In some embodiments, the polymeric materials are crosslinkable.

In some embodiments, the hole transport material has Formula I, Formula II, or Formula III:

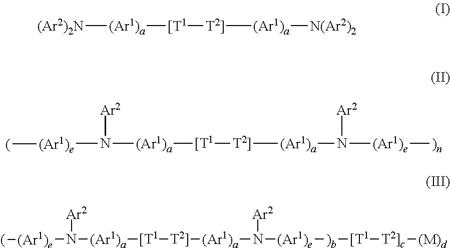

wherein:
Ar¹ is the same or different at each occurrence and is selected from the group consisting of phenylene, substituted phenylene, naphthylene, and substituted naphthylene;
Ar² is the same or different at each occurrence and is an aryl group;
M is the same or different at each occurrence and is a conjugated moiety;
T¹ and T² are independently the same or different at each occurrence and are conjugated moieties;
a is the same or different at each occurrence and is an integer from 1 to 6;
b, c, and d are mole fractions such that b+c+d=1.0, with the proviso that c is not zero, and at least one of b and d is not zero, and when b is zero, M comprises at least two triarylamine units;
e is the same or different at each occurrence and is an integer from 1 to 6; and
n is an integer greater than 1;
wherein the compound is at least 10% deuterated.
   The non-deuterated analogs of such materials have been described in published PCT application WO 2009/067419.

In some embodiments of Formulae I-III, the deuteration is on a substituent group on an aryl ring. In some embodiments, the substituent group is selected from alkyl, aryl, alkoxy, and aryloxy. In some embodiments of Formulae I-III, the deuteration is on any one or more of the aryl groups Ar¹ and Ar². In this case, at least one of Ar¹ and Ar² is a deuterated aryl group. In some embodiments of Formulae I-III, deuteration is present on the [T¹-T²] group. In some embodiments, both T¹ and T² are deuterated. In some embodiments of Formulae I-III, the deuteration is present on both the substituent groups and the Ar¹ and Ar² groups. In some embodiments of Formulae I-III, the deuteration is present on both the [T¹-T²] group and the Ar¹ and Ar² groups. In some embodiments of Formulae I-III, the deuteration is present on the substituent groups, the [T¹-T²] group, and the Ar¹ and Ar² groups.

In some embodiments, at least one Ar¹ is a substituted phenyl with a substituent selected from the group consisting of alkyl, alkoxy, silyl, and a substituent with a crosslinking group. In some embodiments, a is 1-3. In some embodiments a is 1-2. In some embodiments, a is 1. In some embodiments, e is 1-4. In some embodiments, e is 1-3. In some embodiments, e=1. In some embodiments, at least one Ar¹ has a substituent that has a crosslinking group.

In some embodiments, at least one of Ar² has Formula a

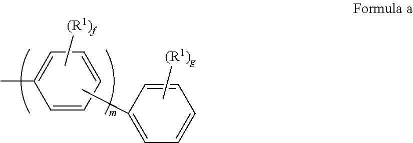

where:
R¹ is the same or different at each occurrence and is selected from the group consisting of D, alkyl, alkoxy, siloxane and, silyl; or adjacent R¹ groups may be joined to form an aromatic ring;
f is the same or different at each occurrence and is an integer from 0-4;
g is an integer from 0-5; and
m is an integer from 1 to 5.
In some embodiments, at least one of Ar² has Formula b:

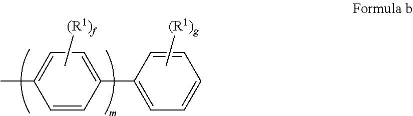

where:
R¹ is the same or different at each occurrence and is selected from the group consisting of D, alkyl, alkoxy, siloxane and, silyl; or adjacent R¹ groups may be joined to form an aromatic ring;
f is the same or different at each occurrence and is an integer from 0-4;
g is an integer from 0-5; and
m is an integer from 1 to 5.
   In some embodiments of Formula a or b, at least one of f and g is not zero. In some embodiments, m=1-3.

In some embodiments, Ar² is selected from the group consisting of a group having Formula a, naphthyl, phenylnaphthyl, naphthylphenyl, and deuterated analogs thereof. In some embodiments, Ar² is selected from the group consisting phenyl, p-biphenyl, p-terphenyl, naphthyl, phenylnaphthyl, naphthylphenyl, and deuterated analogs thereof. In some embodiments, Ar² is selected from the group consisting of phenyl, biphenyl, terphenyl, and deuterated analogs thereof.

Any of the aromatic rings in Formulae I-III may be substituted at any position. The substituents may be present to improve one or more physical properties of the compound, such as solubility. In some embodiments, the substituents are selected from the group consisting of C₁₋₁₂ alkyl groups, C₁₋₁₂ alkoxy groups, silyl groups, and deuterated analogs thereof. In some embodiments, crosslinking substituents are present on at least one Ar². In some embodiments, crosslinking substituents are present on at least one M moiety.

T¹ and T² are conjugated moieties. In some embodiments, T¹ and T² are aromatic moieties. In some embodiments, T¹ and T² are deuterated aromatic moieties. In some embodiments, T¹ and T² are selected from the group consisting of phenylene, napthylene, anthracenyl groups, and deuterated analogs thereof.

In some embodiments, the T¹-T² group introduces non-planarity into the backbone of the compound. The moiety in T¹ that is directly linked to a moiety in T² is linked such that the T¹ moiety is oriented in a plane that is different from the moiety in T² to which it is linked. Although other parts of the T¹ unit, for example, substituents, may lie in one or more different planes, it is the plane of the linking moiety in T¹ and the linking moiety in T² in the compound backbone that provide the non-planarity. Because of the non-planar T¹-T² linkage, the compounds are chiral. In general, they are formed as racemic mixtures. The compounds can also be in enantiomerically pure form. The non-planarity can be viewed as the restriction to free rotation about the T¹-T² bond. Rotation about that bond leads to racemization. The half-life of racemization for T¹-T² is greater than that for an unsubstituted biphenyl. In some embodiments, the half-life or racemization is 12 hours or greater at 20° C.

In some embodiments, [T¹-T²] is a substituted biphenylene group, deuterated analog thereof. The term “biphenylene” is intended to mean a biphenyl group having two points of attachment to the compound backbone. The term “biphenyl” is intended to mean a group having two phenyl units joined by a single bond. The biphenylene group can be attached at one of the 2,3-, 4-, or 5-positions and one of the 2′,3′-, 4′-, or 5′-positions. The substituted biphenylene group has at least one substitutent in the 2-position. In some embodiments, the biphenylene group has substituents in at least the 2- and 2′-positions.

In some embodiments, [T¹-T²] is a binaphthylene group, or deuterated analog thereof. The term “binaphthylene” is intended to mean a binapthyl group having 2 points of attachment to the compound backbone. The term “binaphthyl” is intended to mean a group having two naphthalene units joined by a single bond.

In some embodiments, [T¹-T²] is a phenylene-naphthylene group, or deuterated analog thereof. In some embodiments, [T¹-T²] is a phenylene-1-naphthylene group, which is attached to the compound backbone at one of the 3-, 4-, or 5-positions in the phenylene and one of the 3-, 4-, or 5-positions of the naphthylene. In some embodiments, [T¹-T²] is a phenylene-2-naphthylene group, which is attached to the compound backbone at one of the 3-, 4-, or 5-positions in the phenylene and one of the 4-, 5-, 6-, 7-, or 8-positions of the naphthylene.

In some embodiments, the biphenylene, binaphthylene, and phenylene-naphthylene groups are substituted at one or more positions.

In some embodiments, [T¹-T²] is a 1,1-binaphthylene group, or deuterated analog thereof, which is attached to the compound backbone at the 4 and 4′ positions, referred to as 4,4′-(1,1-binaphthylene). In some embodiments, the 4,4′-(1,1-binaphthylene) is the only isomer present. In some embodiments, two or more isomers are present. In some embodiments, the 4,4′-(1,1-binaphthylene) is present with up to 50% by weight of a second isomer. In some embodiments, the second isomer is selected from the group consisting of 4,5′-(1,1-binaphthylene), 4,6′-(1,1-binaphthylene), and 4,7′-(1,1-binaphthylene).

Formula III represents a copolymer in which there is at least one [T¹-T²] moiety and at least one other conjugated moiety, where the overall polymer is at least 10% deuterated. In some embodiments, the deuteration is in the first monomeric unit, with the subscript “b”. In some embodiments, the deuteration is in the second monomeric unit, with the subscript “c”. In some embodiments, the deuteration is in the third monomeric unit, with the subscript “d”. In some embodiments, the deuteration is in two monomeric units. In some embodiments, one of the two monomeric units is the first monomeric unit. In some embodiments, the deuteration is in all three monomeric units.

Some non-limiting examples of deuterated hole transport compounds include Compounds HT1 through HT10 below.

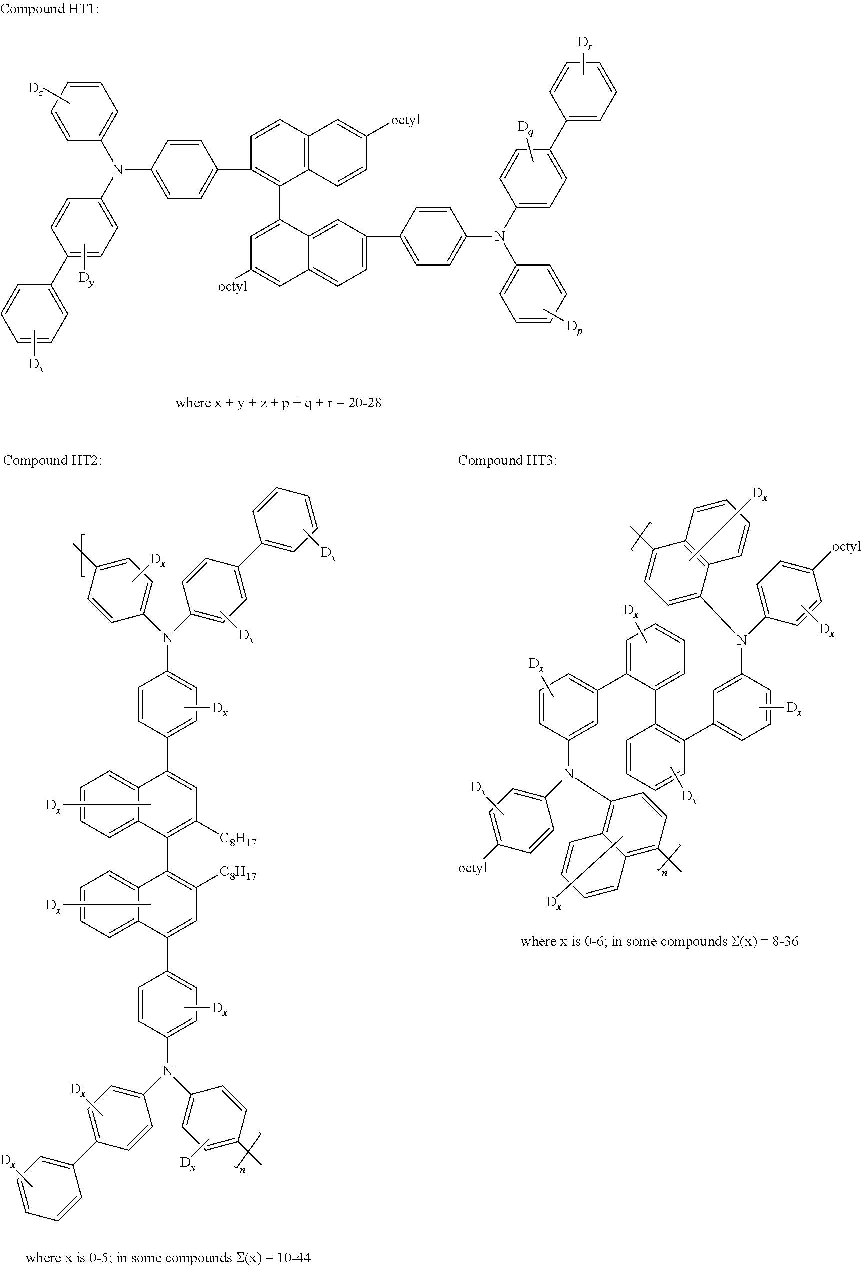

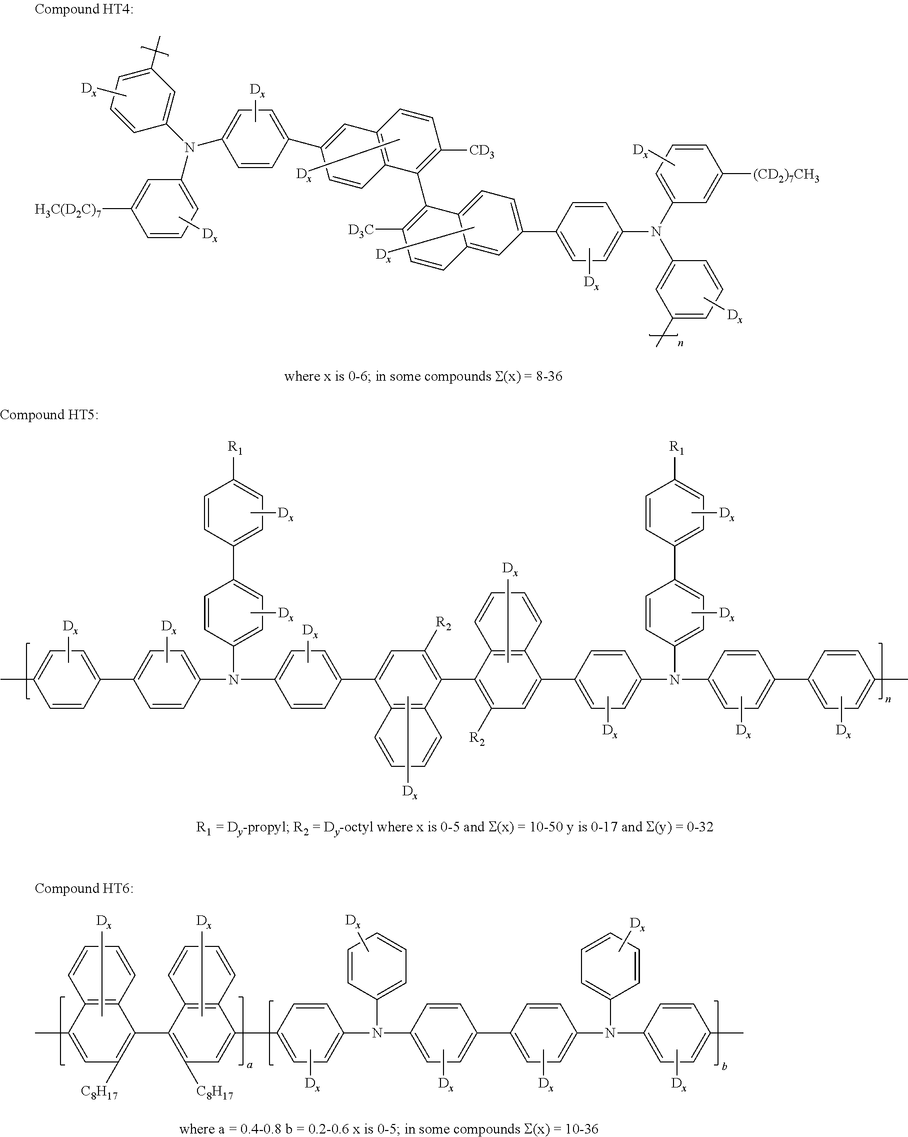

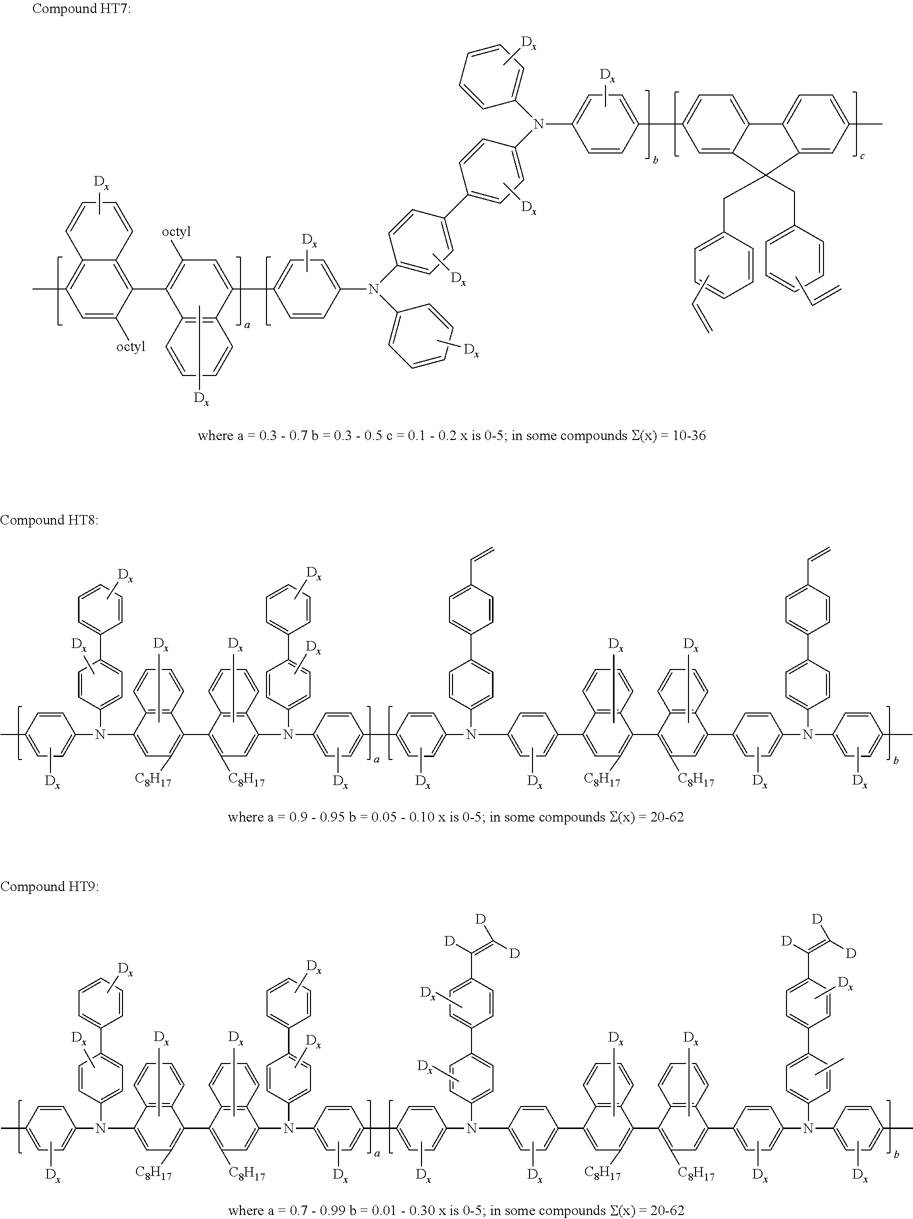

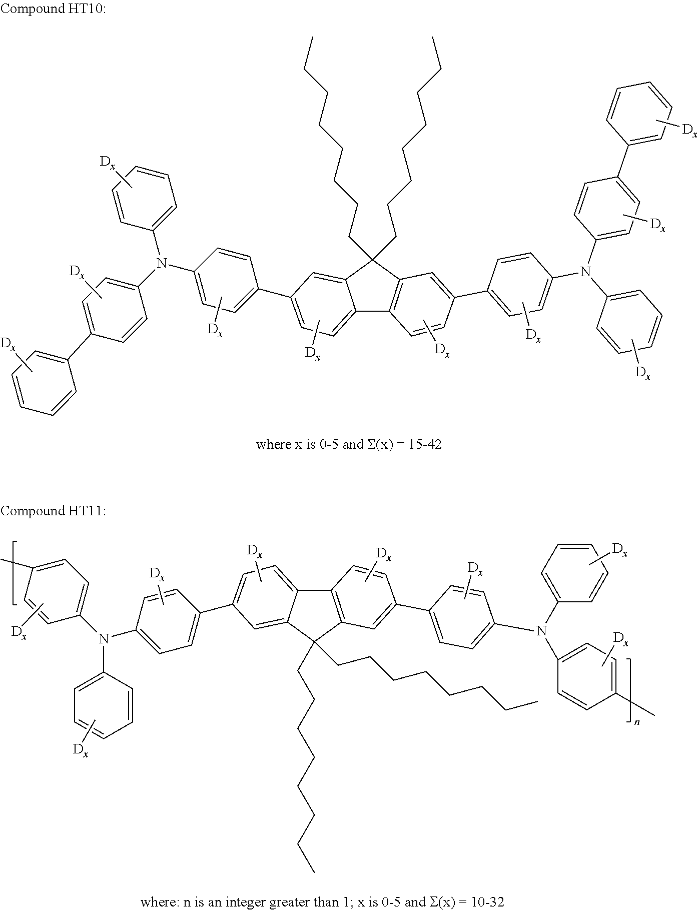

Another example of a triarylamine polymer is Compound HT12.

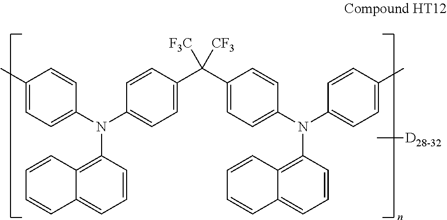

Examples of non-deuterated analogs of other hole transport materials for layer 130 have been summarized for example, in Kirk-Othmer Encyclopedia of Chemical Technology, Fourth Edition, Vol. 18, p. 837-860, 1996, by Y. Wang. Other hole transport materials include, but are not limited to: N,N′-diphenyl-N,N′-bis(3-methylphenyl)-[1,1′-biphenyl]-4,4′-diamine (TPD), 1,1-bis[(di-4-tolylamino) phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (PDA), a-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3-[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), N,N′-bis(naphthalen-1-yl)-N,N′-bis-(phenyl)benzidine (NPB), porphyrinic compounds, such as copper phthalocyanine, and deuterated analogs of any of the previously listed materials. It is also possible to obtain hole transporting polymers by doping hole transporting molecules such as those mentioned above into polymers such as polystyrene, polycarbonate, and deuterated analogs thereof.

In some embodiments, the hole transport layer is doped with a p-dopant, such as tetrafluorotetracyanoquinodimethane, perylene-3,4,9,10-tetracarboxylic-3,4,9,10-dianhydride, and deuterated analogs thereof.

### 4. Electroluminescent Layer

The electroluminescent layer 140 comprises electroluminescent material. The term “electroluminescent material” refers to a material that emits light when activated by an applied voltage. In some embodiments, the electroluminescent layer 140 consists essentially of electroluminescent material. In some embodiments, the electroluminescent layer 140 comprises one or more dopants and one or more host compounds. In some embodiments, the electroluminescent layer 140 consists essentially of one or more dopants and one or more host compounds. An electroluminescent dopant is a material which is capable of electroluminescence having an emission maximum between 380 and 750 nm. In some embodiments, the dopant emits red, green, or blue light. The host compound is a compound, usually in the form of a layer, in which one or more dopants are dispersed and in which the one or more dopants are emissive. The term “host material” refers to the total of all host compounds present. The host material may or may not have electronic characteristic(s) or the ability to emit, receive, or filter radiation. In the electroluminescent layer comprising at least one dopant and host material, the light emission is from the dopant. In some embodiments, the host material is present in larger concentration than the sum of all the dopants. In some embodiments, the electroluminescent layer 140 consists essentially of one or more dopants and one or more host compounds. In some embodiments, the electroluminescent layer 140 consists essentially of a dopant and a host compound. In some embodiments, the electroluminescent layer 140 consists essentially of a dopant and two host compounds.

In some embodiments, the electroluminescent layer comprises deuterated material selected from the group consisting of deuterated electroluminescent material, deuterated host material, and combinations thereof.

Materials for the electroluminescent layer may be polymers, oligomers, small molecules, or combinations thereof. They may be vapor deposited or deposited from liquids, which may be in the form of solutions, dispersions, suspensions, emulsions, colloidal mixtures, or other compositions.

When a host is present, the amount of total dopant present in the electroluminescent composition is generally in the range of 3-20% by weight, based on the total weight of the composition; in some embodiments, 5-15% by weight. When two host compounds are present, the ratio of first host to second host is generally in the range of 1:20 to 20:1; in some embodiments, 5:15 to 15:5.

a. Electroluminescent Material

The electroluminescent material can be selected from small molecule organic electroluminescent compounds, electroluminescent metal complexes, electroluminescent conjugated polymers, and mixtures thereof.

In some embodiments, the electroluminescent material is deuterated. In some embodiments, the electroluminescent material is at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated.

Examples of red light-emitting materials include, but are not limited to, cyclometalated complexes of Ir having phenylquinoline or phenylisoquinoline ligands, periflanthenes, fluoranthenes, perylenes, and deuterated analogs thereof. Non-deuterated red light-emitting materials have been disclosed in, for example, U.S. Pat. No. 6,875,524, and published US application 2005-0158577.

Examples of green light-emitting materials include, but are not limited to, cyclometalated complexes of Ir having phenylpyridine ligands, diaminoanthracenes, polyphenylenevinylene polymers, and deuterated analogs thereof. Non-deuterated green light-emitting materials have been disclosed in, for example, published PCT application WO 2007/021117.

Examples of blue light-emitting materials include, but are not limited to, diarylanthracenes, diaminochrysenes, diaminopyrenes, diaminostilbenes, cyclometalated complexes of Ir having phenylpyridine ligands, polyfluorene polymers, and deuterated analogs thereof. Non-deuterated blue light-emitting materials have been disclosed in, for example, U.S. Pat. No. 6,875,524, and published US applications 2007-0292713 and 2007-0063638.

In some embodiments, the dopant is an organometallic complex. In some embodiments, the dopant is a cyclometalated complex of iridium or platinum. Such materials when not deuterated have been disclosed in, for example, U.S. Pat. No. 6,670,645 and Published PCT Applications WO 03/063555, WO 2004/016710, and WO 03/040257.

In some embodiments, the dopant is a complex having the formula Ir(L1)ₓ(L2)_{y}(L3)_{z}; where

L1 is a monoanionic bidentate cyclometalating ligand coordinated through carbon and nitrogen;

L2 is a monoanionic bidentate ligand which is not coordinated through a carbon;

L3 is a monodentate ligand;

x is 1-3;

y and z are independently 0-2;

and x, y, and z are selected such that the iridium is hexacoordinate and the complex is electrically neutral.

Some examples of formulae include, but are not limited to, Ir(L1)₃; Ir(L1)₂(L2); and Ir(L1)₂(L3)(L3′), where L3 is anionic and L3′ is nonionic.

Examples of L1 ligands include, but are not limited to phenylpyridines, phenylquinolines, phenylpyrimidines, phenylpyrazoles, thienylpyridines, thienylquinolines, thienylpyrimidines, and deuterated analogs thereof. As used herein, the term “quinolines” includes “isoquinolines” unless otherwise specified. The fluorinated derivatives can have one or more fluorine substituents. In some embodiments, there are 1-3 fluorine substituents on the non-nitrogen ring of the ligand.

Monoanionic bidentate ligands, L2, are well known in the art of metal coordination chemistry. In general these ligands have N, O, P, or S as coordinating atoms and form 5- or 6-membered rings when coordinated to the iridium. Suitable coordinating groups include, but are not limited to, amino, imino, amido, alkoxide, carboxylate, phosphino, thiolate, and deuterated analogs thereof. Examples of suitable parent compounds for these ligands include β-dicarbonyls (β-enolate ligands), and their N and S analogs; amino carboxylic acids (aminocarboxylate ligands); pyridine carboxylic acids (iminocarboxylate ligands); salicylic acid derivatives (salicylate ligands); hydroxyquinolines (hydroxyquinolinate ligands) and their S analogs; phosphinoalkanols (phosphinoalkoxide ligands); and deuterated analogs thereof.

Monodentate ligand L3 can be anionic or nonionic. Anionic ligands include, but are not limited to, H⁻ (“hydride”) and ligands having C, O or S as coordinating atoms. Coordinating groups include, but are not limited to alkoxide, carboxylate, thiocarboxylate, dithiocarboxylate, sulfonate, thiolate, carbamate, dithiocarbamate, thiocarbazone anions, sulfonamide anions, and deuterated analogs thereof. In some cases, ligands listed above as L2, such as β-enolates and phosphinoakoxides, can act as monodentate ligands. The monodentate ligand can also be a coordinating anion such as halide, cyanide, isocyanide, nitrate, sulfate, hexahaloantimonate, and the like. These ligands are generally available commercially.

The monodentate L3 ligand can also be a non-ionic ligand, such as CO, a monodentate phosphine ligand, or a deuterated monodentate phosphine ligand.

In some embodiments, one or more of the ligands has at least one substituent selected from the group consisting of F and fluorinated alkyls.

The iridium complex dopants can be made using standard synthetic techniques analogous to those described for non-deuterated analogs in, for example, U.S. Pat. No. 6,670,645.

In some embodiments, the electroluminescent material is a small organic compound. Examples of small molecule luminescent compounds include, but are not limited to, chrysenes, pyrenes, perylenes, rubrenes, periflanthenes, fluoranthenes, stilbenes, coumarins, anthracenes, thiadiazoles, derivatives thereof, deuterated analogs thereof, and mixtures thereof.

In some embodiments, the electroluminescent material has one of the following structures:

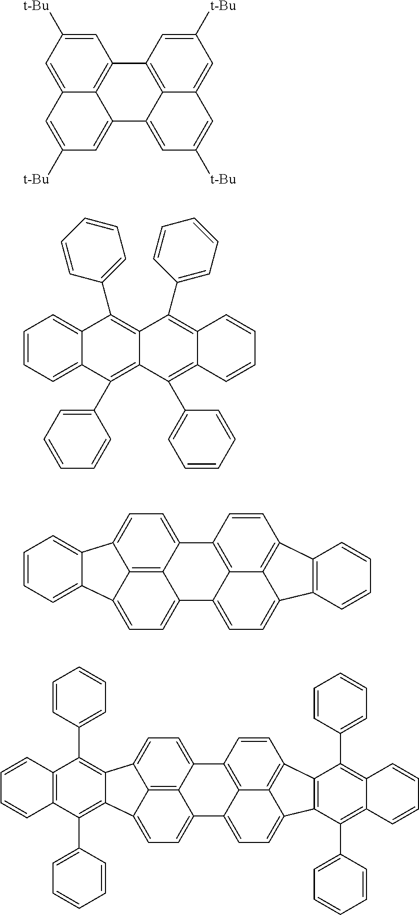

where the structure may be unsubstituted or further substituted with alkyl or aryl groups, and the compound is from 10% to 100% deuterated.

In some embodiments, the dopant is selected from the group consisting of a non-polymeric spirobifluorene compound and a fluoranthene compound.

In some embodiments, the electroluminescent material is a compound having aryl amine groups. In some embodiments, the electroluminescent material is selected from the formulae below:

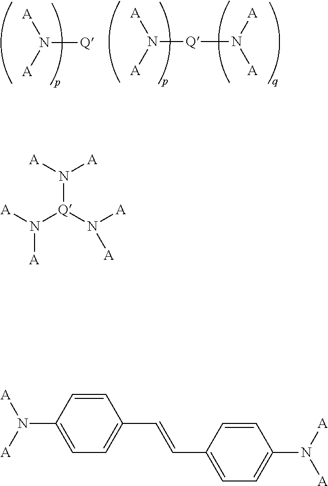

where:

A is the same or different at each occurrence and is an aromatic group having from 3-60 carbon atoms;

Q′ is a single bond or an aromatic group having from 3-60 carbon atoms;

p and q are the same or different and each is an integer from 1-6. In the above formulae the values of p and q may be limited by the available bonding sites on the core Q′ group.

In some embodiments of the above formulae, the compound is at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated.

In some embodiments of the above formula, at least one of A and Q′ in each formula has at least three condensed rings. In some embodiments, p and q are equal to 1.

In some embodiments, Q′ is a styryl or styrylphenyl group.

In some embodiments, Q′ is an aromatic group having at least two condensed rings. In some embodiments, Q′ is selected from the group consisting of naphthalene, anthracene, benz[a]anthracene, dibenz[a,h]anthracene, fluoranthene, fluorene, spirofluorene, tetracene, chrysene, pyrene, tetracene, xanthene, perylene, coumarin, rhodamine, quinacridone, rubrene, substituted derivatives thereof, and deuterated analogs thereof.

In some embodiments, A is selected from the group consisting of phenyl, biphenyl, tolyl, naphthyl, naphthylphenyl, anthracenyl, and deuterated analogs thereof.

In some embodiments, the electroluminescent material has the structure

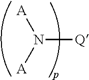

where A is an aromatic group, p is 1 or 2, and Q′ is selected from the group consisting of:

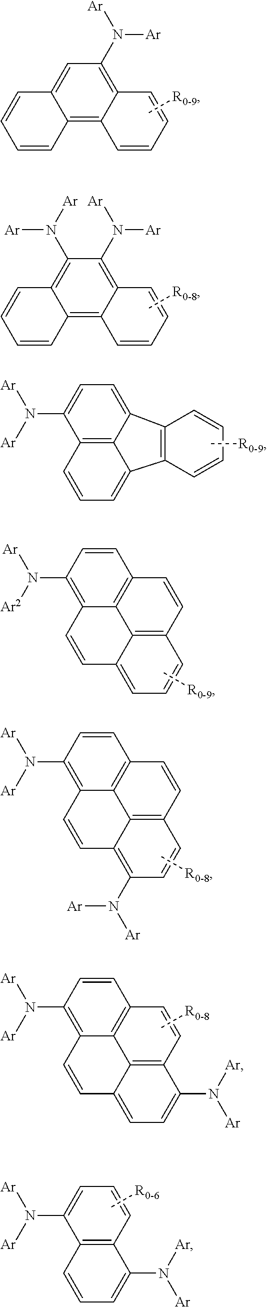

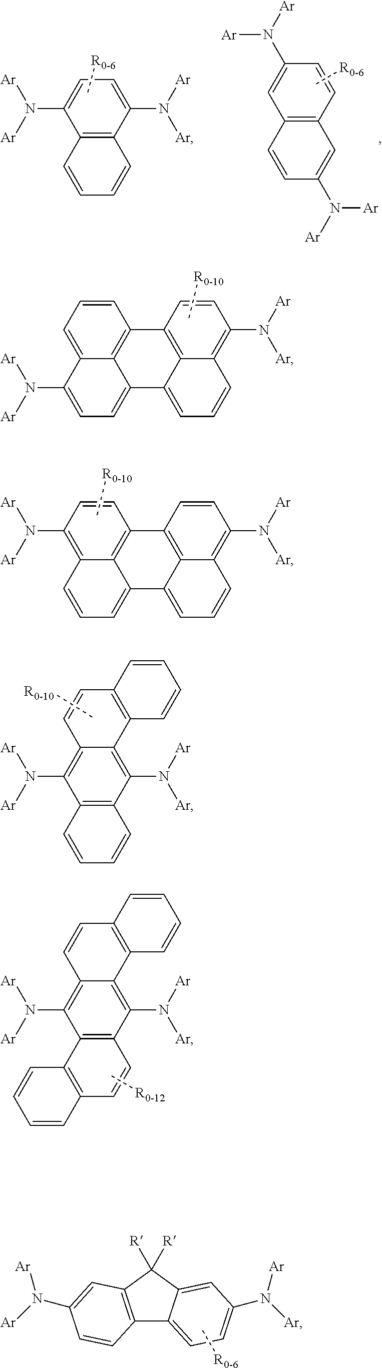

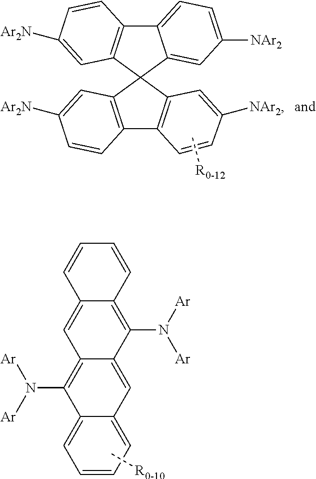

wherein:
R is the same or different at each occurrence and is selected from the group consisting of D, alkyl, alkoxy and aryl, where adjacent R groups may be joined together to form a 5- or 6-membered aliphatic ring;
Ar is the same or different and is selected from the group consisting of aryl groups;
wherein the compound has at least one D.
   The dashed line in the formula is intended to indicate that the R group, when present, can be at any site on the core Q′ group.

In some embodiments, the electroluminescent material has the formula below:

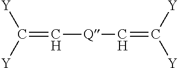

where:

Y is the same or different at each occurrence and is an aromatic group having 3-60 carbon atoms;

Q″ is an aromatic group, a divalent triphenylamine residue group, or a single bond.

In some embodiments, the electroluminescent is an aryl acene or a deuterated analog thereof. In some embodiments, the electroluminescent material is a non-symmetrical aryl acene or a deuterated analog thereof.

In some embodiments, the electroluminescent material is an anthracene derivative having Formula IV:

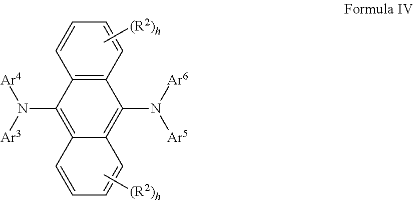

wherein:
R² is the same or different at each occurrence and is selected from the group consisting of D, alkyl, alkoxy and aryl, where adjacent R² groups may be joined together to form a 5- or 6-membered aliphatic ring;
Ar³ through Ar⁶ are the same or different and are selected from the group consisting of aryl groups and deuterated aryl groups;
h is the same or different at each occurrence and is an integer from 0 to 4;
wherein there is at least one D.

In some embodiments, the electroluminescent material is a chrysene derivative having Formula V:

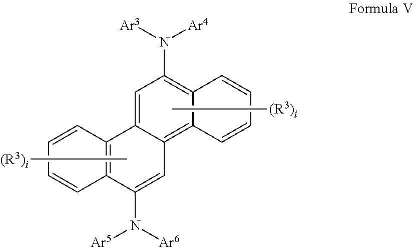

wherein:
R³ is the same or different at each occurrence and is selected from the group consisting of D, alkyl, alkoxy aryl, fluoro, cyano, nitro, —SO₂R⁴, where R⁴ is alkyl or perfluoroalkyl, where adjacent R³ groups may be joined together to form a 5- or 6-membered aliphatic ring;
Ar³ through Ar⁶ are the same or different and are selected from the group consisting of aryl groups; and
i is the same or different at each occurrence and is an integer from 0 to 5;
wherein there is at least one D.

In some embodiments of Formulae IV and V, the deuteration is on a substituent group on an aryl ring. The aryl group having a deuterated substituent group can be the core anthracene group of Formula IV or the core chrysene group of Formula V; or an aryl on the nitrogen; or a substituent aryl group. In some embodiments, the deuterated substituent group on an aryl ring is selected from alkyl, aryl, alkoxy, and aryloxy. In some embodiments, the substituent groups are at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated.

In some embodiments of Formulae IV and V, the deuteration is on any one or more of the aryl groups Ar³ through Ar⁶. In this case, at least one of Ar³ through Ar⁶ is a deuterated aryl group. In some embodiments, Ar³ through Ar⁶ are at least 10% deuterated. By this it is meant that at least 10% of all the available H bonded to aryl C in Ar³ through Ar⁶ are replaced with D. In some embodiments, each aryl ring will have some D. In some embodiments, some, and not all of the aryl rings have D. In some embodiments, Ar³ through Ar⁶ are at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated.

In some embodiments of Formulae IV and V, the deuteration is present on both the substituent groups (R² or R³) and the aryl groups. In some embodiments, the compound of Formulae IV and V is at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated.

In some embodiments of Formulae IV and V, the compound is symmetrical with respect to the amino groups. In this case, Ar³=Ar⁵, and Ar⁴=Ar⁶, where Ar³ may be the same as or different from Ar⁴.

In some embodiments of Formulae IV and V, the compound is not symmetrical with respect to the amino groups. In this case, Ar³ is different from both Ar⁵ and Ar⁶. Ar³ may be the same as or different from Ar⁴, and Ar⁴ may be the same as or different from each of Ar⁵ and Ar⁶.

In some embodiments of Formula IV, both h=0.

In some embodiments of Formula IV, at least one h is greater than 0. In some embodiments, at least one R² is a hydrocarbon alkyl. In some embodiments, R² is a deuterated alkyl. In some embodiments, R² is selected from a branched hydrocarbon alkyl and a cyclic hydrocarbon alkyl.

In some embodiments of Formula IV, both h=4 and R² is D.

In Formula V, the bond to (R³)ᵢ is intended to indicate that the R³ group can be at any one or more sites on the two fused rings.

In some embodiments of Formula V, both i=0.

In some embodiments of Formula V, at least one i is greater than 0. In some embodiments, at least one R³ is a hydrocarbon alkyl. In some embodiments, R³ is selected from a branched hydrocarbon alkyl and a cyclic hydrocarbon alkyl.

In some embodiments of Formula V, both i=5 and R³ is D.

In some embodiments, at least one of Ar³ through Ar⁶ has Formula a or Formula b as shown above.

In some embodiments, Ar³ through Ar⁶ is selected from the group consisting of phenyl, biphenyl, terphenyl, naphthyl, phenylnapthyl, naphthylphenyl, and binaphthyl.

In some embodiments, Ar³ through Ar⁶ are perdeuterated.

In some embodiments, Ar³ through Ar⁶ are perdeuterated, except for one or more alkyl groups on a terminal aryl.

Some non-limiting examples of deuterated electroluminescent materials are shown as E1 through E13 below:

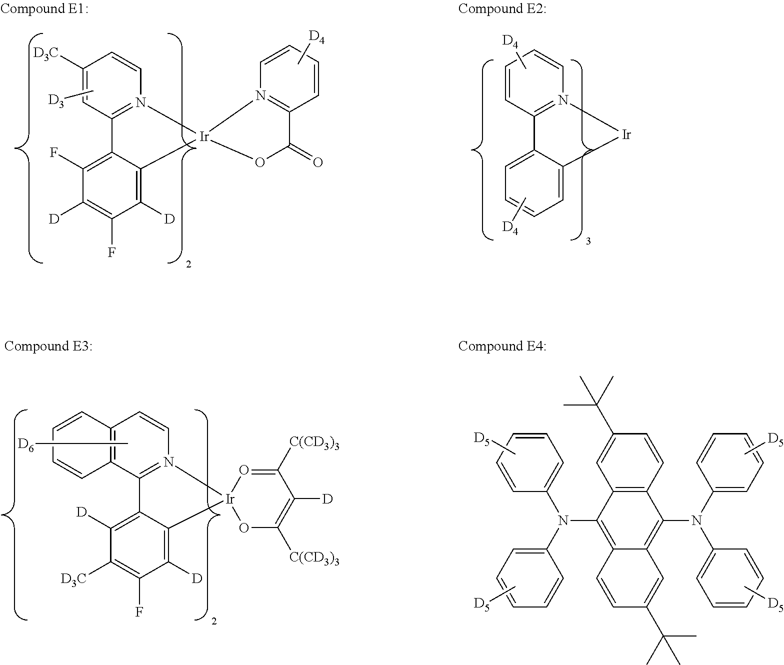

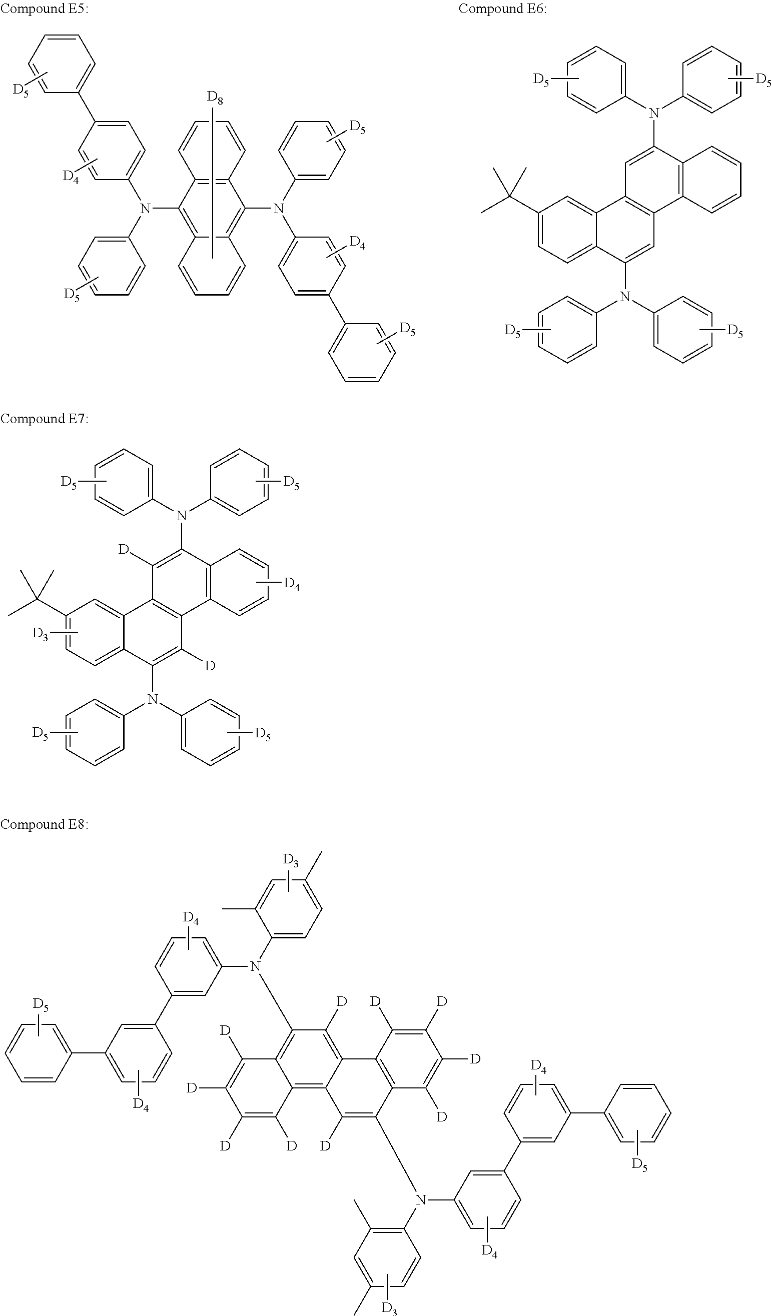

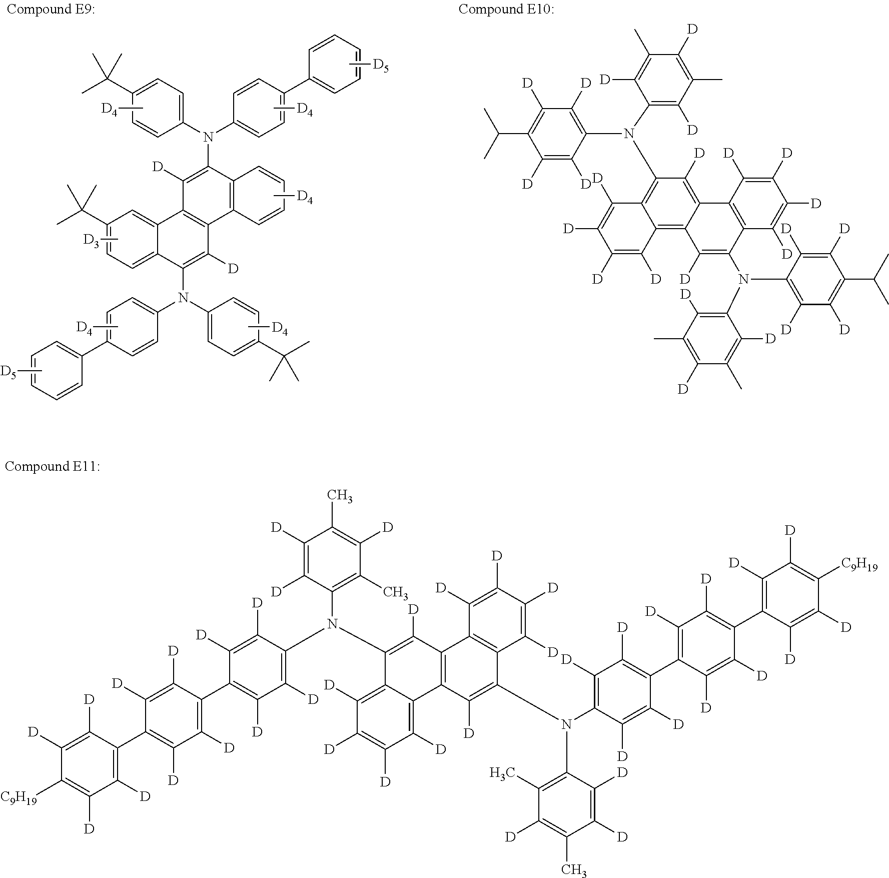

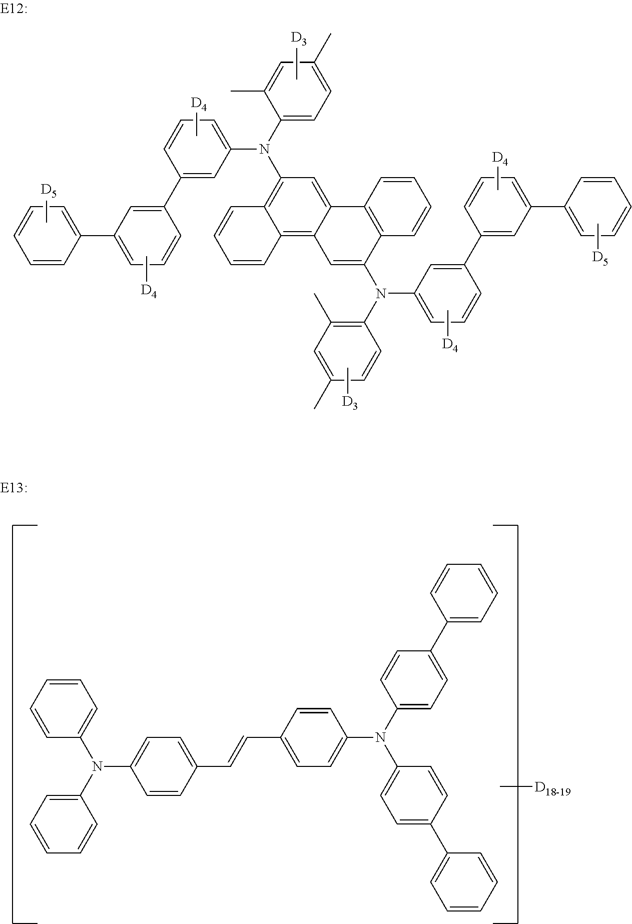

b. Host

A single host compound or two or more host compounds may be present as the host material. Non-deuterated examples of host compounds have been disclosed in, for example, U.S. Pat. No. 7,362,796, and published US patent application 2006-0115676.

In some embodiments, the host material is at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated. In some embodiments, the host material is 100% deuterated.

In some embodiments, the host material is selected from the group consisting of anthracenes, chrysenes, pyrenes, phenanthrenes, triphenylenes, phenanthrolines, naphthalenes, anthracenes, quinolines, isoquinolines, quinoxalines, phenylpyridines, dibenzofurans, difuranobenzenes, metal quinolinate complexes, indolocarbazoles, benzimidazoles, triazolopyridines, diheteroarylphenyls, substituted derivatives thereof, deuterated analogs thereof, and combinations thereof. In some embodiments, the aforementioned host compounds have a substituent selected from the group consisting of aryl, alkyl, and deuterated analogs thereof. In some embodiments, the heteroaryl group is selected from the group consisting of pyridine, pyrazine, pyrimidine, pyridazine, triazines, tetrazines, quinazoline, quinoxaline, naphthylpyridines, heterobiaryl analogs thereof, heterotriaryl analogs thereof, and deuterated analogs thereof.

In some embodiments, the host is selected from structures 1-9, below, or a deuterated analog thereof.

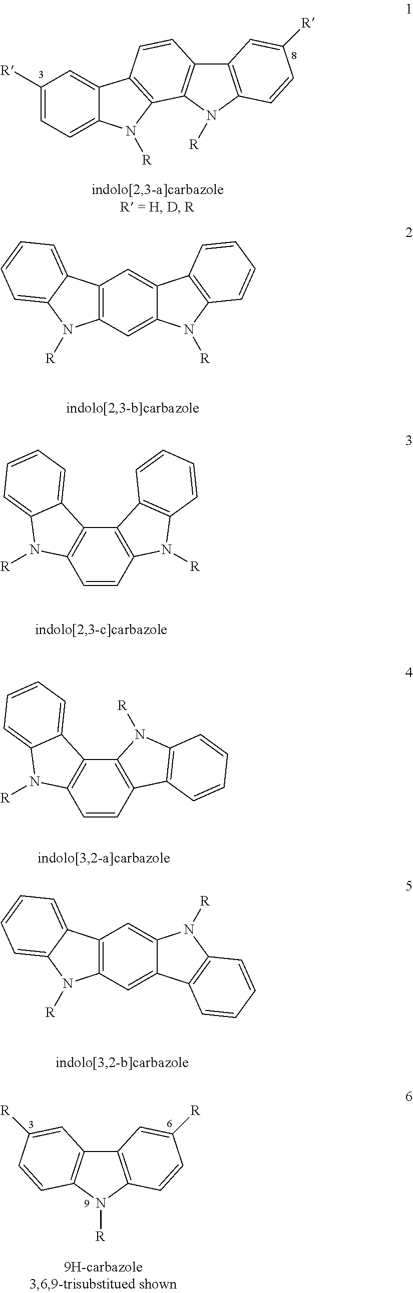

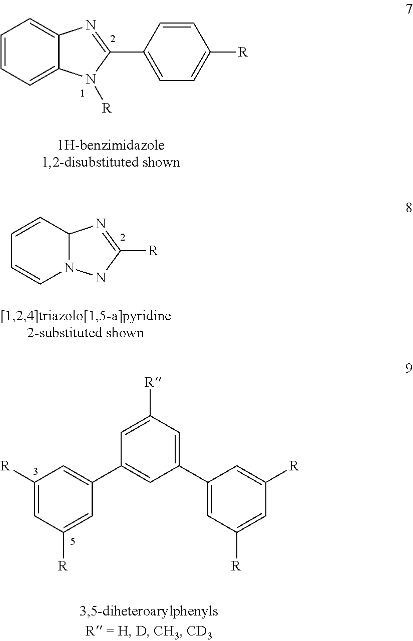

where R is selected from aryl, heteroaryl, and alkyl. In some embodiments, the heteroaryl group is selected from structures 10-20 below, or a deuterated analog thereof.

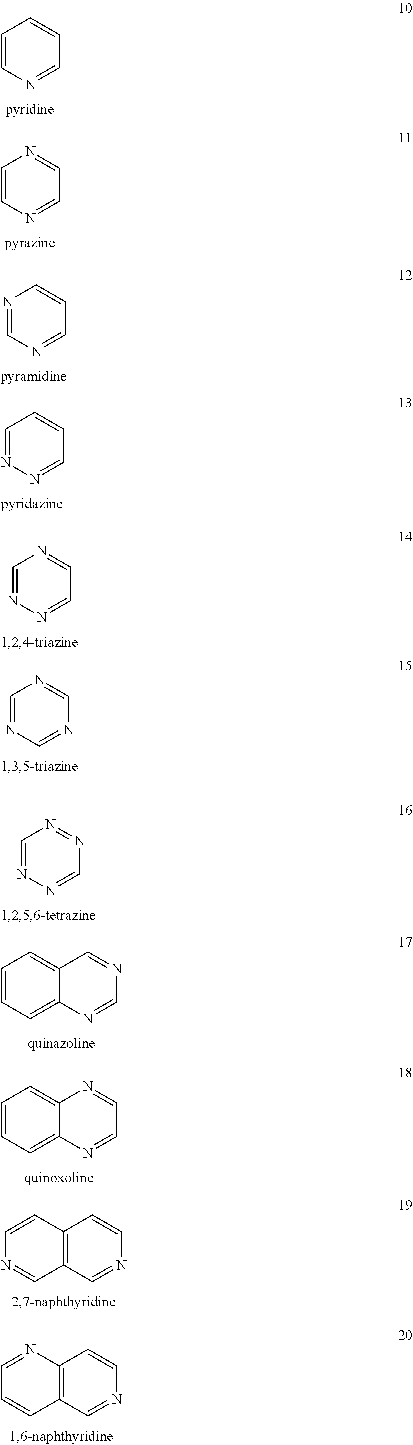

In some embodiments, the group is a heterobiaryl derivative or a heterotriaryl derivative.

In some embodiments, the host material has one of the structures shown below

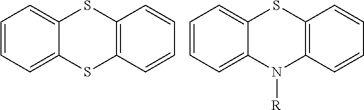

where R is selected from aryl, heteroaryl, and alkyl and the compound may be deuterated. In some embodiments, the above structures are further substituted with aryl or heteroaryl groups. In some embodiments, the heteroaryl group is selected from structures 10-20 above, or a deuterated analog thereof.

In some embodiments, the host material has Formula VI:

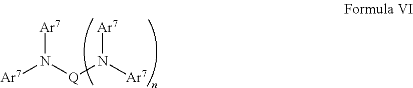

where:
Ar⁷ is the same or different at each occurrence and is an aryl group;
Q is selected from the group consisting of multivalent aryl groups and

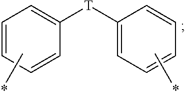

T is selected from the group consisting of (CR′)ₐ, SiR₂, S, SO₂, PR, PO, PO₂, BR, and R;
R is the same or different at each occurrence and is selected from the group consisting of alkyl, and aryl;
R′ is the same or different at each occurrence and is selected from the group consisting of H, D, and alkyl;
a is an integer from 1-6; and
n is an integer from 0-6.
   While n can have a value from 0-6, it will be understood that for some Q groups the value of n is restricted by the chemistry of the group. In some embodiments, n is 0 or 1.

In some embodiments of Formula VI, adjacent Ar groups are joined together to form rings such as carbazole. In Formula VI, “adjacent” means that the Ar groups are bonded to the same N.

In some embodiments, Ar⁷ is independently selected from the group consisting of phenyl, biphenyl, terphenyl, quaterphenyl, naphthyl, phenanthryl, naphthylphenyl, phenanthrylphenyl, and deuterated analogs thereof. Analogs higher than quaterphenyl, having 5-10 phenyl rings, can also be used.

In some embodiments, at least one of Ar¹ has at least one substituent. Substituent groups can be present in order to alter the physical or electronic properties of the host material. In some embodiments, the substituents improve the processibility of the host material. In some embodiments, the substituents increase the solubility and/or increase the Tg of the host material. In some embodiments, the substituents are selected from the group consisting of D, alkyl groups, alkoxy groups, silyl groups, siloxane, and combinations thereof.

In some embodiments, Q is an aryl group having at least two fused rings. In some embodiments, Q has 3-5 fused aromatic rings. In some embodiments, Q is selected from the group consisting of anthracenes, chrysenes, pyrenes, phenanthrenes, triphenylenes, phenanthrolines, naphthalenes, anthracenes, quinolines, isoquinolines, quinoxalines, phenylpyridines, dibenzofurans, difuranobenzenes, indolocarbazoles, substituted derivatives thereof, and deuterated analogs thereof.

In some embodiments, the host compound has Formula VII:

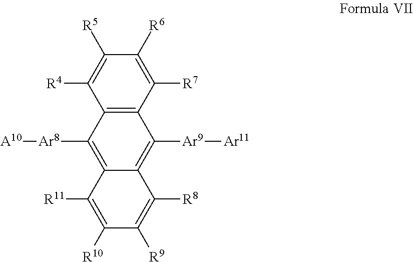

wherein:
R⁴ through R¹¹ are the same or different at each occurrence and are selected from the group consisting of H, D, alkyl, alkoxy, aryl, aryloxy, siloxane, and silyl;
Ar⁸ and Ar⁹ are the same or different and are selected from the group consisting of aryl groups; and
Ar¹⁰ and Ar¹¹ are the same or different and are selected from the group consisting of H, D, and aryl groups,
wherein there is at least one D.

In some embodiments of Formula VII, the at least one D is on a substituent group on an aryl ring. In some embodiments, the substituent group is selected from alkyl and aryl.

In some embodiments of Formula VII, at least one of R⁴ through R¹¹ is D. In some embodiments, at least two of R⁴ through R¹¹ are D. In some embodiments, at least three are D; in some embodiments, at least four are D; in some embodiments, at least five are D; in some embodiments, at least six are D; in some embodiments, at least seven are D. In some embodiments, all of R⁴ through R¹¹ are D.

In some embodiments, R⁴ through R¹¹ are selected from H and D. In some embodiments, one of R⁴ through R¹¹ are D and seven are H. In some embodiments, two of R⁴ through R¹¹ are D and six are H. In some embodiments, three of R⁴ through R¹¹ are D and five are H. In some embodiments, four of R⁴ through R¹¹ are D, and four are H. In some embodiments, five of R⁴ through R¹¹ are D and three are H. In some embodiments, six of R⁴ through R¹¹ are D and two are H. In some embodiments, seven of R⁴ through R¹¹ are D and one is H. In some embodiments, eight of R⁴ through R¹¹ are D.

In some embodiments, at least one of R⁴ through R¹¹ is selected from alkyl, alkoxy, aryl, aryloxy, siloxane, and silyl, and the remainder of R⁴ through R¹¹ are selected from H and D. In some embodiments, R⁵ is selected from alkyl, alkoxy, aryl, aryloxy, siloxane, and silyl. In some embodiments, R⁵ is selected from alkyl and aryl. In some embodiments, R⁵ is selected from deuterated alkyl and deuterated aryl. In some embodiments, R⁵ is selected from deuterated aryl having at least 10% deuteration. In some embodiments, R⁵ is selected from deuterated aryl having at least 20% deuteration; in some embodiments, at least 30% deuteration; in some embodiments, at least 40% deuteration; in some embodiments, at least 50% deuteration; in some embodiments, at least 60% deuteration; in some embodiments, at least 70% deuteration; in some embodiments, at least 80% deuteration; in some embodiments, at least 90% deuteration. In some embodiments, R² is selected from deuterated aryl having 100% deuteration.

In some embodiments of Formula VII, at least one of Ar⁸ through Ar¹¹ is a deuterated aryl. In some embodiments, Ar¹⁰ and Ar¹¹ are selected from D and deuterated aryls.

In some embodiments of Formula VII, Ar⁸ through Ar¹¹ are at least 10% deuterated. In some embodiments of Formula VII, Ar⁸ through Ar¹¹ are at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated.

In some embodiments, the compound of Formula VII is at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated. In some embodiments, the compound is 100% deuterated.

In some embodiments, Ar⁸ and Ar⁹ are selected from the group consisting of phenyl, naphthyl, phenanthryl, anthracenyl, and deuterated analogs thereof. In some embodiments, Ar⁸ and Ar⁹ are selected from the group consisting of phenyl, naphthyl, and deuterated analogs thereof.

In some embodiments, Ar¹⁰ and Ar¹¹ are selected from the group consisting of phenyl, naphthyl, phenanthryl, anthracenyl, phenylnaphthylene, naphthylphenylene, deuterated derivatives thereof, and a group having Formula a or Formula b, as shown above.

In some embodiments, at least one of Ar⁸ through Ar¹¹ is a heteroaryl group. In some embodiments, the heteroaryl group is deuterated. In some embodiments, the heteroaryl group is at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated. In some embodiments, the heteroaryl group is 100% deuterated. In some embodiments, the heteroaryl group is selected from carbazole, benzofuran, dibenzofuran, and deuterated derivatives thereof.

In some embodiments of Formula VII, at least one of R⁴ through R¹¹ is D and at least one of Ar⁸ through Ar¹¹ is a deuterated aryl. In some embodiments, the compound is at least 10% deuterated. In some embodiments, the compound is at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated. In some embodiments, the compound is 100% deuterated.

In some embodiments, the host compound has Formula VIII

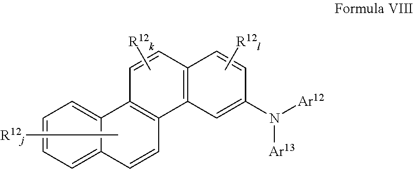

where:
R¹² is the same or different at each occurrence and is selected from the group consisting of D, alkyl, alkoxy, silyl, and siloxane, or adjacent R¹² groups may be joined together to form a 5- or 6-membered aliphatic ring,
Ar¹² and Ar¹³ are the same or different and are aryl groups,
j is an integer from 0 to 6;
k is an integer from 0 to 2; and
l is an integer from 0 to 3;
wherein there is at least one D.
In some embodiments, R¹² is D and at least one of j, k, and l is greater than 0. In some embodiments, R¹² is D and j, k, and l are all greater than 0. In some embodiments R¹² is D, j=5-6, k=1-2 and l=2-3.

In some embodiments, at least one R¹² is a branched alkyl group. In some embodiments, the branched alkyl group is 2-propyl group, a t-butyl group, or a deuterated analog thereof.

In some embodiments, Ar¹² and Ar¹³ are phenyl groups having a substituent selected from the group consisting of D, alkyl, silyl, phenyl, naphthyl, N-carbazolyl, and fluorenyl.

In some embodiments, Ar¹² and Ar¹³ are selected from the group consisting of phenyl, biphenyl, naphthyl, phenanthryl, anthracenyl, 4-naphthylphenyl, 4-phenanthrylphenyl, deuterated analogs thereof, and a group having Formula a or Formula b, as shown above.

In some embodiments, the host compound has Formula IX

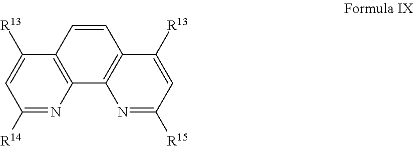

where:
R¹³ is the same or different and is selected from the group consisting of phenyl, biphenyl, naphthyl, naphthylphenyl, triphenylamino, carbazolylphenyl, and deuterated analogs thereof;
and one of the following conditions is met:
(i) R¹⁴=R¹⁵ and is selected from the group consisting of H, D, phenyl, biphenyl, naphthyl, naphthylphenyl, arylanthracenyl, phenanthryl, triphenylamino, carbazolylphenyl, and deuterated analogs thereof; or
(ii) R¹⁴ is selected from the group consisting of H, D, phenyl, and deutero-phenyl;
   R¹⁵ is selected from the group consisting of phenyl, biphenyl, naphthyl, naphthylphenyl, arylanthracenyl, phenanthryl, triphenylamino, carbazolylphenyl, and deuterated analogs thereof;
wherein there is at least one D.

In some embodiments, the phenanthroline compounds are symmetrical, where both R¹³ are the same and R¹⁴=R¹⁵. In some embodiments, R¹³=R¹⁴=R¹⁵. In some embodiments, the phenanthroline compounds are non-symmetrical, where the two R¹³ groups are different, R¹⁴≠R¹⁵, or both.

In some embodiments, the R¹³ groups are the same and are selected from the group consisting of biphenyl, naphthyl, naphthylphenyl, triphenylamino, carbazolylphenyl, and deuterated analogs thereof. In some embodiments, the R¹³ groups are selected from the group consisting of phenyl, triphenylamino, carbazolylphenyl, and deuterated analogs thereof. In some embodiments, the R¹³ groups are selected from the group consisting of 4-triphenylamino, m-carbazolylphenyl, and deuterated analogs thereof.

In some embodiments, R¹³=R¹⁴ and is selected from the group consisting of triphenylamino, naphthylphenyl, arylanthracenyl, m-carbazolylphenyl, and deuterated analogs thereof.

In some embodiments, the host has Formula X or Formula XI

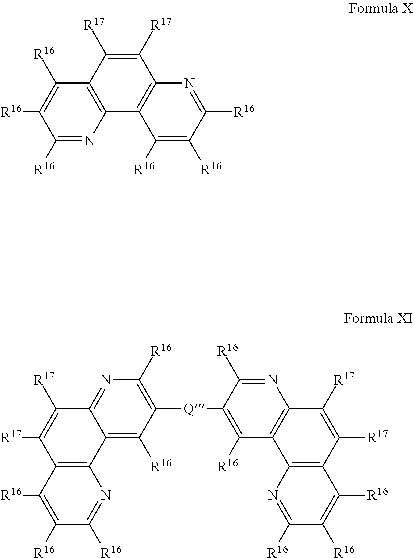

where:
R¹⁶ is the same or different at each occurrence and is selected from the group consisting of hydrogen, deuterium, phenyl, biphenyl, naphthyl, naphthylphenyl, phenanthryl, triphenylamino, carbazolyl, carbazolylphenyl, and deuterated derivatives thereof;
R¹⁷ is H or D; and
Q′″ is an aryl group;
wherein there is at least one D.
   In some embodiments, Q′″ is selected from the group consisting of phenylene, naphthylene, biphenylene, binaphthylene, and deuterated derivatives thereof. In some embodiments, Q′″ is selected from the group consisting of 1,4-phenylene, 2,6-naphthylene, 4,4′-biphenylene, 4,4′-(1,1′-binaphthylene), and deuterated derivatives thereof.

In one embodiment, the host is a deuterated indolocarbazole having Formula XII or Formula XIII:

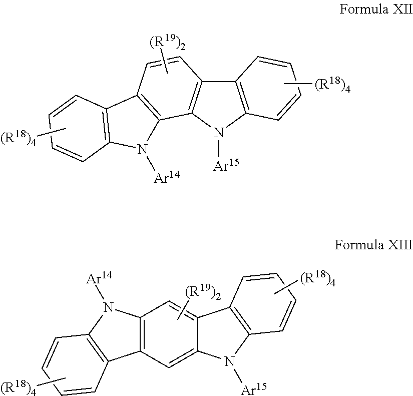

wherein:
Ar¹⁴ is an aromatic electron transporting group;
Ar¹⁵ is selected from the group consisting of aryl groups and aromatic electron transporting groups; and
R¹⁸ and R¹⁹ are the same or different at each occurrence and are selected from the group consisting of H, D and aryl;
wherein the compound has at least one D.

In some embodiments of Formula XII and Formula XIII, deuterium is present on a moiety selected from the group consisting of the indolocarbazole core, an aryl ring, a substituent group on an aryl ring, and combinations thereof.

Ar¹⁴ is an aromatic electron transporting group. In some embodiments, the aromatic electron transporting group is a nitrogen-containing heteroaromatic group. Some examples of nitrogen-containing heteroaromatic groups which are electron transporting include, but are not limited to those shown below.

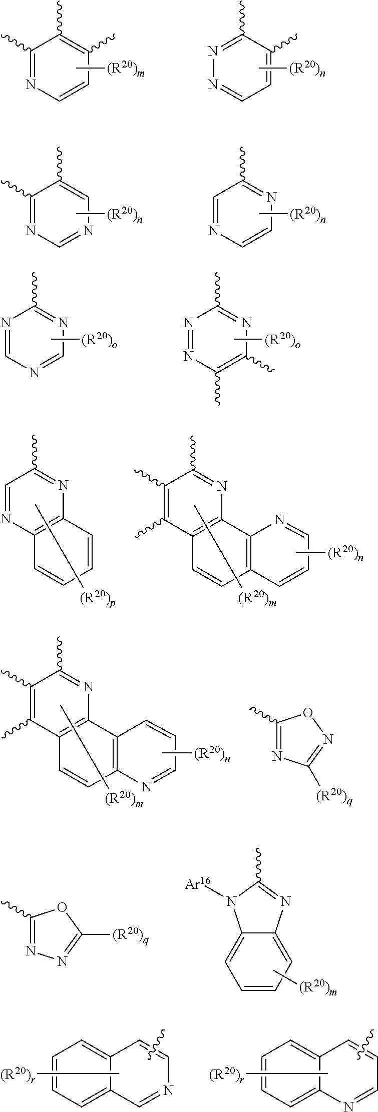

In the above formulae:
Ar¹⁶ is an aryl group;
R²⁰ is the same or different at each occurrence and is selected from the group consisting of D, alkyl, alkoxy, aryl, aryloxy, siloxane, and silyl;
m is an integer from 0-4;
n is an integer from 0-3;
o is an integer from 0-2;
p is an integer from 0-5;
q is 0 or 1; and
r is an integer from 0-6.
   The group can be bonded to the nitrogen on the core at any of the positions indicated with the wavy line.

In some embodiments, two or more of the same or different electron-withdrawing substituents are bonded together to form oligomeric substituents. In some embodiments, R²⁰ is selected from the group consisting of D and aryl. In some embodiments, R²⁰ is a nitrogen-containing heteroaromatic electron transporting group.

In some embodiments, Ar¹⁵ is an aromatic electron transporting group as discussed above. In some embodiments, Ar¹⁵ is selected from the group consisting of phenyl, naphthyl, phenanthryl, anthracenyl, phenylnaphthylene, naphthylphenylene, deuterated derivatives thereof, and a group having Formula a or Formula b, as discussed above.

In some embodiments, the host material is selected from the group consisting of deuterated diarylanthracenes, deuterated aminochrysenes, deuterated diarylchrysenes, deuterated diarylpyrenes, deuterated indolocarbazoles, deuterated phenanthrolines, and combinations thereof.

Some non-limiting examples of deuterated host compounds include Compounds H1 through H17, shown below.

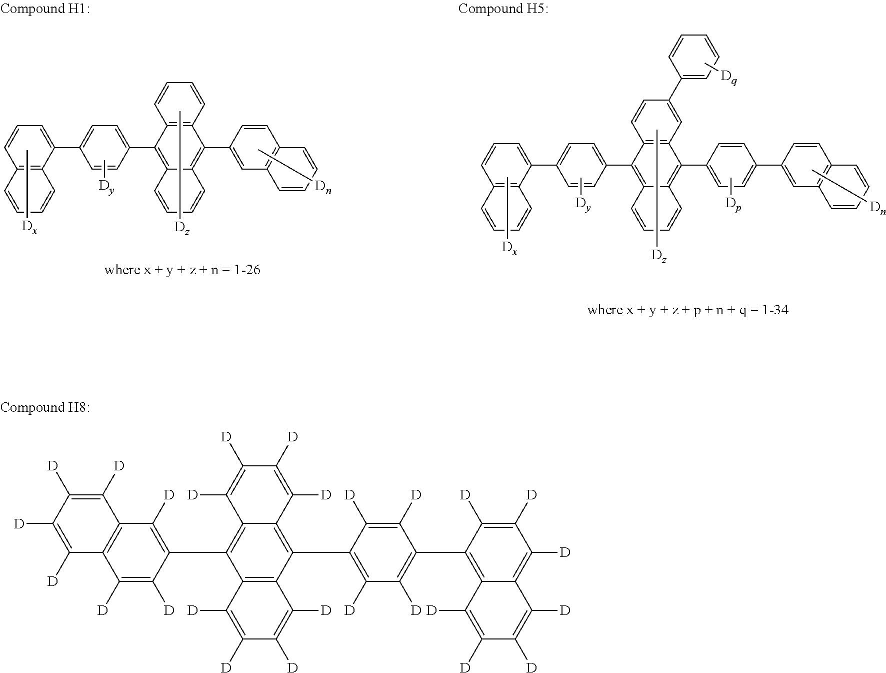

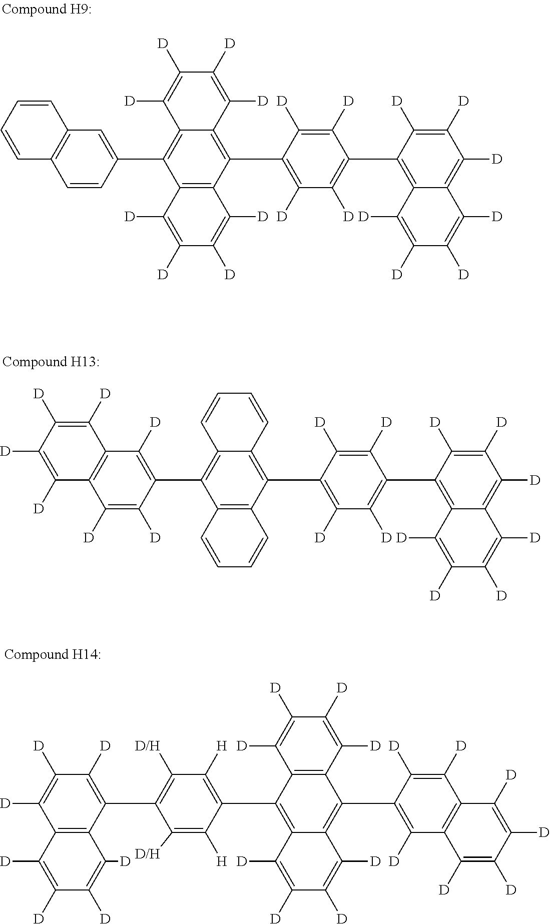

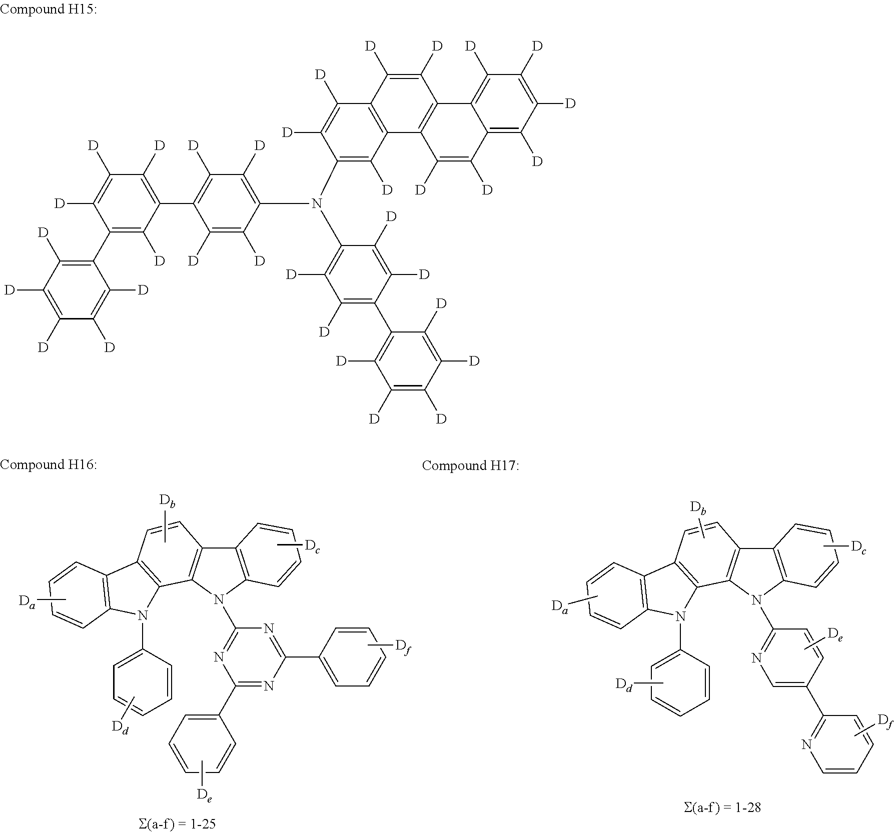

### 5. Electron Transport Layer

The electron transport layer 150 comprises electron transport material. The term “electron transport” when referring to a layer, material, member, or structure, is intended to mean that such layer, material, member, or structure facilitates migration of negative charges through the thickness of such layer, material, member, or structure with relative efficiency and small loss of charge. Although light-emitting materials may also have some electron transport properties, the terms “electron transport layer, material, member, or structure” are not intended to include a layer, material, member, or structure whose primary function is light emission.

Electron transport materials may be polymers, oligomers, or small molecules. They may be vapor deposited or deposited from liquids, which may be in the form of solutions, dispersions, suspensions, emulsions, colloidal mixtures, or other compositions.

In some embodiments, the electron transport layer comprises deuterated material. In some embodiments, the electron transport material is at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated.

In some embodiments, the electron transport layer 150 comprises a deuterated phenanthroline derivative having Formula IX, Formula X, or Formula XI, as discussed above. In some embodiments, the electron transport layer 150 consists essentially of a deuterated phenanthroline derivative having Formula IX, Formula X, or Formula XI.

In some embodiments, the electron transport layer 150 comprises a deuterated indolocarbazole derivative having Formula XII or Formula XIII, as discussed above. In some embodiments, the electron transport layer 150 consists essentially of a deuterated indolocarbazole derivative having Formula XII or Formula XIII.

In some embodiments, the electron transport layer comprises a material selected from the group consisting of deuterated benzimidazoles, deuterated triazolopyridines and deuterated diheteroarylphenyls.

In some embodiments, the electron transport layer 150 comprises a deuterated metal chelated oxinoid compound. Examples of such materials include deuterated metal quinolate derivatives such as deuterated tris(8-hydroxyquinolato)aluminum (d-AIQ), deuterated bis(2-methyl-8-quinolinolato)(p-phenylphenolato) aluminum (d-BAlq), deuterated tetrakis-(8-hydroxyquinolato)hafnium (d-HfQ) and deuterated tetrakis-(8-hydroxyquinolato)zirconium (d-ZrQ).

In some embodiments, the electron transport layer comprises an electron transport material selected from the group consisting of deuterated phenanthrolines, deuterated indolocarbazoles, deuterated benzimidazoles, deuterated triazolopyridines, deuterated diheteroarylphenyls, deuterated metal quinolates, and combinations thereof. In some embodiments, the electron transport layer consists essentially of an electron transport material selected from the group consisting of deuterated phenanthrolines, deuterated indolocarbazoles, deuterated benzimidazoles, deuterated triazolopyridines, deuterated diheteroarylphenyls, deuterated metal quinolates, and combinations thereof.

Examples of other electron transport materials which can be used in the electron transport layer 150, include azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; triazines; fullerenes; deuterated analogs of any of the preceding material; and mixtures thereof. In some embodiments, the electron transport layer further comprises an n-dopant. N-dopant materials are well known. The n-dopants include, but are not limited to, Group 1 and 2 metals; Group 1 and 2 metal salts, such as LiF, CsF, and Cs₂CO₃; Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals. The n-dopants may also be deuterated.

Some non-limiting examples of deuterated electron transport compounds include Compounds ET1 through ET4, shown below.

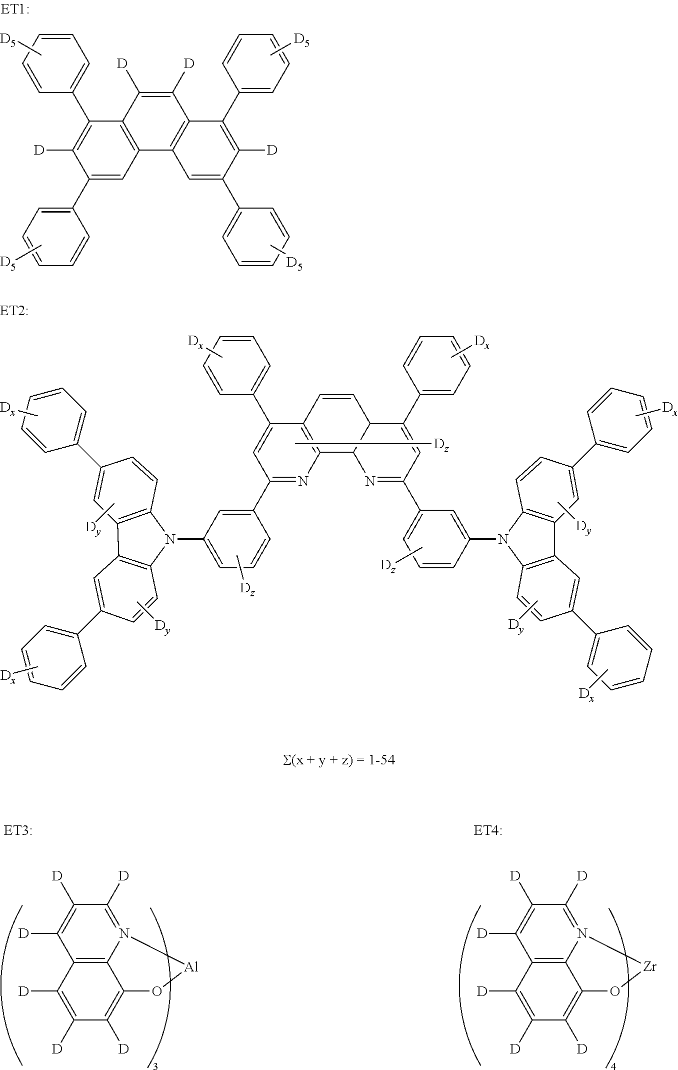

### 6. Chemical Containment

To make a display with full-color images, each display pixel is divided into three subpixels, each emitting one of the three primary display colors, red, green, and blue. When the different color are applied by a liquid deposition technique, there is a need to prevent the spreading of the liquid colored materials (i.e., inks) and color mixing, from one subpixel to the next.

One way to prevent color mixing is to provide a chemical containment layer prior to the application of the colored inks. The term “chemical containment layer” is intended to mean a patterned layer that contains or restrains the spread of a liquid material by surface energy effects rather than physical barrier structures. The term “contained” when referring to a layer, is intended to mean that the layer does not spread significantly beyond the area where it is deposited. The term “surface energy” is the energy required to create a unit area of a surface from a material. A characteristic of surface energy is that liquid materials with a given surface energy will not wet surfaces with a lower surface energy.

In some embodiments, the chemical containment layer comprises deuterated material. In some embodiments, the chemical containment material is at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated.

In some embodiments, for devices made starting from the anode side, the chemical containment layer is applied over the hole injection layer and contains both the hole transport layer and the electroluminescent layer. In some embodiments, the chemical containment layer is applied over the hole transport layer and contains the electroluminescent layer. For devices made starting from the cathode side, the chemical containment layer can be applied over the electron injection layer or the electron transport layer.

In some embodiments, the chemical containment layer is formed on a first layer using a priming layer, where the priming layer has a surface energy that is significantly different than the surface energy of the first layer. The priming layer is applied overall on the first layer. The priming layer is then exposed to radiation in a pattern to form exposed areas and unexposed areas. The priming layer is then developed to effectively remove the priming layer from either the exposed areas or the unexposed areas. The result is a patterned priming layer on the first layer. The patterned priming layer is the chemical containment layer. By the terms “effectively remove” and “effective removal” it is meant that the priming layer is essentially completely removed in either the exposed or unexposed areas. The priming layer may also be partially removed in the other areas, so that the remaining pattern of priming layer may be thinner than the original priming layer.

In some embodiments, the pattern of priming layer has a surface energy that is higher than the surface energy of the first layer. A second layer is formed by liquid deposition over and on the pattern of priming layer on the first layer.

In some embodiments, the pattern of priming layer has a surface energy that is lower than the surface energy of the first layer. A second layer is formed by liquid deposition over and on the first layer in the areas where the priming layer has been removed. This process and non-deuterated materials have been described in published U.S. patent application US 2007/0205409.

One way to determine the relative surface energies, is to compare the contact angle of a given liquid on the first organic layer to the contact angle of the same liquid on the priming layer after exposure and development (hereinafter referred to as the “developed priming layer”). The contact angle increases with decreasing surface energy. A variety of manufacturers make equipment capable of measuring contact angles.

In some embodiments, the surface energy of the first layer is layer than the surface energy of the priming layer. In some embodiments, the first layer has a contact angle with anisole of greater than 40° C.; in some embodiments, greater than 50°; in some embodiments, greater than 60°; in some embodiments, greater than 70°. In some embodiments, the developed priming layer, has a contact angle with anisole of less than 30°; in some embodiments, less than 20°; in some embodiments, less than 10°. In some embodiments, for a given solvent, the contact angle with the developed priming layer is at least 20° lower than the contact angle with the first layer; In some embodiments, for a given solvent, the contact angle with the developed priming layer is at least 30° lower than the contact angle with the first layer; In some embodiments, for a given solvent, the contact angle with the developed priming layer is at least 40° lower than the contact angle with the first layer.

The priming layer comprises a composition which, when exposed to radiation reacts to form a material that is either more or less removable from the underlying first layer, relative to unexposed priming material. This change must be enough to allow physical differentiation of the exposed and non-exposed areas and development.

In one embodiment, the priming layer comprises a radiation-hardenable composition. In this case, when exposed to radiation, the priming layer can become less soluble or dispersable in a liquid medium, less tacky, less soft, less flowable, less liftable, or less absorbable. Other physical properties may also be affected.

In one embodiment, the priming layer consists essentially of one or more radiation-sensitive materials. In one embodiment, the priming layer consists essentially of a material which, when exposed to radiation, hardens, or becomes less soluble, swellable, or dispersible in a liquid medium, or becomes less tacky or absorbable. In one embodiment, the priming layer consists essentially of a material having radiation polymerizable groups. Examples of such groups include, but are not limited to olefins, acrylates, methacrylates and vinyl ethers. In one embodiment, the priming material has two or more polymerizable groups which can result in crosslinking.

In one embodiment, the priming layer consists essentially of at least one reactive material and at least one radiation-sensitive material. The radiation-sensitive material, when exposed to radiation, generates an active species that initiates the reaction of the reactive material. Examples of radiation-sensitive materials include, but are not limited to, those that generate free radicals, acids, or combinations thereof.

In one embodiment, the reactive material is polymerizable or crosslinkable. The material polymerization or crosslinking reaction is initiated or catalyzed by the active species. In one embodiment, the reactive material is an ethylenically unsaturated compound and the radiation-sensitive material generates free radicals. Ethylenically unsaturated compounds include, but are not limited to, acrylates, methacrylates, vinyl compounds, and combinations thereof. Any of the known classes of radiation-sensitive materials that generate free radicals can be used. Examples of radiation-sensitive materials which generate free radicals include, but are not limited to, quinones, benzophenones, benzoin ethers, aryl ketones, peroxides, biimidazoles, benzyl dimethyl ketal, hydroxyl alkyl phenyl acetophone, dialkoxy actophenone, trimethylbenzoyl phosphine oxide derivatives, aminoketones, benzoyl cyclohexanol, methyl thio phenyl morpholino ketones, morpholino phenyl amino ketones, alpha halogennoacetophenones, oxysulfonyl ketones, sulfonyl ketones, oxysulfonyl ketones, sulfonyl ketones, benzoyl oxime esters, thioxanthrones, camphorquinones, ketocoumarins, and Michler's ketone. Alternatively, the radiation sensitive material may be a mixture of compounds, one of which provides the free radicals when caused to do so by a sensitizer activated by radiation. In one embodiment, the radiation sensitive material is sensitive to visible or ultraviolet radiation.

The radiation-sensitive material is generally present in amounts from 0.001% to 10.0% based on the total weight of the priming layer.

In one embodiment, the reactive material can undergo polymerization initiated by acid, and the radiation-sensitive material generates acid. Examples of such reactive materials include, but are not limited to, epoxies. Examples of radiation-sensitive materials which generate acid, include, but are not limited to, sulfonium and iodonium salts, such as diphenyliodonium hexafluorophosphate.

In one embodiment, the priming layer comprises a radiation-softenable composition. In this case, when exposed to radiation, the priming layer can become more soluble or dispersable in a liquid medium, more tacky, more soft, more flowable, more liftable, or more absorbable. Other physical properties may also be affected.

In one embodiment, the priming layer consists essentially of a material which, when exposed to radiation, softens, or becomes more soluble, swellable, or dispersible in a liquid medium, or becomes more tacky or absorbable.

In one example of a radiation-softenable composition, the reactive material is a phenolic resin and the radiation-sensitive material is a diazonaphthoquinone.

In one example of a radiation-softenable composition, the priming layer consists essentially of at least one polymer which undergoes backbone degradation when exposed to deep UV radiation, having a wavelength in the range of 200-300 nm. Examples of polymers undergoing such degradation include, but are not limited to, polyacrylates, polymethacrylates, polyketones, polysulfones, copolymers thereof, and mixtures thereof.

Other radiation-sensitive systems that are known in the art can be used as well.

In one embodiment, the priming layer reacts with the underlying area when exposed to radiation. The exact mechanism of this reaction will depend on the materials used. After exposure to radiation, the priming layer is effectively removed in the unexposed areas by a suitable development treatment. In some embodiments, the priming layer is removed only in the unexposed areas. In some embodiments, the priming layer is partially removed in the exposed areas as well, leaving a thinner layer in those areas. In some embodiments, the priming layer that remains in the exposed areas is less than 50 Å in thickness. In some embodiments, the priming layer that remains in the exposed areas is essentially a monolayer in thickness.

In some embodiments, the priming material is deuterated. The term “deuterated” is intended to mean that at least one H has been replaced by D. The term “deuterated analog” refers to a structural analog of a compound or group in which one or more available hydrogens have been replaced with deuterium. In a deuterated compound or deuterated analog, the deuterium is present in at least 100 times the natural abundance level. In some embodiments, the priming material is at least 10% deuterated. By this it is meant that at least 10% of the hydrogens have been replaced by deuterium. In some embodiments, the priming material is at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at elast 90% deuterated; in some embodiments, 100% deuterated.

The priming layer can be applied by any known deposition process. In one embodiment, the priming layer is applied without adding it to a solvent. In one embodiment, the priming layer is applied by vapor deposition.

In one embodiment, the priming layer is applied by a condensation process. If the priming layer is applied by condensation from the vapor phase, and the surface layer temperature is too high during vapor condensation, the priming layer can migrate into the pores or free volume of an organic substrate surface. In some embodiments, the organic substrate is maintained at a temperature below the glass transition temperature or the melting temperature of the substrate materials. The temperature can be maintained by any known techniques, such as placing the first layer on a surface which is cooled with flowing liquids or gases.

In one embodiment, the priming layer is applied to a temporary support prior to the condensation step, to form a uniform coating of priming layer. This can be accomplished by any deposition method, including liquid deposition, vapor deposition, and thermal transfer. In one embodiment, the priming layer is deposited on the temporary support by a continuous liquid deposition technique. The choice of liquid medium for depositing the priming layer will depend on the exact nature of the priming layer itself. In one embodiment, the material is deposited by spin coating. The coated temporary support is then used as the source for heating to form the vapor for the condensation step.

Application of the priming layer can be accomplished utilizing either continuous or batch processes. For instance, in a batch process, one or more devices would be coated simultaneously with the priming layer and then exposed simultaneously to a source of radiation. In a continuous process, devices transported on a belt or other conveyer device would pass a station when they are sequentially coated with priming layer and then continue past a station where they are sequentially exposed to a source of radiation. Portions of the process may be continuous while other portions of the process may be batch.

In one embodiment, the priming material is a liquid at room temperature and is applied by liquid deposition over the first layer. The liquid priming material may be film-forming or it may be absorbed or adsorbed onto the surface of the first layer. In one embodiment, the liquid priming material is cooled to a temperature below its melting point in order to form a second layer over the first layer. In one embodiment, the priming material is not a liquid at room temperature and is heated to a temperature above its melting point, deposited on the first layer, and cooled to room temperature to form a second layer over the first layer. For the liquid deposition, any of the methods described above may be used.

In one embodiment, the priming layer is deposited from a second liquid composition. The liquid deposition method can be continuous or discontinuous, as described above. In one embodiment, the priming liquid composition is deposited using a continuous liquid deposition method. The choice of liquid medium for depositing the priming layer will depend on the exact nature of the priming material itself.

After the priming layer is formed, it is exposed to radiation. The type of radiation used will depend upon the sensitivity of the priming layer as discussed above. The exposure is patternwise. As used herein, the term “patternwise” indicates that only selected portions of a material or layer are exposed. Patternwise exposure can be achieved using any known imaging technique. In one embodiment, the pattern is achieved by exposing through a mask. In one embodiment, the pattern is achieved by exposing only select portions with a rastered laser. The time of exposure can range from seconds to minutes, depending upon the specific chemistry of the priming layer used. When lasers are used, much shorter exposure times are used for each individual area, depending upon the power of the laser. The exposure step can be carried out in air or in an inert atmosphere, depending upon the sensitivity of the materials.

In one embodiment, the radiation is selected from the group consisting of ultra-violet radiation (10-390 nm), visible radiation (390-770 nm), infrared radiation (770-10⁶ nm), and combinations thereof, including simultaneous and serial treatments. In one embodiment, the radiation is selected from visible radiation and ultraviolet radiation. In one embodiment, the radiation has a wavelength in the range of 300 to 450 nm. In one embodiment, the radiation is deep UV (200-300 nm). In another embodiment, the ultraviolet radiation has a wavelength between 300 and 400 nm. In another embodiment, the radiation has a wavelength in the range of 400 to 450 nm. In one embodiment, the radiation is thermal radiation. In one embodiment, the exposure to radiation is carried out by heating. The temperature and duration for the heating step is such that at least one physical property of the priming layer is changed, without damaging any underlying layers of the light-emitting areas. In one embodiment, the heating temperature is less than 250° C. In one embodiment, the heating temperature is less than 150° C.

After patternwise exposure to radiation, the priming layer is developed. Development can be accomplished by any known technique. Such techniques have been used extensively in the photoresist and printing art. Examples of development techniques include, but are not limited to, application of heat (evaporation), treatment with a liquid medium (washing), treatment with an absorbent material (blotting), treatment with a tacky material, and the like. The development step results in effective removal of the priming layer in either the exposed or unexposed areas. The priming layer then remains in either the unexposed or exposed areas, respectively. The priming layer may also be partially removed in the unexposed or exposed areas, but enough must remain in order for there to be a wettability difference between the exposed and unexposed areas. For example, the priming layer may be effectively removed in the unexposed areas and a part of the thickness removed in the exposed areas. In some embodiments, the development step results in effective removal of the priming layer in the unexposed areas.

In one embodiment, the exposure of the priming layer to radiation results in a change in the solubility or dispersibility of the priming layer in solvents. In this case, development can be accomplished by a wet development treatment. The treatment usually involves washing with a solvent which dissolves, disperses or lifts off one type of area. In one embodiment, the patternwise exposure to radiation results in insolubilization of the exposed areas of the priming layer, and treatment with solvent results in removal of the unexposed areas of the priming layer.

In one embodiment, the exposure of the priming layer to radiation results in a reaction which changes the volatility of the priming layer in exposed areas. In this case, development can be accomplished by a thermal development treatment. The treatment involves heating to a temperature above the volatilization or sublimation temperature of the more volatile material and below the temperature at which the material is thermally reactive. For example, for a polymerizable monomer, the material would be heated at a temperature above the sublimation temperature and below the thermal polymerization temperature. It will be understood that priming materials which have a temperature of thermal reactivity that is close to or below the volatilization temperature, may not be able to be developed in this manner.

In one embodiment, the exposure of the priming layer to radiation results in a change in the temperature at which the material melts, softens or flows. In this case, development can be accomplished by a dry development treatment. A dry development treatment can include contacting an outermost surface of the element with an absorbent surface to absorb or wick away the softer portions. This dry development can be carried out at an elevated temperature, so long as it does not further affect the properties of the remaining areas.

The development step results in areas of priming layer that remain and areas in which the underlying first layer is uncovered.

In some embodiments, the priming layer comprises a hole transport material. In some embodiments, the priming layer comprises a material selected from the group consisting of triarylamines, carbazoles, fluorenes, polymers thereof, copolymers thereof, deuterated analogs thereof, and combinations thereof. In some embodiments, the priming layer comprises a material selected from the group consisting of polymeric triarylamines, polycarbazoles, polyfluorenes, polymeric triarylamines having conjugated moieties which are connected in a non-planar configuration, copolymers of fluorene and triarylamine, deuterated analogs thereof, and combinations thereof. In some embodiments, the polymeric materials are crosslinkable. In some embodiments, the priming layer comprises an electron transport material. In some embodiments, the priming layer comprises a metal chelated oxinoid compound. In some embodiments, the priming layer comprises a metal quinolate derivative. In some embodiments, the priming layer comprises a material selected from the group consisting of tris(8-hydroxyquinolato)aluminum, bis(2-methyl-8-quinolinolato)(p-phenylphenolato) aluminum, tetrakis-(8-hydroxyquinolato)hafnium, and tetrakis-(8-hydroxyquinolato)zirconium. In some embodiments, the priming layer consists essentially of a material selected from the group consisting of polymeric triarylamines, polycarbazoles, polyfluorenes, copolymers thereof, and metal quinolates.

In some embodiments, the hole injection layer comprises a conductive polymer doped with a fluorinated acid polymer and the priming layer consists essentially of a hole transport material. In some embodiments, the hole transport material is a triarylamine polymer. Such polymers have been described in, for example, published PCT applications WO 2008/024378, WO 2008/024379, and WO 2009/067419. In some embodiments, the priming material is selected from the group consisting of polymeric triarylamines having conjugated moieties which are connected in a non-planar configuration, compounds having at least one fluorene moiety and at least two triarylamine moieties, and deuterated analogs thereof. In some embodiments, the polymeric triarylamines have Formula I, Formula II, or Formula III, as described above.

Some exemplary compounds which can be used as a priming layer include deuterated fluorene, deuterated polyfluorene, deuterated polyvinylcarbazole, Compounds HT1 through HT12, ET3 and ET4.

### 7. Other Device Layers

The other layers in the device can be made of any materials that are known to be useful in such layers.

The anode 110, is an electrode that is particularly efficient for injecting positive charge carriers. It can be made of, for example, materials containing a metal, mixed metal, alloy, metal oxide or mixed-metal oxide, or it can be a conducting polymer, or mixtures thereof. Suitable metals include the Group 11 metals, the metals in Groups 4-6, and the Group 8-10 transition metals. If the anode is to be light-transmitting, mixed-metal oxides of Groups 12, 13 and 14 metals, such as indium-tin-oxide, are generally used. The anode 110 can also comprise an organic material such as polyaniline as described in “Flexible light-emitting diodes made from soluble conducting polymer,” Nature vol. 357, pp 477-479 (11 Jun. 1992). At least one of the anode and cathode is desirably at least partially transparent to allow the generated light to be observed.

The cathode 160, is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used. Li- or Cs-containing organometallic compounds, LiF, CsF, and Li₂O can also be deposited between the organic layer and the cathode layer to lower the operating voltage.

It is known to have other layers in organic electronic devices. For example, there can be a layer (not shown) between the anode 110 and hole injection layer 120 to control the amount of positive charge injected and/or to provide band-gap matching of the layers, or to function as a protective layer. Layers that are known in the art can be used, such as copper phthalocyanine, silicon oxy-nitride, fluorocarbons, silanes, or an ultra-thin layer of a metal, such as Pt. Alternatively, some or all of anode layer 110, active layers 120, 130, 140, and 150, or cathode layer 160, can be surface-treated to increase charge carrier transport efficiency. The choice of materials for each of the component layers is preferably determined by balancing the positive and negative charges in the emitter layer to provide a device with high electroluminescence efficiency. Any or all of these layer can contain deuterated materials.

It is understood that each functional layer can be made up of more than one layer.

The device can be prepared by a variety of techniques, including sequential vapor deposition of the individual layers on a suitable substrate. Substrates such as glass, plastics, and metals can be used. Conventional vapor deposition techniques can be used, such as thermal evaporation, chemical vapor deposition, and the like. Alternatively, the organic layers can be applied from solutions or dispersions in suitable solvents, using conventional coating or printing techniques, including but not limited to spin-coating, dip-coating, roll-to-roll techniques, ink-jet printing, screen-printing, gravure printing and the like.

In some embodiments, the process for making an organic light-emitting device, comprises:
providing a substrate having a patterned anode thereon;
forming an electroactive layer by depositing a first liquid composition comprising (a) a deuterated a deuterated electroactive material and (b) a liquid medium; and
forming a cathode overall.

The term “liquid composition” is intended to include a liquid medium in which one or more materials are dissolved to form a solution, a liquid medium in which one or more materials are dispersed to form a dispersion, or a liquid medium in which one or more materials are suspended to form a suspension or an emulsion.

In some embodiments of the above process, the deuterated electroactive material is a deuterated hole injection material. In some embodiments of the above process, the deuterated electroactive material is a deuterated hole transport material. In some embodiments of the above process, the deuterated electroactive material is a deuterated electroluminescent material. In some embodiments of the above process, the deuterated electroactive material is a deuterated host material. In some embodiments of the above process, the deuterated electroactive material is a deuterated electron transport material. In some embodiments of the above process, the deuterated electroactive material is a deuterated chemical containment material.

In some embodiments, the process further comprises:
forming a second electroactive layer by depositing a second liquid composition comprising a second deuterated electroactive material in a second liquid medium.
   In some embodiments, the second deuterated electroactive material is selected from the group consisting of deuterated hole injection material, deuterated hole transport material, deuterated electroluminescent material, deuterated host material, deuterated electron transport material, and deuterated chemical containment material.

Any known liquid deposition technique or combination of techniques can be used, including continuous and discontinuous techniques. Examples of continuous liquid deposition techniques include, but are not limited to spin coating, gravure coating, curtain coating, dip coating, slot-die coating, spray coating, and continuous nozzle printing. Examples of discontinuous deposition techniques include, but are not limited to, ink jet printing, gravure printing, and screen printing. In some embodiments, the electroactive layer is formed in a pattern by a method selected from continuous nozzle coating and ink jet printing. Although the nozzle printing can be considered a continuous technique, a pattern can be formed by placing the nozzle over only the desired areas for layer formation. For example, patterns of continuous rows can be formed.

A suitable liquid medium for a particular composition to be deposited can be readily determined by one skilled in the art. For some applications, it is desirable that the compounds be dissolved in non-aqueous solvents. Such non-aqueous solvents can be relatively polar, such as C₁ to C₂₀ alcohols, ethers, and acid esters, or can be relatively non-polar such as C₁ to C₁₂ alkanes or aromatics such as toluene, xylenes, trifluorotoluene and the like. Another suitable liquid for use in making the liquid composition, either as a solution or dispersion as described herein, comprising the new compound, includes, but not limited to, a chlorinated hydrocarbon (such as methylene chloride, chloroform, chlorobenzene), an aromatic hydrocarbon (such as a substituted or non-substituted toluene or xylenes, including trifluorotoluene), a polar solvent (such as tetrahydrofuran (THF), N-methylpyrrolidone (NMP)), an ester (such as ethylacetate), an alcohol (such as isopropanol), a ketone (such as cyclopentatone), or any mixture thereof. Examples of mixtures of solvents for electroluminescent materials have been described in, for example, published US application 2008-0067473.

After deposition, the material is dried to form a layer. Any conventional drying technique can be used, including heating, vacuum, and combinations thereof.

In some embodiments, the device is fabricated by liquid deposition of the hole injection layer, the hole transport layer, and the electroactive layer, and by vapor deposition of the anode, the electron transport layer, an electron injection layer and the cathode.

### 8. Synthesis of Deuterated Materials

The non-deuterated analogs of the compounds described herein can be prepared by known coupling and substitution reactions. The new deuterated compounds can then be prepared in a similar manner using deuterated precursor materials or, more generally, by treating the non-deuterated compound with deuterated solvent, such as d6-benzene, in the presence of a Lewis acid H/D exchange catalyst, such as aluminum trichloride or ethyl aluminum chloride, or acids such as CF₃COOD, DCI, etc. Exemplary preparations are given in the Examples. The level of deuteration can be determined by NMR analysis and by mass spectrometry, such as Atmospheric Solids Analysis Probe Mass Spectrometry (ASAP-MS).

The starting materials of the perdeuterated or partially deuterated aromatic compounds or alkyl compounds can be purchased from commercial sources or can be obtained using known methods. Some examples of such methods can be found in a) “Efficient H/D Exchange Reactions of Alkyl-Substituted Benzene Derivatives by Means of the Pd/C—H2-D2O System” Hiroyoshi Esaki, Fumiyo Aoki, Miho Umemura, Masatsugu Kato, Tomohiro Maegawa, Yasunari Monguchi, and Hironao Sajiki Chem. Eur. J. 2007, 13, 4052-4063. b) “Aromatic H/D Exchange Reaction Catalyzed by Groups 5 and 6 Metal Chlorides” GUO, Qiao-Xia, SHEN, Bao-Jian; GUO, Hai-Qing TAKAHASHI, Tamotsu Chinese Journal of Chemistry, 2005, 23, 341-344; c) “A novel deuterium effect on dual charge-transfer and ligand-field emission of the cis-dichlorobis(2,2′-bipyridine)iridium(III) ion” Richard J. Watts, Shlomo Efrima, and Horia Metiu J. Am. Chem. Soc., 1979, 101 (10), 2742-2743; d) “Efficient H-D Exchange of Aromatic Compounds in Near-Critical D20 Catalysed by a Polymer-Supported Sulphonic Acid” Carmen Boix and Martyn Poliakoff Tetrahedron Letters 40 (1999) 4433-4436; e) U.S. Pat. No. 3,849,458; f) “Efficient C-H/C-D Exchange Reaction on the Alkyl Side Chain of Aromatic Compounds Using Heterogeneous Pd/C in D2O” Hironao Sajiki, Fumiyo Aoki, Hiroyoshi Esaki, Tomohiro Maegawa, and Kosaku Hirota Org. Lett., 2004, 6 (9), 1485-1487.

The compounds described herein can be formed into films using liquid deposition techniques. Surprisingly and unexpectedly, these compounds have greatly improved properties when compared to analogous non-deuterated compounds. Electronic devices including an active layer with the compounds described herein, have greatly improved lifetimes. In addition, the lifetime increases are achieved in combination with high quantum efficiency and good color saturation. Furthermore, the deuterated compounds described herein have greater air tolerance than the non-deuterated analogs. This can result in greater processing tolerance both for the preparation and purification of the materials and in the formation of electronic devices using the materials.

### EXAMPLES

The following examples illustrate certain features and advantages of the present invention. They are intended to be illustrative of the invention, but not limiting. All percentages are by weight, unless otherwise indicated.

### Synthesis Example 1

This example illustrates the preparation of a deuterated hole injection material, D-HIJ-1.

a. Preparation of a Dispersion of the Deutero-HFAP in Deuterium Oxide (D₂O).

A copolymer of tetrafluoroethylene (“TFE”) and perfluoro-3,6-dioxa-4-methyl-7-octenesulfonic acid (“PSEPVE”) was deuterated and made into a colloidal dispersion in D₂O in the following manner. Poly(TFE-PSEPVE) having one proton in sulfonic acid for every 987 gram (weight of the copolymer per one acidic site) was first made into water dispersion using a procedure similar to the procedure in U.S. Pat. No. 6,150,426, Example 1, Part 2, except that the temperature is approximately 270° C. The non-deuterated poly(TFE-PSEPVE) dispersion was converted to free-flowing solid flakes of poly(TFE-PSEPVE) on a tray having liquid depth no more than ⅝″. The tray was then cooled to below 0° C. to freeze the water dispersion first. Once freezed, it was subjected to a partial vacuum pressure no higher than 1 mm Hg until most of water was removed. The partially dried solids were then taken up to about 30° C. under the vacuum pressure to completely remove the moisture without coalescing the polymer.

21 g of the solid flakes of non-deuterated poly(TFE-PSEPVE), pre-dried in a vacuum oven to remove water, were placed in a metal cylindrical tube pre-purged with nitrogen. 150 g D₂O purchased from Cambridge Isotope Lab, Inc. was immediately added to the poly(TFE-PSEPVE) containing tube. The tube was capped and heated to about 270° C. in a pressure lab for a short period time before cooled down to R.T. to ensure conversion of the solid flakes to poly(TFE-PSEPVE) colloidal dispersion in D₂O. Moreover, the proton in poly(TFE-PSEPVE) in the overwhelming excess of deuterium has been exchanged with deuterium to complete deuteration of poly(TFE-PSEPVE). The deuterated poly(TFE-PSEPVE) (“D-poly(TFE-PSEPVE)”) dispersion in D₂O was further processed to remove larger particles. The D-poly(TFE-PSEPVE) weight % in the D₂O dispersion was determined to be 11.34 wt. %, based on the total weight of the dispersion, by a gravimetric method.

b. Direct Process to Form a Deutero-HFAP. and a Dispersion of the Deutero-HFAP in Deuterium Oxide (D₂O).

A copolymer of tetrafluoroethylene (“TFE”) and perfluoro-3,6-dioxa-4-methyl-7-octenesulfonic acid (“PSEPVE”) can be deuterated and made into a colloidal dispersion in D₂O in the following manner. Poly(TFE-PSEPVE) resin having one proton in sulfonic acid for every 987 gram (weight of the copolymer per one acidic site) can be made into D2O dispersion using a procedure similar to the procedure in U.S. Pat. No. 6,150,426, Example 1, Part 2, except that the temperature is approximately 270° C. and D₂O is used instead of water.

c. Preparation of a Deuterated Electrically Conductive Polymer Doped with a Deuterated HFAP.

Deuterated pyrrole, (“D₅-Py”) (Formula wt.: 72.12) was purchased from Aldrich Chemical Company (Milwaukee, Wis.). This brown-colored liquid was fractionally distilled under reduced pressure prior to use. The colorless distillate was characterized by ¹³C NMR spectroscopy to confirm the structure.

Polymerization of D₅-Py in D-poly(TFE-PSEPVE)/D₂O dispersion was carried out in the following manner. 70.2 g of the D-poly(TFE-PSEPVE)/D₂O prepared in Example 1 was weighed in to a 500 mL resin kettle first before added additional 14 g D₂O. The amount of D-poly(TFE-PSEPVE)/D₂O represents 8.14 mmol of acid. The kettle was capped with a glass lid having an overhead stirrer. While the D-poly(TFE-PSEPVE)/D₂O being stirred, 0.135 g (0.26 mmol) ferric sulfate and 0.62 g (2.6 mmol) Na₂S₂O₈ pre-dissolved in 10 mL was added to the D-poly(TFE-PSEPVE)/D₂O, Shortly after, 0.175 g (2.43 mmol) D₅-Py pre-dissolved in 7 mL D₂O was added to the mixture in one minute. Polymerization started immediately as soon as D₅-Py was added. The polymerization was allowed to proceed for 10 minutes. Addition of the ingredients and polymerization took place under nitrogen. At the end of 10 minutes, Dowex M-43 resin was added to the resin kettle and mixed for approximately 5 minutes. After vacuum filtered with 417 filter paper, Dowex M-31 Na⁺ resin was added to the mixture and mixed for 5 minutes. The resulting material was vacuum filtered once again using 417 filter paper. The D₂O dispersion of deuterated polypyrrole doped with D-poly(TFE-PSEPVE) (“poly(D₅-Py)/D-poly(TFE-PSEPVE)”) was treated with ion-exchanged resin again to further purify the dispersion in which it only contained 1.79 ppm of sulfate, and 0.79 ppm of chloride. Solid % of the dispersion was determined to be 4.3% and pH was determined to be 5.2. Electrical conductivity of cast film baked at 275° C. in a dry box for 30 minutes was measured to be ˜1×10⁻⁶ S/cm at room temperature.

### Synthesis Example 2

This example illustrates the preparation of the deuterated hole transport material, HT5. This is shown below, where R¹=n-propyl, R²=n-octyl, y=0 and x=42:

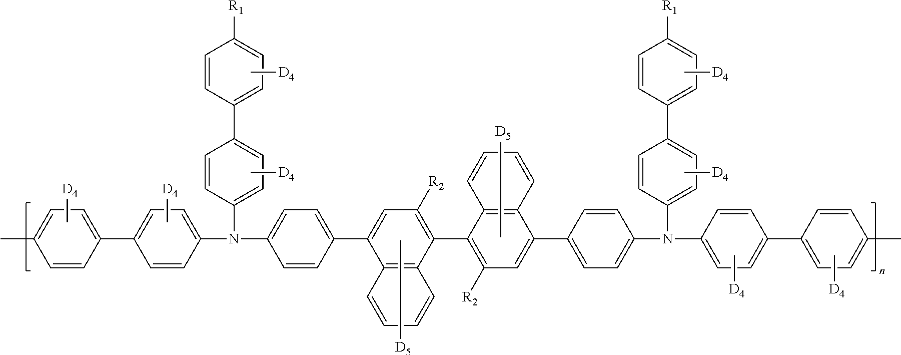

The compound is made according to the scheme below.

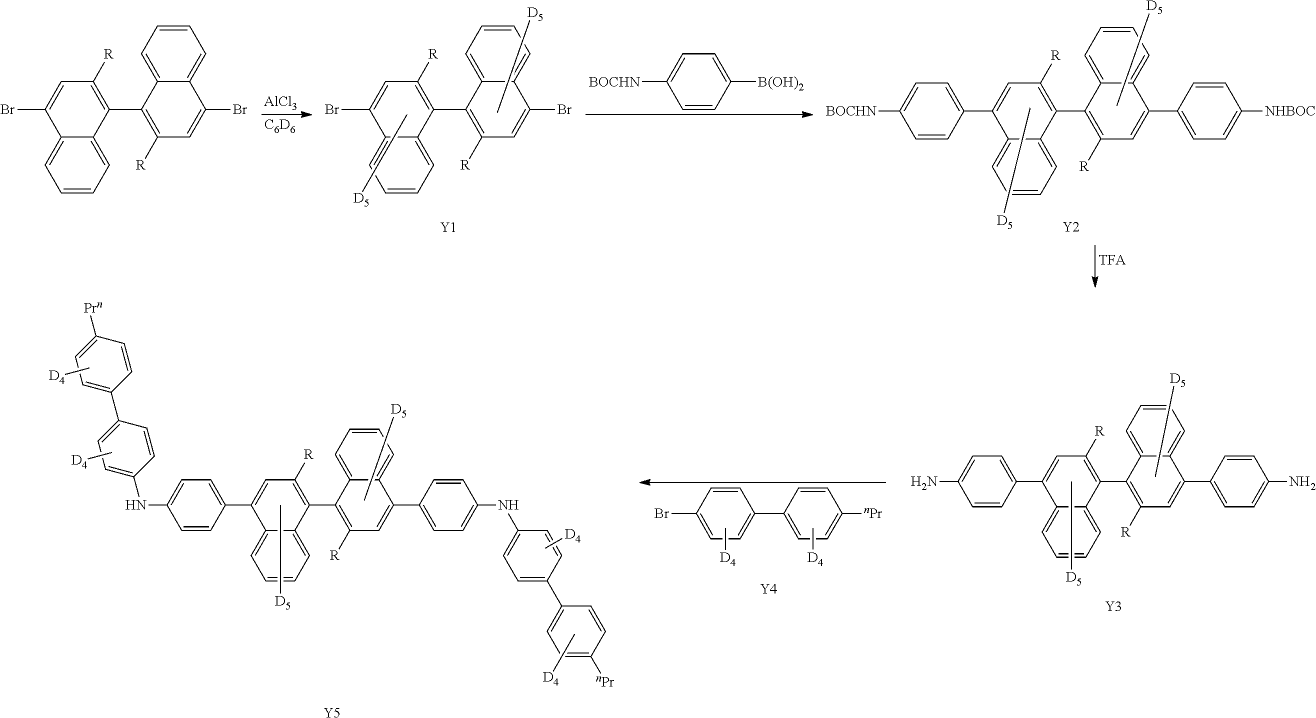

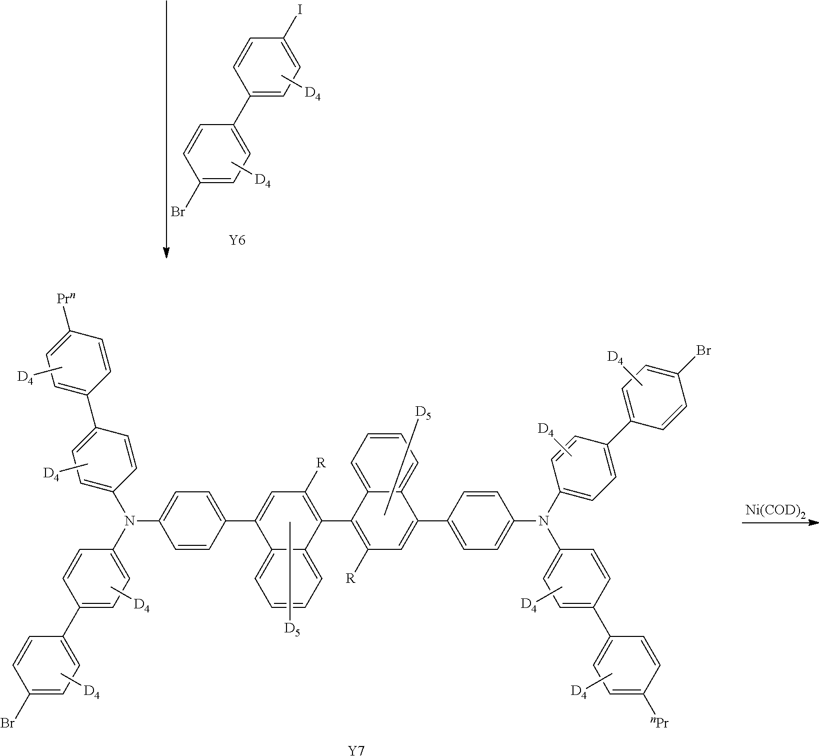

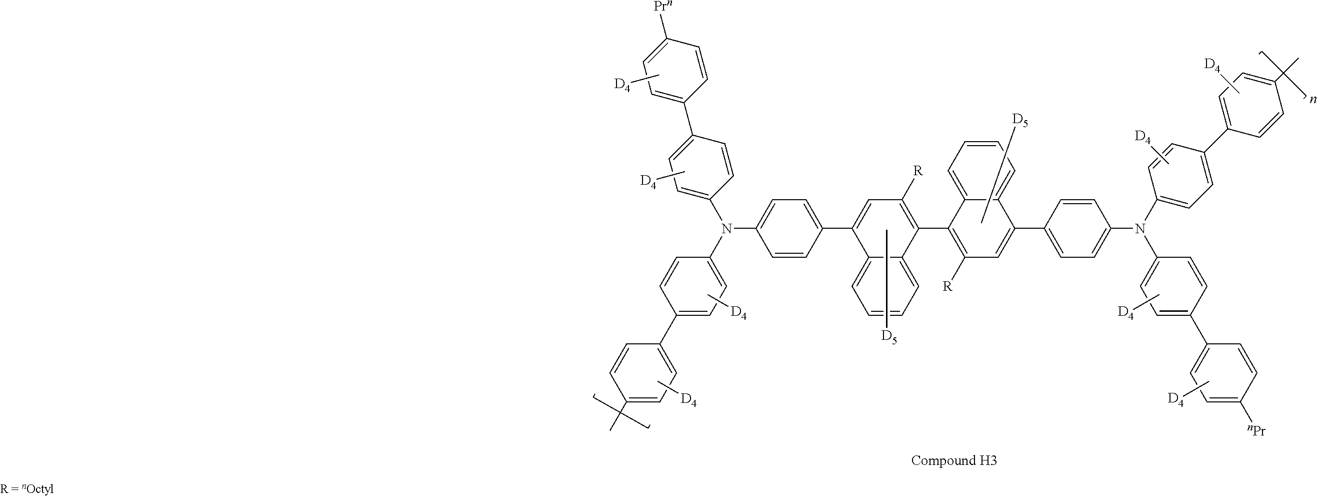

### Synthesis of Intermediate Compound Y1

Under an atmosphere of nitrogen, AlCl₃ (0.17 g, 1.29 mmol) was added to a C₆D₆ (100 mL) solution of 2,2′-dioctyl-4,4′-dibromo-1,1′-binaphthylene (2.328 g, 3.66 mmol). The resulting mixture was stirred at room temperature for 30 minutes after which D₂O (50 mL) was added. The layers were separated followed by washing the water layer with CH₂Cl₂ (2×30 mL). The combined organic layers were dried over magnesium sulfate and the volatiles were removed by rotary evaporation. The crude product was purified via column chromatography. Compound Y1 was obtained (1.96 g) as a white powder.

### Synthesis of Intermediate Compound Y2

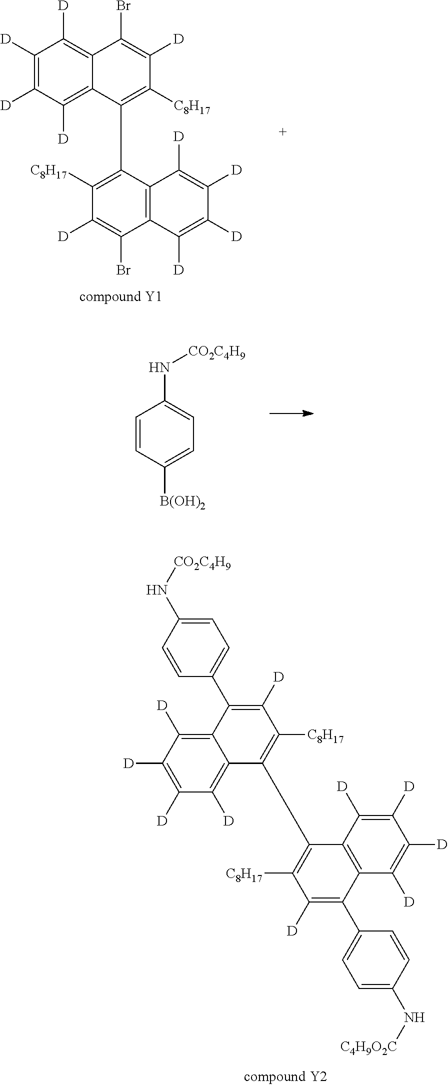

Compound Y2 can be made from Compound Y1 using a procedure analogous to the preparation of intermediate Compound C1 above. Compound Y2 is purified using chromatography.

### Synthesis of Intermediate Compound Y3

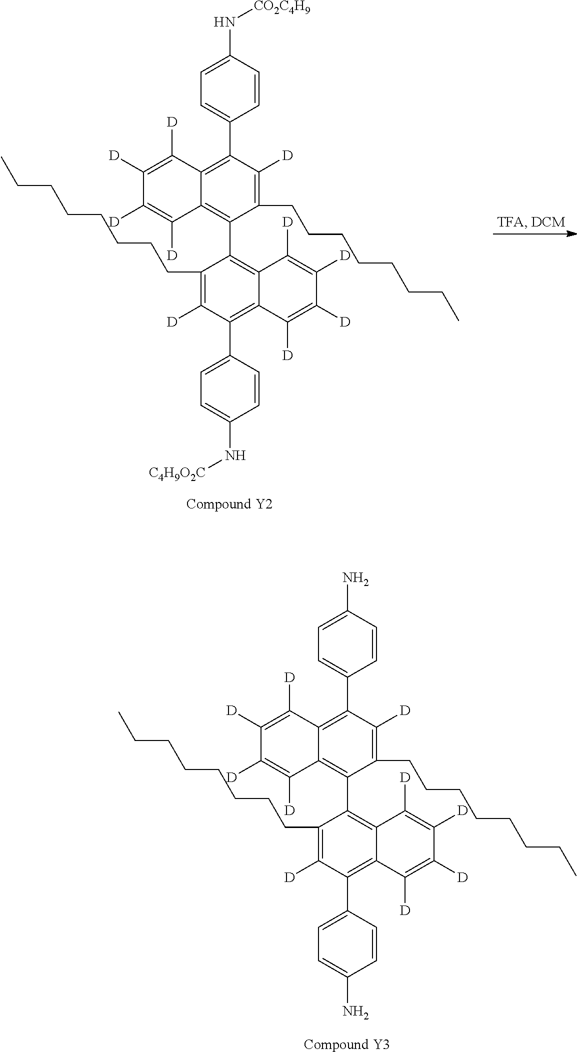

Under nitrogen, a 100 mL round-bottomed flask was charged with compound Y2 (2.100 g, 2.410 mmol) and dichloromethane (30 mL). It was allowed to stir for 5 minutes and then trifluoroacetic acid (1.793 mL) was added and the reaction was left to stir overnight. Once the reaction was complete, it was quenched using saturated sodium carbonate solution. The water was removed and washed with CH₂Cl₂ and the combined organic layer was evaporated to dryness. The residue dissolved in diethyl ether and the product was washed with sodium carbonate, brine and water and dried using magnesium sulphate. Compound Y3 was purified using chromatography to yield 1.037 g.

The structure of the compound was confirmed by ¹H NMR, as shown in FIG. 2.

### Synthesis of Intermediate Compound Y4

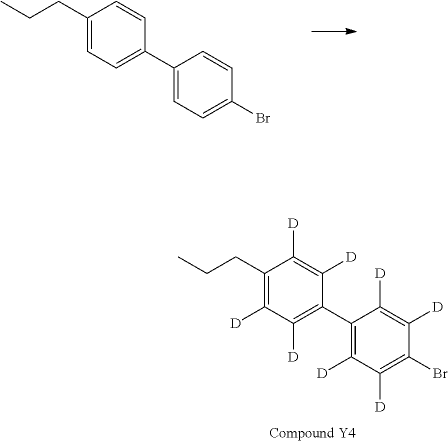

A solution of 4-bromo-4′-propylbiphenyl (5.10 g, 18.53 mmol) in C6D6 (20 mL) was purged with nitrogen for 30 min. A 1.0 M solution of ethyl aluminum dichloride solution in hexanes (4.0 mL, 4.0 mmol) was added dropwise via syringe and the reaction mixture was heated at reflux for 1.75 h under nitrogen atmosphere. After cooling to room temperature under nitrogen atmosphere, deuterium oxide (20 mL) is added, the mixture is shaken, and the layers are separated. The aqueous layer is extracted with benzene (3×10 mL) and the combined organic phase is dried over magnesium sulfate, filtered and concentrated by rotary evaporation. The product thus obtained was resubjected to the above reaction conditions two more times. After the third treatment the crude product was recrystallized from ethanol (20 mL) to afford compound Y4 (1.01 g) as a white solid. Mp 110.1-111.6° C. Purity (HPLC): 100%. The ¹H NMR spectrum of Y4 was consistent with an average of 7.64 of the 8 aromatic protons replaced by deuterium.

### Synthesis of Intermediate Compound Y5

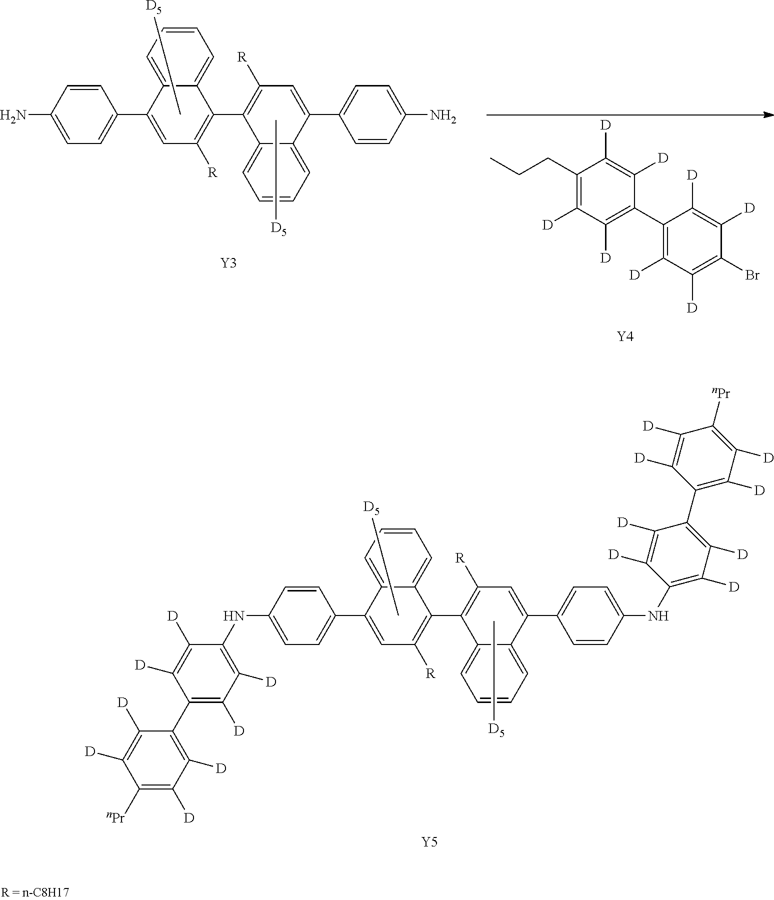

Under an atmosphere of nitrogen, compound Y3 (1.04 g, 1.55 mmol), Y4 (0.80 g, 2.82 mmol), tris(dibenzylideneacetone)dipalladium(0) (81 mg, 0.09 mmol), tri-t-butylphosphine (42 mg, 0.21 mol %) and toluene (25 mL) were combined. Sodium t-butoxide (0.52 g, 5.41 mmol) was added and the reaction was stirred at room temperature for 40 h. Tris(dibenzylideneacetone)dipalladium(0) (50 mg, 0.05 mmol), tri-t-butylphosphine (30 mg, 0.15 mmol) and Y4 (196 mg, 0.69 mmol) were then added. and the reaction mixture was warmed to 50° C. After another 72 h, the reaction mixture was filtered through a pad of Celite, rinsing with CH2Cl2 (50 mL). The filtrate was concentrated on a rotary evaporator and dried under vacuum. The product was purified by medium pressure liquid chromatography on silica gel (0-40% methylene chloride gradient in hexanes) to give 0.99 g (59% yield) of a white solid. NMR analysis confirmed the structure of Intermediate Compound Y5 as a mixture of 4,4′- and 4,5′-regioisomers. Purity (HPLC): 99.3%.

### Synthesis of Intermediate Compound Y6

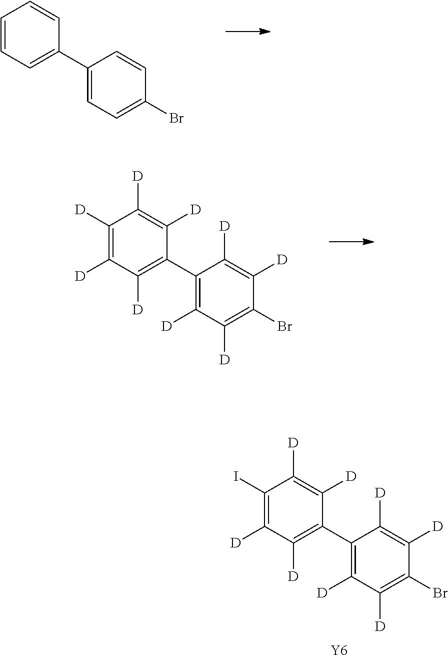

### Step 1: Preparation of deuterated 4-bromobiphenyl

A solution of 4-bromobiphenyl (4.66 g, 20.0 mmol) in C6D6 (20 mL) was purged with nitrogen for 30 min. A 1.0 M solution of ethyl aluminum dichloride solution in hexanes (4.0 mL, 4.0 mmol) was added dropwise via syringe and the reaction mixture was heated at reflux for 50 min under nitrogen atmosphere. After cooling to room temperature under nitrogen atmosphere, deuterium oxide (20 mL) is added, the mixture is shaken, and the layers are separated. The organic phase is dried over magnesium sulfate, filtered and concentrated by rotary evaporation. The product thus obtained was resubjected to the above reaction conditions four more times. After the fifth treatment the crude product was recrystallized from ethanol (20 mL) to afford the title compound of Step 1 (2.26 g) as a white solid. Mp 92.8-94.1° C. Purity (HPLC): 98.14%. The mass spectrum indicated that 6-9 deuterium atoms had been incorporated.

### Step 2: Preparation of Y6

The product of Step 1 (2.26 g, 9.36 mmol) and iodic acid (687 mg) were dissolved in acetic acid (40 mL). Iodine chips (1.56 g) were added, followed by concentrated sulfuric acid (1.0 mL) and water (2.0 mL) and the reaction mixture was heated to reflux for 210 min. After cooling to room temperature, the precipitate was collected by filtration and washed with water, then methanol (20 mL each). The crude product was crystallized from EtOH/EtOAc (1/1) to afford Y6 (1.31 g) as a white solid. Mp 179.0-181.3° C. Purity (HPLC): 100%. The mass spectrum indicated that 6-7 deuterium atoms on average had been incorporated.

### Synthesis of Intermediate Compound Y7

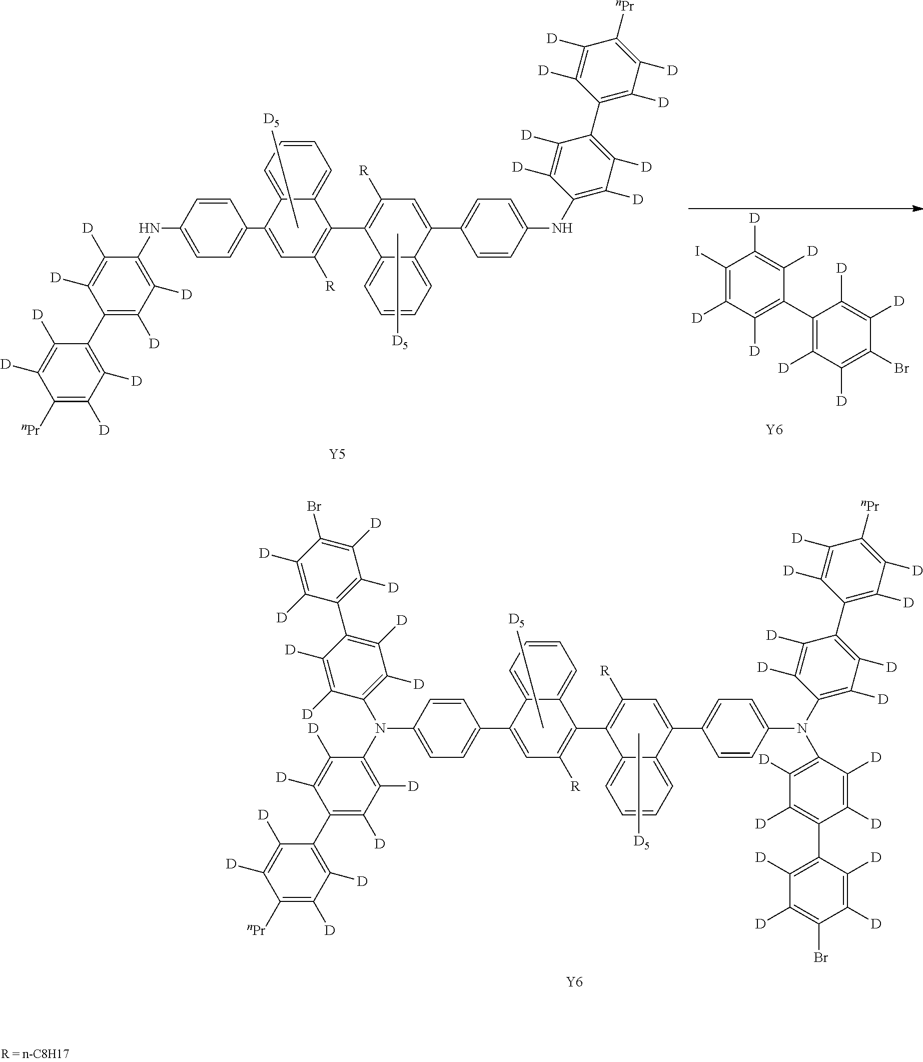

In a nitrogen purged glovebox, a 3-neck round bottom flask equipped with a magnetic stirrer, thermometer and reflux condenser topped with a gas inlet adaptor in the closed position was charged with Y5 (986 mg, 0.92 mmol), Y6 (1.30 g, 3.55 mmol), tris(dibenzylideneacetone)dipalladium(0) (124 mg, 14.8 mol %), bis(diphenylphosphinoferrocene) (151 mg, 29.6 mol %) and toluene (20 mL) through the open neck. Sodium t-butoxide (0.30 g, 3.12 mmol) was added, the open neck was capped and the reaction vessel was removed from the glovebox. A nitrogen bubbler hose was fitted to the gas inlet adaptor and the stopcock was turned to the open position under a slight positive pressure of nitrogen. The reaction was heated at reflux. After 21 h, the reaction was judged complete by HPLC analysis of an aliquot and the reaction was cooled to room temperature. The reaction mixture was filtered through a pad of Celite, rinsing with CH2Cl2. The filtrate was concentrated by rotary evaporation. The crude product was dried under high vacuum and purified by medium pressure liquid chromatography on silica gel (0-40% methylene chloride gradient in hexanes) to give 1.21 g of a white solid that was triturated with boiling methanol for 2 h to afford 0.975 g of Y7. ¹H NMR analysis confirmed the structure of Intermediate Compound Y7 as a mixture of 4,4′- and 4,5′-regioisomers and indicated that an average of 14 aromatic protons remained. This was corroborated by a parent ion (m/z 1550.3) in the mass spectrum confirming that 36 out of 50 aromatic hydrogens were replaced by deuterium. Purity (HPLC): >99%.

### Synthesis of Compound Hole Transport Compound HT5

The polymerization of intermediate compound Y7 was performed as described for comparative A. The polymer was obtained as a white solid in 68% yield (0.285 g). The molecular weight of the polymer was determined by GPC (THF mobile phase, polystyrene standards): M_{w}=325,740; Mₙ=139,748; M_{w}/Mₙ=2.33.

### Synthesis Example 3

This example illustrates the preparation of a deuterated hole transport material, Compound HT11 where Σ(x)=18.

### Synthesis of Compound 2

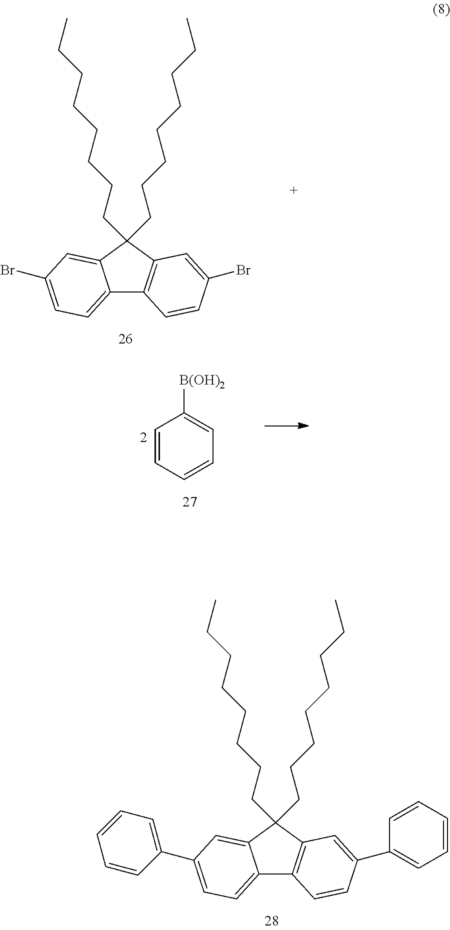

Under an atmosphere of nitrogen, a 250 mL round bottom was charged with 9,9-dioctyl-2,7-dibromofluorene (25.0 g, 45.58 mmol), phenylboronic acid (12.23 g, 100.28 mmol), Pd₂(dba)₃ (0.42 g, 0.46 mmol), P^{t}Bu₃ (0.22 g, 1.09 mmol) and 100 mL toluene. The reaction mixture stirred for five minutes after which KF (8.74 g, 150.43 mmol) was added in two portions and the resulting solution was stirred at room temperature overnight. The mixture was diluted with 500 mL THF and filtered through a plug of silica and celite and the volatiles were removed from the filtrate under reduced pressure. The yellow oil was purified by flash column chromatography on silica gel using hexanes as eluent. The product was obtained as a white solid in 80.0% (19.8 g). Analysis by NMR indicated the material to be compound 2 having structure given above.

### Synthesis of Compound 3

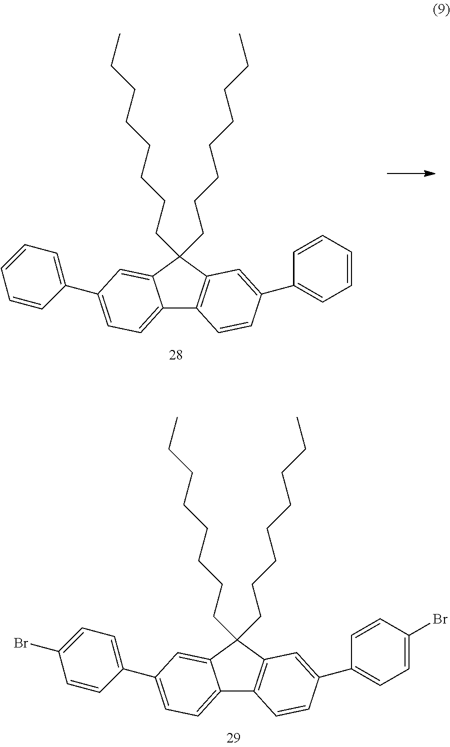

A 250 mL three-necked-round-bottom-flask, equipped with a condenser and dripping funnel was flushed with N₂ for 30 minutes. 9,9-dioctyl-2,7-diphenylfluorene (19.8 g, 36.48 mmol) was added and dissolved in 100 mL dichloromethane. The clear solution was cooled to −10° C. and a solution of bromine (12.24 g, 76.60 mmol) in 20 mL dichloromethane was added dropwise. The mixture was stirred for one hour at 0° C. and then allowed to warm to room temperature and stirred overnight. 100 mL of an aqueous 10% Na₂S₂O₃ solution was added and the reaction mixture was stirred for one hour. The organic layer was extracted and the water layer was washed three times with 100 mL dichloromethane. The combined organic layers were dried with Na₂SO₄ filtered and concentrated to dryness. Addition of acetone to the resulting oil gave a white precipitated. Upon filtration and drying a white powder was obtained (13.3 g, 52.2%). Analysis by NMR indicated the material to be compound 3 having structure given above.

### Synthesis of Compound 4

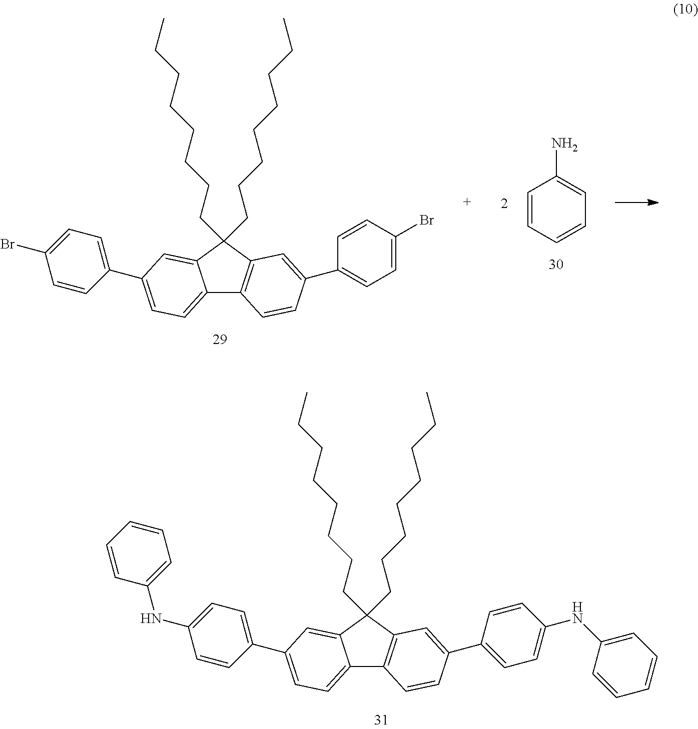

Under an atmosphere of nitrogen, a 250 mL round bottom was charged with 3 (13.1 g, 18.70 mmol), aniline (3.66 g, 39.27 mmol), Pd₂(dba)₃ (0.34 g, 0.37 mmol), P^{t}Bu₃ (0.15 g, 0.75 mmol) and 100 mL toluene. The reaction mixture stirred for 10 min after which NaO^{t}Bu (3.68 g, 38.33 mmol) was added and the reaction mixture was stirred at room temperature for one day. The resulting reaction mixture was diluted with 3 L toluene and filtered through a plug of silica and celite. Upon evaporation of volatiles, the dark brown oil obtained was purified by flash column chromatography on silica gel using a mixture of 1:10 ethyl acetate:hexanes as eluent. The product was obtained as a pale yellow powder in 50.2% (6.8 g). Analysis by NMR indicated the material to be compound 4 having structure given above.

### Synthesis of Compound 5

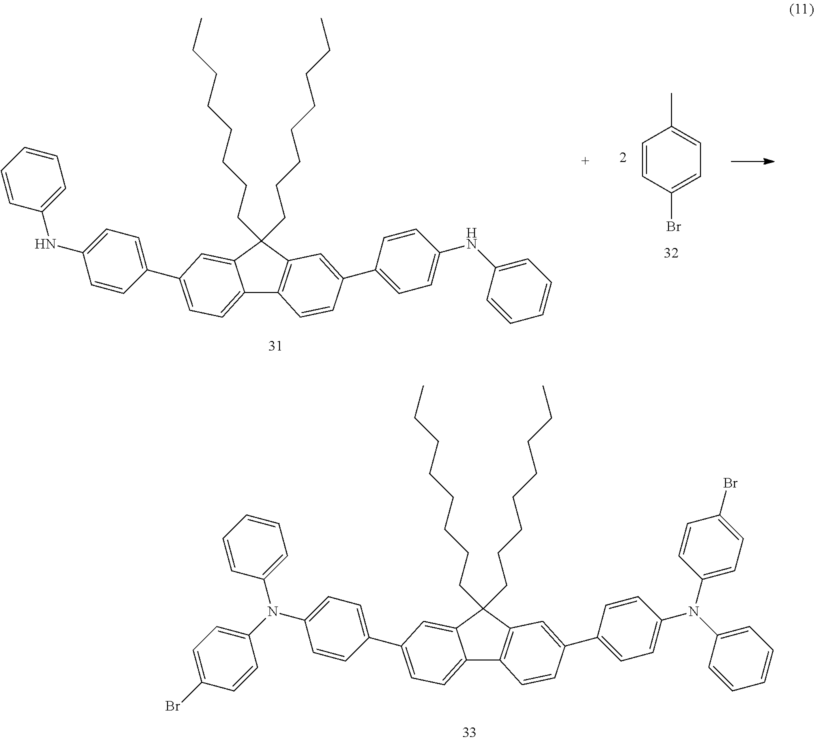

In a 250 mL three-necked-round-bottom-flask equipped with condenser, 4 (4.00 g, 5.52 mmol), 1-bromo-4-iodobenzene (4.68 g, 16.55 mmol), Pd₂(dba)₃ (0.30 g, 0.33 mmol) and DPPF (0.37 g, 0.66 mmol) were combined with 80 mL toluene. The resultant mixture was stirred for 10 min. NaO^{t}Bu (1.17 g, 12.14 mmol) was added and the mixture was heated to 80° C. for four days. The resulting reaction mixture was diluted with 1 L toluene and 1 L THF filtered through a plug of silica and celite to remove the insoluble salts. Upon evaporation of volatiles, the resulting brown oil was purified by flash column chromatography on silica gel using a mixture of 1:10 dichloromethane:hexanes as eluent. After drying a yellow powder was obtained (4.8 g, 84.8%). Analysis by NMR indicated the material to be compound 5 having structure given above.

### Synthesis of Compound 6

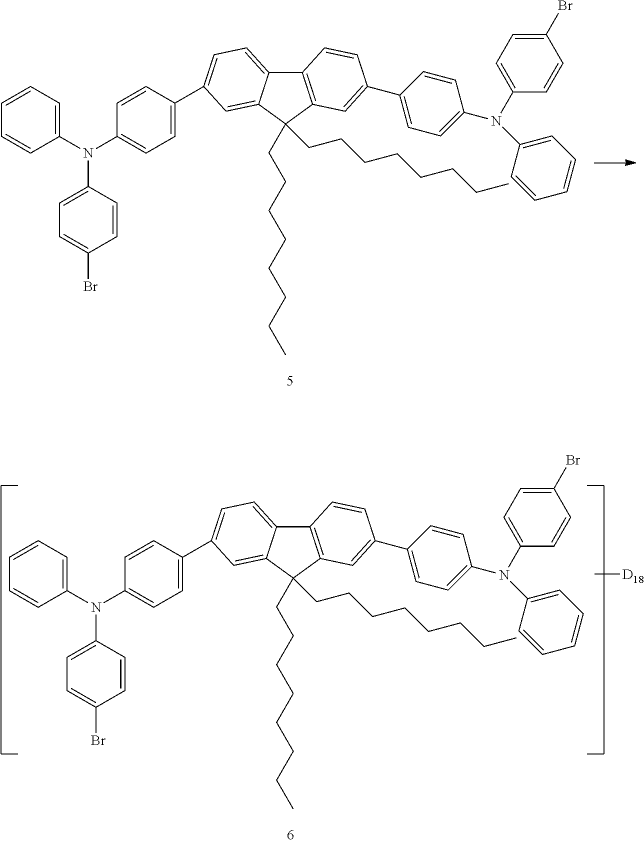

Under an atmosphere of nitrogen 1 g of compound 5 was dissolved in C₆D₆ (20 mL) to which CF₃OSO₂D (1.4 mL) was added dropwise. The reaction mixture was allowed to stir at room temperate overnight and then it was quenched with satd. Na2CO₃/D₂O. The organic layer was isolated and dried over MgSO₄. The product was purified using silica chromatography (20% CH₂Cl₂:hexane) to yield 0.688 g of material. The MS spectrum of the isolated material confirmed the structure with 18 aromatic D.

### Polymerization of Compound 6

All operations were carried out in a nitrogen purged glovebox unless otherwise noted. Compound 6 (0.652 g, 0.50 mmol) was added to a scintillation vial and dissolved in 16 mL toluene. A clean, dry 50 mL Schlenk tube was charged with bis(1,5-cyclooctadiene)nickel(0) (0.344 g, 1.252 mmol). 2,2′-Dipyridyl (0.195 g, 1.252 mmol) and 1,5-cyclooctadiene (0.135 g, 1.252 mmol) were weighed into a scintillation vial and dissolved in 3.79 g N,N′-dimethylformamide. The solution was added to the Schlenk tube. The Schlenk tube was inserted into an aluminum block and the block was heated and stirred on a hotplate/stirrer at a setpoint that resulted in an internal temperature of 60° C. The catalyst system was held at 60° C. for 45 minutes and then raised to 65° C. The monomer solution in toluene was added to the Schlenk tube and the tube was sealed. The polymerization mixture was stirred at 65° C. for one while adjusting viscosity by adding toluene (8 mL). The reaction mixture was allowed to cool to room temperature and 20 mL of conc. HCl was added. The mixture was allowed to stir for 45 minutes. The polymer was collected by vacuum filtration and washed with additional methanol and dried under high vacuum. The polymer was purified by successive precipitations from toluene into acetone and MeOH, A white, fibrous polymer (0.437 g, 79% yield) was obtained. The molecular weight of the polymer was determined by GPC (THF mobile phase, polystyrene standards): M_{w}=1,696,019; Mₙ=873,259. NMR analysis confirmed the structure to be the polymer, Compound HT11.

### Synthesis Example 4

This example illustrates the preparation of a deuterated electroluminescent material, E4 shown below.

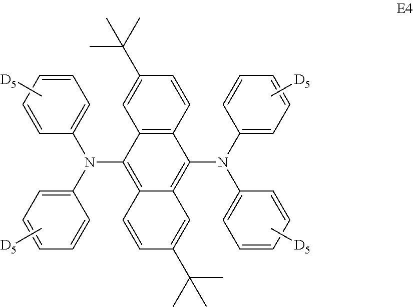

0.45 g of 2,6-di-t-butyl-9,10-dibromoanthracene (1 mM) (Müller, U.; Adam, M.; Müllen, K. Chem. Ber. 1994, 127, 437-444) was placed in a round bottom flask in a nitrogen filled glove box and 0.38 g (2.2 mM) di(perdeuterophenyl)amine and 0.2 g sodium tert-butoxide (2 mM) with 40 mL toluene were added. 0.15 g Pd₂DBA₃ (0.15 mM) and 0.07 g P(t-Bu)3 (0.3 mM) were dissolved in 10 mL toluene and added to the first solution with stirring. When all materials are mixed the solution slowly exotherms and becomes yellow brown. The solution was stirred and heated in the glove box at 80 C under nitrogen for 1 hr. The solution immediately is dark purple but on reaching ˜80 C it is dark yellow green with a noticeable green luminescence. After cooling to room temperature the solution is removed from the glove box and filtered through a short basic-alumina plug eluting with toluene to give a bright yellow-green band. The solvent was evaporated and the material recrystallized from toluene/methanol. Yield, 0.55 g. The structure was confirmed by ¹H nmr.

### Synthesis Example 5

This example illustrates the preparation of a deuterated host compound, H14.

The non-deuterated analog compound, Comparative Compound A, was made first.

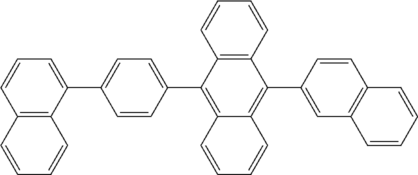

This compound can be prepared according to the following scheme:

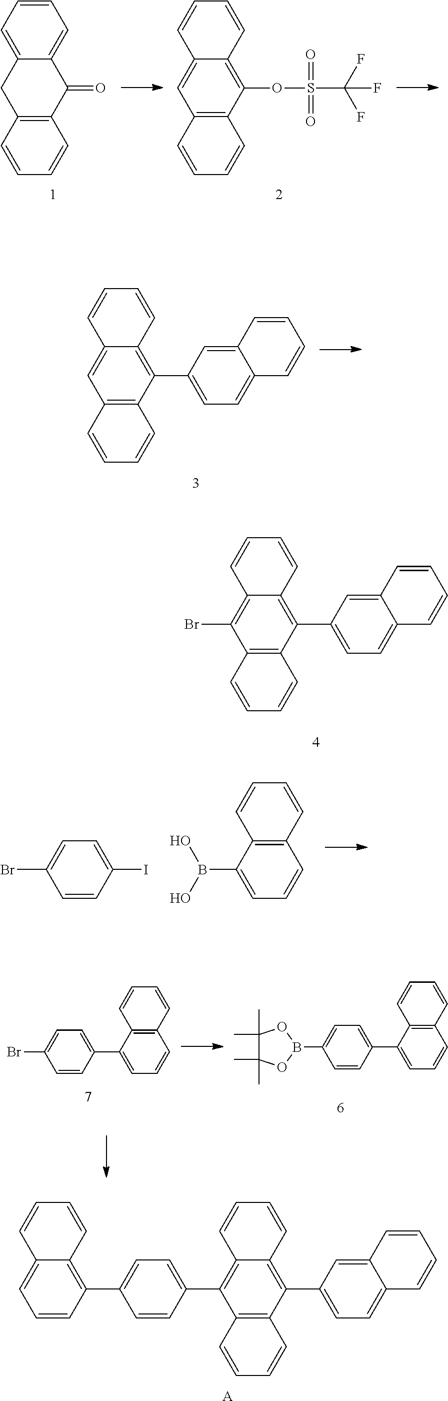

### Synthesis of Compound 2

In a 3 L flask fitted with a mechanical stirrer, dropping funnel, thermometer and N₂ bubbler was added anthrone, 54 g (275.2 mmol) in 1.5 L dry methylene chloride. The flask was cooled in an ice bath and 1,8-diazabicyclo[5.4.0]undec-7-ene (“DBU”), 83.7 ml (559.7 mmol) was added by dropping funnel over 1.5 hr. The solution turned orange, became opaque, then turned deep red. To the still cooled solution was added triflic anhydride, 58 ml (345.0 mmol) via syringe over about 1.5 hr keeping the temperature of the solution below 5° C. The reaction was allowed to proceed for 3 hr at room temperature, after which 1 mL additional triflic anhydride was added and stirring at RT continued for 30 min. 500 mL water was added slowly and the layers separated. The aqueous layer was extracted with 3×200 mL dichloromethane (“DCM”) and the combined organics dried over magnesium sulfate, filtered and concentrated by rotary evaporation to give a red oil. Column chromatography on silica gel followed by crystallization from hexanes afforded 43.1 g (43%) of a tan powder

### Synthesis of Compound 3

To a 200 mL Kjeldahl reaction flask equipped with a magnetic stirring bar in a nitrogen-filled glove box were added anthracen-9-yl trifluoromethanesulfonate (6.0 g, 18.40 mmol), Napthalen-2-yl-boronic acid (3.78 g 22.1 mmol), potassium phosphate tribasic (17.50 g, 82.0 mmol), palladium(II) acetate (0.41 g, 1.8 mmol), tricyclohexylphosphine (0.52 g, 1.8 mmol) and THF (100 mL). After removal from the dry box, the reaction mixture was purged with nitrogen and degassed water (50 mL) was added by syringe. A condenser was then added and the reaction was refluxed overnight. The reaction was monitored by TLC. Upon completion the reaction mixture was cooled to room temperature. The organic layer was separated and the aqueous layer was extracted with DCM. The organic fractions were combined, washed with brine and dried with magnesium sulfate. The solvent was removed under reduced pressure. The resulting solid was washed with acetone and hexane and filtered. Purification by column chromatography on silica gel afforded 4.03 g (72%) of product as pale yellow crystalline material.

### Synthesis of Compound 4

9-(naphthalen-2-yl)anthracene, 11.17 g (36.7 mmol) was suspended in 100 mL DCM. N-bromosuccinimide 6.86 g (38.5 mmol) was added and the mixture stirred with illumination from a 100 W lamp. A yellow clear solution formed and then precipitation occurred. The reaction was monitored by TLC. After 1.5 h, the reaction mixture was partially concentrated to remove methylene chloride, and then crystallized from acetonitrile to afford 12.2 g of pale yellow crystals (87%).

### Synthesis of Compound 7

To a 500 mL round bottom flask equipped with a stir bar in a nitrogen-filled glove box were added naphthalen-1-yl-1-boronic (14.2 g, 82.6 mmol), acid, 1-bromo-2-iodobenzene (25.8 g, 91.2 mmol), tetrakis(triphenylphospine) palladium(0) (1.2 g, 1.4 mmol), sodium carbonate (25.4 g, 240 mmol), and toluene (120 mL). After removal from the dry box, the reaction mixture was purged with nitrogen and degassed water (120 mL) was added by syringe. The reaction flask was then fitted with a condenser and the reaction was refluxed for 15 hours. The reaction was monitored by TLC. The reaction mixture was cooled to room temperature. The organic layer was separated and the aqueous layer was extracted with DCM. The organic fractions were combined and the solvent was removed under reduced pressure to give a yellow oil. Purification by column chromatography using silica gel afforded 13.6 g of a clear oil (58%).

### Synthesis of Compound 6

To a 1-liter flask equipped with a magnetic stirring bar, a reflux condenser that was connected to a nitrogen line and an oil bath, were added 4-bromophenyl-1-naphthalene (28.4 g, 10.0 mmol), bis(pinacolate) diboron (40.8 g, 16.0 mmol), Pd(dppf)₂Cl₂ (1.64 g, 2.0 mmol), potassium acetate (19.7 g, 200 mmol), and DMSO (350 mL). The mixture was bubbled with nitrogen for 15 min and then Pd(dppf)₂Cl₂ (1.64 g, 0.002 mol) was added. During the process the mixture turned to a dark brown color gradually. The reaction was stirred at 120° C. (oil bath) under nitrogen for 18 h. After cooling the mixture was poured into ice water and extracted with chloroform (3×). The organic layer was washed with water (3×) and saturated brine (1×) and dried with MgSO4. After filtration and removal of solvent, the residue was purified by chromatography on a silica gel column. The product containing fractions were combined and the solvent was removed by rotary evaporation. The resulting white solid was crystallized from hexane/chloroform and dried in a vacuum oven at 40° C. to give the product as white crystalline flakes (15.0 g in 45% yield). 1H and 13C-NMR spectra are in consistent with the expected structure.

### Synthesis of Comparative Compound A

To a 250 mL flask in glove box were added (2.00 g, 5.23 mmol), 4,4,5,5-tetramethyl-2-(4-(naphthalen-4-yl)phenyl)-1,3,2-dioxaborolane (1.90 g, 5.74 mmol), tris(dibenzylideneacetone) dipalladium(0) (0.24 g, 0.26 mmol), and toluene (50 mL). The reaction flask was removed from the dry box and fitted with a condenser and nitrogen inlet. Degassed aqueous sodium carbonate (2 M, 20 mL) was added via syringe. The reaction was stirred and heated to 90° C. overnight. The reaction was monitored by HPLC. After cooling to room temperature, the organic layer was separated. The aqueous layer was washed twice with DCM and the combined organic layers were concentrated by rotary evaporation to afford a grey powder. Purification by filtration over neutral alumina, hexanes precipitation, and column chromatography over silica gel afforded 2.28 g of a white powder (86%).

The product was further purified as described in published U.S. patent application 2008-0138655, to achieve an HPLC purity of at least 99.9% and an impurity absorbance no greater than 0.01.

The ¹H NMR spectrum of Compound A is given in FIG. 2.

The deuterated host compound H14 was made from comparative Compound A.

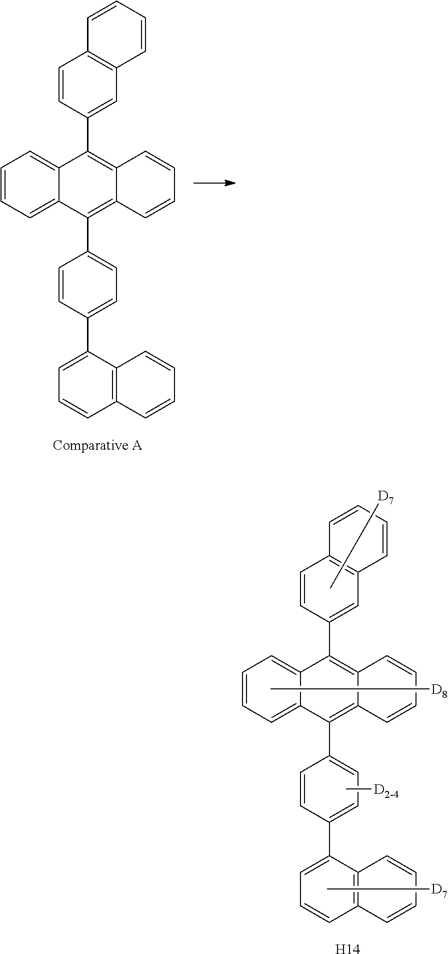

Under an atmosphere of nitrogen, AlCl₃ (0.48 g, 3.6 mmol) was added to a perdeuterobenzene or benzene-D6 (C₆D₆) (100 mL) solution of comparative compound A from Comparative Example A (5 g, 9.87 mmol). The resulting mixture was stirred at room temperature for six hours after which D₂O (50 mL) was added. The layers were separated followed by washing the water layer with CH₂Cl₂ (2×30 mL). The combined organic layers were dried over magnesium sulfate and the volatiles were removed by rotary evaporation. The crude product was purified via column chromatography. The deuterated product H1 (x+y+n+m=21-23) was obtained (4.5 g) as a white powder.

The product was further purified as described in published U.S. patent application 2008-0138655, to achieve an HPLC purity of at least 99.9% and an impurity absorbance no greater than 0.01. The material was determined to have the same level of purity as comparative compound A, from above.

The ¹H NMR (CD₂Cl₂) and ASAP-MS indicated that the compound had the structure given below:

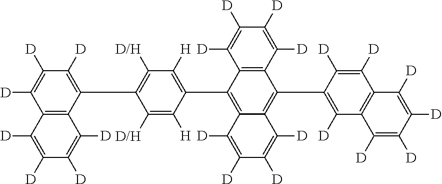

where “D/H” indicates approximately equal probability of H or D at this atomic position. The structure was confirmed by ¹H NMR, ¹³C NMR, ²D NMR and ¹H-¹³C HSQC (Heteronuclear Single Quantum Coherence).

### Synthesis Example 6

This example illustrates the preparation of a deuterated electron transport material, ET2.

a) The procedure from Yamada et al Bull Chem Soc Jpn, 63, 2710, 1990 was used to prepare the trimethylene bridged bathophenanthroline as follows: 2 g of bathophenanthroline was taken into 20 g 1,3-dibromopropane and refluxed under air. After about 30 mins the dense orange slurry was cooled. Methanol was added to dissolve the solids, and then acetone was added to precipitate a bright orange solid. This was filtered and washed with toluene and dichloromethane (“DCM”) resulting in an orange powder in 2.8 g yield.

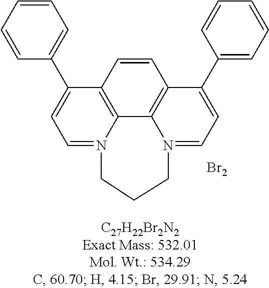

b) 2.8 g of product from above was dissolved into 12 mL water and dripped into an ice-cooled solution of 21 g potassium ferricyanide and 10 g sodium hydroxide in 30 mL water over the course of about 30 mins, and then stirred for 90 mins. This was iced again and neutralized with 60 mL of 4M HCl to a pH of about 8. The pale tan/yellow solid was filtered off and suctioned dry. The filtered solid was placed in a soxhlet and extracted with chloroform to extract a brown solution. This was evaporated to a brownish oily solid and then washed with a small amount of methanol to give a pale brown solid (˜1.0 g 47%). The product may be recrystallized from chloroform/methanol as golden platelets by evaporating out the chloroform from the mixture. The structure was identified by NMR as the diketone below.

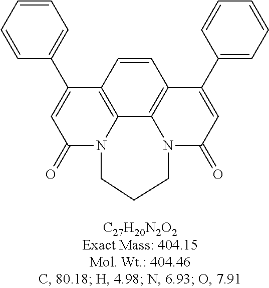

c) Combined portions of diketone from step (b) above totaling 5.5 g (13.6 mM) were suspended in 39 mL POCl₃ and 5.4 g PCl₅ was added. This was degassed and refluxed under nitrogen for 8 hrs. The excess POCl3 was removed by evaporation. Ice was added to decompose the remaining chlorides and the mixture was neutralized with ammonia solution. The brown precipitate was collected and dried under vacuum while the mother liquor was extracted with methylene chloride. All brown material was combined, evaporated to a brown gum and methanol added. After shaking and stirring a pale yellow solid was isolated which recrystallized as off-white needles from CHCl3 and methanol (1:10). Analysis by NMR indicated the structure to be 2,9-dichloro-4,7-diphenyl-1,10-phenanthroline, shown below.

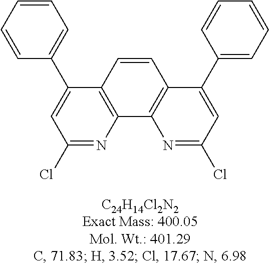

d) The non-deuterated analog compound was prepared using Suzuki coupling of 2,9-dichloro-4,7-diphenyl-1,10-phenanthroline with the boronic ester shown below.

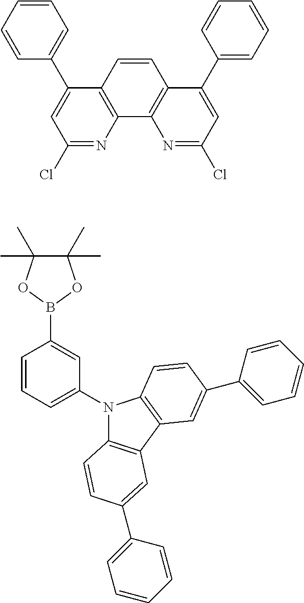

Take 1.0 g of dichloro-phen (2.5 mM) in glove box and add 3.12 g (6 mM) boronic ester. Add 0.15 g Pd₂DBA₃ (DBA=dibenzylideneacetone) (0.15 mM), 0.1 g tricyclohexylphosphine (0.35 mM) and 2.0 g potassium phosphate (9 mM) and dissolve all into 30 mL dioxane and 15 mL water. Mix and heat in glove box in mantle at 100 C for 1 hr then warm gently (minimum rheostat setting) under nitrogen overnight. Solution immediately is dark purple but on reaching ˜80 C it is a tan brown slurry which slowly becomes clear brown with a dense ppt. As the solution refluxes (air condenser) a brown gummy material forms. Cool and work up by removing from glove box and add water. Extract into DCM and dry over magnesium sulfate. Chromatograph on a plug of silica/florisil eluting with DCM then DCM/methanol 2:1. Collect a pale yellow solution which was evaporated and upon addition of methanol ppts a white/pale yellow solid. The structure was confirmed by NMR analysis to be the compound shown below.

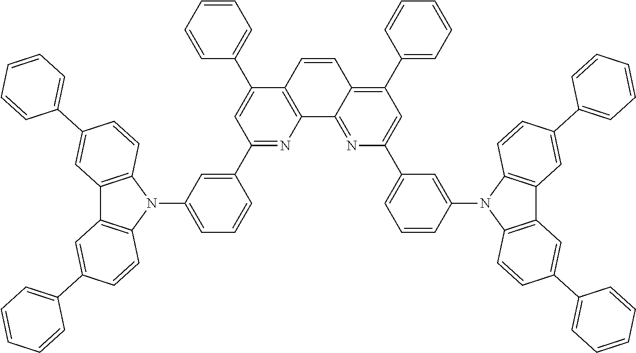

e) Compound ET2 was made from the non-deuterated analog compound.

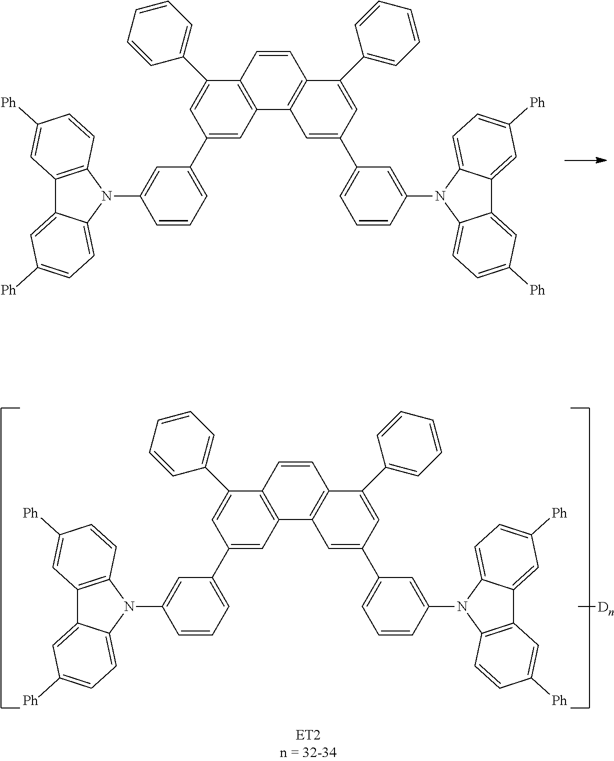

Under an atmosphere of nitrogen, the compound from step (d) above (1.925 g) was dissolved in C₆D₆ (200 mL) to which CF₃OSO₂D (13.2 mL) was added dropwise. The reaction mixture was allowed to stir at room temperate overnight and then it was quenched with saturated Na₂CO₃/D₂O. The organic layer was isolated and dried over MgSO₄. The product was purified using silica chromatography (CH₂Cl₂:hexane) to yield 1.70 g of material. The NMR spectrum of the isolated material confirmed the structure as ET2 with 32-34 D replacing H.

### Synthesis Example 7

This example illustrates the preparation of a deuterated electron transport material, ET4.

### Synthesis of ligand D₆-8-hydroxyquinoline

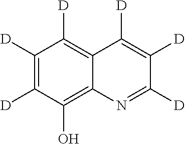

A mixture of 8-hydroxyquinoline 93.00 g, 20.667 mmol), D₂O (60 mL) and 10% Pd/C (0.200 g) was placed in a Parr reactor under an atmosphere of nitrogen and heated to 180 C. for 16 hours. The resulting mixture was added to diethyl ether (200 mL), the layers were separated and the organic layer was filtered through Celite. After evaporation of volatiles the resulting solid was purified using chromatography (20% DCM/hexane) to obtain 2.4 g (77% yield) of D₆-8-hydroxyquinoline product.

### Synthesis of ET4

1.0 g of zirconium(IV) chloride was mixed with 10 mL dry methanol and add to a stirred solution of 3.2 g D₆-8-hydroxyquinoline in 10 mL of dry methanol. This was stirred and refluxed under nitrogen for 30 mins. The Zr reagent formed a dense yellow precipitate immediately which was stirred and heated to reflux for the 30 mins. To this was added 4.8 g tri-n-butylamine and refluxing continued for 15 mins. The deep yellow precipitate was filtered, washed with methanol and ammonia (1N). This was dried, then extracted with methylene chloride as a pale yellow solution and reprecipitated by the addition of methanol. The structure was confirmed by ¹H NMR.

### Synthesis Example 8

This example illustrates the preparation of a deuterated electroluminescent compound, E13.

a) The compound shown below was made according to the procedure of Yan et. al., J. Mater. Chem., 2004, 14, 2295-3000.

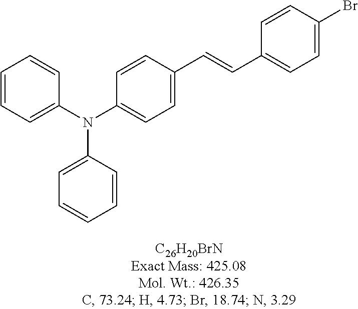

b) The non-deuterated compound was prepared according to the following scheme.

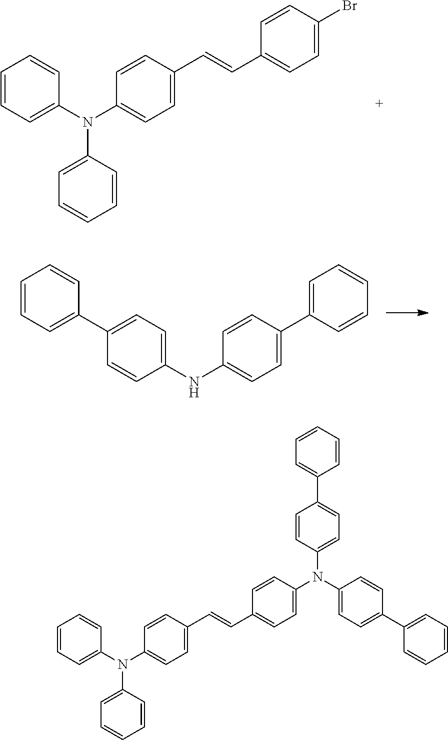

Take 1.0 g of the bromostilbene (2.3 mM) in glove box and add 0.74 g (2.3 mM) secondary amine shown and 0.24 g t-BuONa (2.4 mM) with 10 mL toluene. Add 100 mg Pd₂DBA₃, 40 mg P(t-Bu)₃ dissolved in toluene. Mix and heat in glove box in mantle at 80 C under nitrogen for 1 hr. Solution immediately is dark purple but on reaching ˜80 C it is dark yellow with noticeable blue luminescence. The material was cooled, removed from the glove box and purified by chromatography, eluting with toluene. The blue luminescent material is very soluble and elutes as a pale yellow solution. The solution was evaporated to low volume and methanol added to precipitate a pale yellow solid with brilliant blue PL. NMR analysis confirmed the structure.
c) Compound E13 was prepared by deuterating the compound from step (b) above using a procedure analogous to that in Synthesis Example 6.

### Device Examples 1-6

The following non-deuterated materials were used:

HIJ-A and HIJ-B are aqueous dispersions of an electrically conductive polymer and a polymeric fluorinated sulfonic acid. Such materials have been described in, for example, published U.S. patent applications US 2004/0102577, US 2004/0127637, US 2005/0205860, and published PCT application WO 2009/018009.

Polymer Pol-A is a non-crosslinked arylamine polymer (20 nm)

ELM-A and ELM-B are electroluminescent bis(diarylamino)chrysene compounds having blue emission

Host A is a diarylanthracene compound

ET-A is a metal quinolate derivative (10 nm)

In Device Example 1, deuterated material was present in the hole injection layer. The hole injection layer was D₅-PPy/D-poly(TFE-PSEPVE) from Synthesis Example 1.

In Device Example 2, deuterated material was present in the hole transport layer. The hole transport layer was HT5 from Synthesis Example 2.

In Device Example 3, deuterated material was present in the electroluminescent layer. The electroluminescent material was E4 from Synthesis Example 4.

In Device Example 4, deuterated material was present in the electroluminescent layer. The host in the electroluminescent layer was H14 from Synthesis Example 5.

In Device Example 5, deuterated material was present in the electron transport layer. The electron transport layer was ET2 from Synthesis Example 6.

In Device Example 6, deuterated material was present in the electron transport layer. The electron transport layer was ET4 from Synthesis Example 7.

For each of the devices, the anode was indium tin oxide (ITO), the electron injection layer was CsF, and the cathode was Al (100 nm). In Examples 1, 2, 4, 5, and 6, the anode had a thickness of 50 nm; in Example 3, the anode thickness was 180 nm. In Examples 1-4 and 6, the electron injection layer had a thickness of 1 nm; in Example 5 the electron injection thickness was 0.7 nm. The materials and the thicknesses for the other layers are summarized in Table 1 below.

TABLE 1
Device Structure

| Device | | | EML | | | | |
|---|---|---|---|---|---|---|---|
| Example | HIL | HTL | Host | Dopant | Thickness | Ratio | ETL |
| 1 | D₅-PPy/D- | Pol-A | H14 | ELM-A | 40 nm | 13:1 | ET-A |
| | poly(TFE- | (20 nm) | | | | | (10 nm) |
| | PSEPVE) | | | | | | |
| | (45 nm) | | | | | | |
| 2 | HIJ-A | HT5 | Host A | ELM-A | 40 nm | 6:1 | ET-A |
| | (50 nm) | (20 nm) | | | | | (10 nm) |
| 3 | HIJ-A | Pol-A | Host A | E4 | 60 nm | 13:1 | ET-A |
| | (50 nm) | (20 nm) | | | | | (10 nm) |
| 4 | HIJ-A | Pol-A | H14 | ELM-B | 40 nm | 13:1 | ET-A |
| | (50 nm) | (20 nm) | | | | | (10 nm) |
| 5 | HIJ-B | Pol-A | H14 | ELM-B | 40 nm | 13:1 | ET2 |
| | (50 nm) | (20 nm) | | | | | (10 nm) |
| 6 | HIJ-B | Pol-A | Host A | ELM-B | 40 nm | 13:1 | ET4 |
| | (50 nm) | (20 nm) | | | | | (10 nm) |

HIL = hole injection layer;
HTL = hole transport layer;
EML = electroluminescent layer;
ETL = electron transport layer;
Ratio = host:dopant by weight

OLED devices were fabricated by a combination of solution processing and thermal evaporation techniques. Patterned indium tin oxide (ITO) coated glass substrates from Thin Film Devices, Inc were used. These ITO substrates are based on Corning 1737 glass coated with ITO having a sheet resistance of 30 ohms/square and 80% light transmission. The patterned ITO substrates were cleaned ultrasonically in aqueous detergent solution and rinsed with distilled water. The patterned ITO was subsequently cleaned ultrasonically in acetone, rinsed with isopropanol, and dried in a stream of nitrogen.

Immediately before device fabrication the cleaned, patterned ITO substrates were treated with UV ozone for 10 minutes. Immediately after cooling, an aqueous dispersion of the hole injection material was spin-coated over the ITO surface and heated to remove solvent. After cooling, the substrates were then spin-coated with a solution of the hole transport material, and then heated to remove solvent. After cooling the substrates were spin-coated with the electroluminescent layer solution, and heated to remove solvent. The substrates were masked and placed in a vacuum chamber. The electron transport layer was deposited by thermal evaporation, followed by a layer of CsF as the electron injection layer. Masks were then changed in vacuo and a layer of Al was deposited by thermal evaporation to form the cathode. The chamber was vented, and the devices were encapsulated using a glass lid, desiccant, and UV curable epoxy.

The OLED samples were characterized by measuring their (1) current-voltage (I-V) curves, (2) electroluminescence radiance versus voltage, and (3) electroluminescence spectra versus voltage. All three measurements were performed at the same time and controlled by a computer. The current efficiency of the device at a certain voltage is determined by dividing the electroluminescence radiance of the LED by the current needed to run the device. The unit is a cd/A. The power efficiency is the current efficiency multiplied by pi, divided by the operating voltage. The unit is Im/W. The device data is given in Table 2 and Table 3.

TABLE 2
Device Performance

| | | | | | | Lifetest | | | Calculated |
|---|---|---|---|---|---|---|---|---|---|
| | | | | | | current | Lifetest | Obsvd. | Half-life |
| Device | CIE | V | C.E. | E.Q.E. | P.E. | density | Luminance | Half-life | @1000 nits |
| Ex. | (x, y) | (v) | (cd/A) | (%) | (lm/W) | (mA/cm2) | (nits) | (h) | (h) |
| 1 | 0.138, | 4.5 | 4.9 | 5.0 | 3.5 | 134 | 5851 | 636 | 12816 |
| | 0.116 | | | | | | | | |
| 2 | 0.138, | 3.7 | 7.2 | 7.7 | 6.0 | 129 | 7607 | 241 | 7589 |
| | 0.107 | | | | | | | | |
| 3 | 0.190, | 4.2 | 16.9 | 5.6 | 12.8 | 125 | 24720 | 251 | 58594 |
| | 0.60 | | | | | | | | |
| 4 | 0.135, | 4.3 | 6.0 | 5.9 | 4.4 | 121 | 6741 | 950 | 24356 |
| | 0.122 | | | | | | | | |
| 5 | 0.136 | 5.5 | 5.4 | 5.2 | 3.1 | 127 | 6543 | 1200 | 29241 |
| | 0.126 | | | | | | | | |

CIE (x, y) are the x and y color coordinates according to the C.I.E. chromaticity scale (Commission Internationale de L'Eclairage, 1931);
V = voltage;
CE = current efficiency;
E.Q.E. = external quantum efficiency;
P.E. = power efficiency;
acceleration factor = 1.7.

TABLE 3
Device Performance

| | | | | | | Lifetest | | | Calculated |
|---|---|---|---|---|---|---|---|---|---|
| | | | | | | current | Lifetest | | Lifetime |
| Device | CIE | V | C.E. | E.Q.E. | P.E. | density | Luminance | Obsvd. | T70 |
| Ex. | (x, y) | (v) | (cd/A) | (%) | (lm/W) | (mA/cm2) | (nits) | T70 (h) | @1000 nits |
| 6 | 0.135, | 4.6 | 5.9 | 5.5 | 4.1 | 133 | 6670 | 454 | 11431 |
| | 0.135 | | | | | | | | |

CIE (x, y) are the x and y color coordinates according to the C.I.E. chromaticity scale (Commission Internationale de L'Eclairage, 1931);
V = voltage;
CE = current efficiency;
E.Q.E. = external quantum efficiency;
P.E. = power efficiency;
Obsvd.T70 is the time in hours for a device to reach 70% of the initial luminance at the lifetest luminance given.
Calculated T70 is the projected time to reach 70% of the initial luminance at 1000 nits using an acceleration factor of 1.7.

In this example, the time to reach 70% luminance was determined, rather than the half-life. However, the calculated half-life will be even greater than the calculated time to reach 70% luminance. Thus, the half-life at 1000 nits is clearly greater than 10,000 hours

### Device Example 7

This example illustrates an electronic device having a deuterated priming layer formed by liquid deposition, where the hole transport layer and electroluminescent layer are also formed by liquid deposition.

The device had the following structure on a glass substrate:
anode=ITO: 50 nm
hole injection layer=HIJ-B (50 nm)
primer layer: HT11 (20 nm)
hole transport layer=Pol-A (20 nm)
electroluminescent layer=13:1 weight ratio of host H14:dopant ELM-B (40 nm),
electron transport layer=ET-A (10 nm)
cathode=CsF/Al (1/100 nm)

OLED devices were fabricated by a combination of solution processing and thermal evaporation techniques. A patterned indium tin oxide (ITO) coated glass substrate from Thin Film Devices, Inc was used. The ITO substrate is based on Corning 1737 glass coated with ITO having a sheet resistance of 30 ohms/square and 80% light transmission. The patterned ITO substrate was cleaned ultrasonically in aqueous detergent solution and rinsed with distilled water. The patterned ITO was subsequently cleaned ultrasonically in acetone, rinsed with isopropanol, and dried in a stream of nitrogen.

Immediately before device fabrication the cleaned, patterned ITO substrate was treated with UV ozone for 10 minutes. Immediately after cooling, an aqueous dispersion of HIJ-B was spin-coated over the ITO surface and heated to remove solvent. After cooling, a priming layer was formed by spin coating a toluene solution of HT11 onto the hole injection layer. The priming layer was imagewise exposed at 248 nm with a dosage of 100 mJ/cm². After exposure, the priming layer was developed by spraying with anisole while spinning at 2000 rpm for 60 s and then dried by spinning for 30 s. The substrates were then spin-coated with a solution of a hole transport material, and then heated to remove solvent. The electroluminescent layer was deposited by spin coating from a methyl benzoate solution, and then heated to remove solvent. After cooling, the substrates were masked and placed in a vacuum chamber. The electron transport material was then deposited by thermal evaporation, followed by a layer of CsF. Masks were then changed in vacuo and a layer of Al was deposited by thermal evaporation. The chamber was vented, and the devices were encapsulated using a glass lid, desiccant, and UV curable epoxy.

The OLED sample was characterized as described above.

The resulting device data is given in Table 4.

TABLE 4
Device Performance

| | | | | | | | Lifetest | | Obsvd. | Calc. |
|---|---|---|---|---|---|---|---|---|---|---|
| | Priming | CIE | Voltage | | | | current | Lifetest | Half- | Half- |
| Ex. | Layer | (x, y) | (V) | EQE | CE | PE. | density | Lum. | Life | Life |
| Ex. 7 | HT11 | 0.134 | 4.9 | 5.8 | 6.4 | 4.2 | 126 | 6757 | 609 | 15681 |
| | | 0.137 | | | | | | | | |

All data @ 1000 nits;
CIE(x, y) are the x and y color coordinates according to the C.I.E. chromaticity scale (Commission Internationale de L'Eclairage, 1931);
CE = current efficiency, in cd/A;
EQE = external quantum efficiency, in %;
PE = power efficiency, in lm/W;
Lifetest current density in mA/cm²;
Lifetest Lum. = luminance in nits;
Obsvd. Half-Life is the time in hours for a device to reach one-half the initial luminance at the lifetest luminance given.
Calculated Half-Life is the projected lifetime in hours at 1000 nits using an accelerator factor of 1.7.

### Device Example 8

This example illustrates an electronic device having an electroluminescent layer containing a deuterated host and a deuterated electroluminescent dopant.

The device had the following structure on a glass substrate:
anode=ITO: 50 nm
hole injection layer=HIJ-B (50 nm)
hole transport layer=Pol-A (20 nm)
electroluminescent layer=86:14 weight ratio of host H14:dopant E13 (40 nm),
electron transport layer=ET-A (10 nm)
cathode=CsF/Al (0.7/100 nm)

An OLED device was prepared as described in Device Example 1. The results are given in Table 5.

TABLE 5
Device Performance

| | | | | | | Lifetest | | | Calculated |
|---|---|---|---|---|---|---|---|---|---|
| | | | | | | current | Lifetest | Obsvd. | Half-life |
| Device | CIE | V | C.E. | E.Q.E. | P.E. | density | Luminance | Half-life | @1000 nits |
| Ex. | (x, y) | (v) | (cd/A) | (%) | (lm/W) | (mA/cm2) | (nits) | (h) | (h) |
| 8 | 0.15, | 4.3 | 3.5 | 2.5 | 2.5 | 137 | 5279 | 345 | 5837 |
| | 0.178 | | | | | | | | |

All data @ 1000 nits;
CIE(x, y) are the x and y color coordinates according to the C.I.E. chromaticity scale (Commission Internationale de L'Eclairage, 1931);
CE = current efficiency, in cd/A;
EQE = external quantum efficiency, in %;
PE = power efficiency, in lm/W;
Lifetest current density in mA/cm²;
Lifetest Lum. = luminance in nits;
Obsvd. Half-Life is the time in hours for a device to reach one-half the initial luminance at the lifetest luminance given.
Calculated Half-Life is the projected lifetime in hours at 1000 nits using an accelerator factor of 1.7.

As is shown by the data in the tables, the devices with at least one layer containing deuterated material had a calculated half-life of greater than 5000 hours. In Device Example 3, the calculated half-life is greater than 50,000 hours.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination.

The use of numerical values in the various ranges specified herein is stated as approximations as though the minimum and maximum values within the stated ranges were both being preceded by the word “about.” In this manner slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

What is claimed is:

1. An organic light-emitting diode comprising an anode, a cathode, and an organic active layer therebetween, wherein the organic active layer comprises a deuterated compound and the device has a calculated half-life at 1000 nits of at least 5000 hours.

2. The organic light-emitting diode of claim 1, wherein the organic active layer comprises a deuterated conductive polymer and a fluorinated acid polymer.

3. The organic light-emitting diode of claim 1, wherein the organic active layer comprises a deuterated hole transport compound having at least two diarylamino moieties per molecular formula unit.

4. The organic light-emitting diode of claim 1, wherein the organic active layer comprises a material selected from the group consisting of deuterated polymeric triarylamines, deuterated polycarbazoles, deuterated polyfluorenes, deuterated polymeric triarylamines having conjugated moieties which are connected in a non-planar configuration, deuterated copolymers of fluorene and triarylamine, and combinations thereof.

5. The organic light-emitting diode of claim 1, wherein the organic active layer comprises an electroluminescent compound selected from the group consisting of deuterated chrysenes, deuterated pyrenes, deuterated perylenes, deuterated rubrenes, deuterated periflanthenes, deuterated fluoranthenes, deuterated stilbenes, deuterated coumarins, deuterated anthracenes, deuterated thiadiazoles, deuterated spirobifluorenes, derivatives thereof, and mixtures thereof.

6. The organic light-emitting diode of claim 1, wherein the organic active layer comprises an electroluminescent compound having one of the formulae: 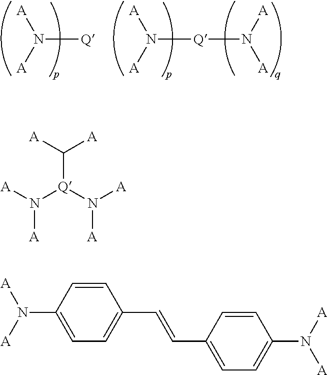
where:
A is the same or different at each occurrence and is an aromatic group having from 3-60 carbon atoms;
Q′ is selected from the group consisting of naphthalene, anthracene, benz[a]anthracene, dibenz[a,h]anthracene, fluoranthene, fluorene, spirofluorene, tetracene, chrysene, pyrene, tetracene, xanthene, perylene, coumarin, rhodamine, quinacridone, rubrene, substituted derivatives thereof, and deuterated analogs thereof.
p and q are the same or different and each is an integer from 1-6; wherein the compound is at least 10% deuterated.

7. The organic light-emitting diode of claim 1, wherein the organic active layer comprises an electroluminescent compound selected from the group consisting of deuterated aminoanthracenes, deuterated aminochrysenes, deuterated aminostilbenes, deuterated metal quinolate complexes, and deuterated iridium complexes.

8. The organic light-emitting diode of claim 1, wherein the organic active layer comprises (a) at least one host material selected from the group consisting of deuterated anthracenes, deuterated chrysenes, deuterated pyrenes, deuterated phenanthrenes, deuterated triphenylenes, deuterated phenanthrolines, deuterated naphthalenes, deuterated quinolines, deuterated isoquinolines, deuterated quinoxalines, deuterated deuterated phenylpyridines, deuterated dibenzofurans, deuterated difuranobenzenes, deuterated metal quinolinate complexes, deuterated indolocarbazoles, deuterated benzimidazoles, deuterated triazolopyridines, deuterated diheteroarylphenyls, substituted derivatives thereof, and combinations thereof and (b) at least one dopant capable of electroluminescence having an emission maximum between 380 and 750 nm.

9. The organic light-emitting diode of claim 8, wherein the host material is selected from the group consisting of deuterated diarylanthracenes, deuterated aminochrysenes, deuterated diarylchrysenes, deuterated diarylpyrenes, deuterated indolocarbazoles, deuterated phenanthrolines, and combinations thereof.

10. The organic light-emitting diode of claim 1, wherein the organic active layer comprises an electron transport material selected from the group consisting of deuterated phenanthrolines, deuterated indolocarbazoles, deuterated benzimidazoles, deuterated triazolopyridines, deuterated diheteroarylphenyls, deuterated metal quinolates, and combinations thereof.

11. The organic light-emitting diode of claim 1, wherein the active layer is a chemical containment layer formed using a priming layer, wherein the priming layer comprises a material selected from the group consisting of deuterated polymeric triarylamines, deuterated polycarbazoles, deuterated polyfluorenes, deuterated polymeric triarylamines having conjugated moieties which are connected in a non-planar configuration, deuterated copolymers of fluorene and triarylamine, deuterated metal quinolate derivatives, and combinations thereof.

12. The organic light-emitting diode of claim 1, further comprising a second active layer, wherein the second active layer comprises a deuterated compound.

13. The organic light-emitting diode of claim 1, wherein the calculated half-life at 1000 nits is at least 10,000 hours.

14. The organic light-emitting diode of claim 1, wherein the calculated half-life at 1000 nits is at least 20,000 hours.

15. The organic light-emitting diode of claim 1, wherein the calculated half-life at 1000 nits is at least 50,000 hours.

16. An organic light-emitting diode comprising an anode, a cathode and having organic layers therebetween, wherein the organic layers are a hole injection layer, a hole transport layer, an electroluminescent layer, an electron transport layer, and a cathode, and wherein at least two of the organic layers consist essentially of deuterated material.

17. The organic light-emitting diode of claim 16, where all of the organic layers consist essentially of deuterated material.
